(19) United States
(12) Patent Application Publication
(10) Pub. No.: US 2025/0331209 A1
(43) Pub. Date: Oct. 23, 2025

(54) SEMICONDUCTOR DEVICE AND METHOD FOR MANUFACTURING SEMICONDUCTOR DEVICE

(71) Applicant: FUJI ELECTRIC CO., LTD., Kanagawa (JP)

(72) Inventors: Motoyoshi KUBOUCHI, Matsumoto-city (JP); Soichi YOSHIDA, Matsumoto-city (JP)

(21) Appl. No.: 19/245,375

(22) Filed: Jun. 22, 2025

Related U.S. Application Data
(63) Continuation of application No. PCT/JP2024/025242, filed on Jul. 12, 2024.

(30) Foreign Application Priority Data
Jul. 14, 2023 (JP) 2023-115935

(51) Int. Cl. H10D 12/00; H10D 8/00; H10D 12/01; H10D 62/10; H10D 62/53; H10D 64/00; H10D 84/00

(52) U.S. Cl. CPC H10D 12/481; H10D 8/411; H10D 12/038; H10D 12/415; H10D 62/107; H10D 62/53; H10D 64/111; H10D 84/161

(57) ABSTRACT

Provided is a semiconductor device including: an active portion which is provided in a semiconductor substrate; and a temperature sensitive portion which is provided above the semiconductor substrate, in which the temperature sensitive portion includes a temperature sensitive diode which is provided above the semiconductor substrate, a first interlayer dielectric film which is provided above the temperature sensitive diode, a temperature sensitive contact portion which is provided to extend from an upper surface to a lower surface of the first interlayer dielectric film, and a housing portion which is provided below the temperature sensitive contact portion, a bottom surface corner portion of the temperature sensitive contact portion is in contact with the temperature sensitive diode, and a bottom surface of the temperature sensitive contact portion is in contact with the housing portion.

The contents of the following patent application(s) are incorporated herein by reference:
NO. 2023-115935 filed in JP on Jul. 14, 2023
NO. PCT/JP2024/025242 filed in WO on Jul. 12, 2024.

### BACKGROUND

### 1. Technical Field

The present invention relates to a semiconductor device and a method for manufacturing the semiconductor device.

### 2. Related Art

Patent Document 1 describes “a semiconductor device including an integrated PN diode temperature sensor and a method for manufacturing the same”.

### PRIOR ART DOCUMENTS

### Patent Documents

Patent Document 1: U.S. Patent Application Publication No. 2019/0172770

### BRIEF DESCRIPTION OF THE DRAWINGS

FIG. 1A illustrates an example of an enlarged top view of a semiconductor device 100.

FIG. 1B illustrates an example of a cross section a-a′ in FIG. 1A.

FIG. 2A illustrates an enlarged top view of a modification of the semiconductor device 100.

FIG. 2B illustrates an example of a cross section b-b′ in FIG. 2A.

FIG. 3 illustrates an example of a top view of the semiconductor device 100.

FIG. 4 illustrates an example of a cross section of the semiconductor device 100 including a temperature sensitive portion 180.

FIG. 5A illustrates an example of an enlarged view of a cross section of the semiconductor device 100.

FIG. 5B illustrates an enlarged view of a cross section of a modification of the semiconductor device 100.

FIG. 5C illustrates an enlarged view of a cross section of a modification of the semiconductor device 100.

FIG. 5D illustrates an example of an enlarged view of the cross section of the semiconductor device 100 when a void 302 is generated in a temperature sensitive contact portion 188.

FIG. 5E illustrates another example of the enlarged view of the cross section of the semiconductor device 100 when the void 302 is generated in the temperature sensitive contact portion 188.

FIG. 6 illustrates a cross section of a modification of the semiconductor device 100 including a temperature sensitive portion 180.

FIG. 7A illustrates an enlarged view of a cross section of a modification of the semiconductor device 100.

FIG. 7B illustrates an enlarged view of a cross section of a modification of the semiconductor device 100.

FIG. 7C illustrates an enlarged view of a cross section of a modification of the semiconductor device 100.

FIG. 7D illustrates an example of an enlarged view of the cross section of the semiconductor device 100 when the void 302 is generated in the temperature sensitive contact portion 188.

FIG. 7E illustrates another example of the enlarged view of the cross section of the semiconductor device 100 when the void 302 is generated in the temperature sensitive contact portion 188.

FIG. 8 is a flowchart illustrating an example of a manufacturing step of the semiconductor device 100.

FIG. 9 is an example of electrical connection of each portion of the semiconductor device 100 illustrated in FIG. 3.

FIG. 10A illustrates an example of the enlarged top view of the semiconductor device 100.

FIG. 10B illustrates an example of a cross section c-c′ in FIG. 9.

FIG. 11 illustrates an example of a cross section d-d′ in FIG. 9.

FIG. 12A illustrates an example of an enlarged view of a cross section d-d′ in FIG. 9.

FIG. 12B illustrates an example of the enlarged view of the cross section d-d′ in FIG. 9 when the void 302 is generated in the first inactive contact portion 134.

FIG. 12C illustrates another example of the enlarged view of the cross section d-d′ in FIG. 9 when the void 302 is generated in the first inactive contact portion 134.

FIG. 13 illustrates an example of the cross section d-d′ in FIG. 9.

FIG. 14A illustrates an example of the enlarged view of the cross section d-d′ in FIG. 9.

FIG. 14B illustrates an example of the enlarged view of the cross section d-d′ in FIG. 9 when the void 302 is generated in the first inactive contact portion 134.

FIG. 14C illustrates another example of the enlarged view of the cross section d-d′ in FIG. 9 when the void 302 is generated in the first inactive contact portion 134.

FIG. 15 illustrates an example of a cross section e-e′ in FIG. 9.

FIG. 16A illustrates an example of an enlarged view of the cross section e-e′ in FIG. 9.

FIG. 16B illustrates an example of the enlarged view of the cross section e-e′ in FIG. 9 when the void 302 is generated in the first inactive contact portion 134.

FIG. 16C illustrates another example of the enlarged view of the cross section e-e′ in FIG. 9 when the void 302 is generated in the first inactive contact portion 134.

FIG. 17 illustrates an example of the cross section e-e′ in FIG. 9.

FIG. 18A illustrates an example of the enlarged view of the cross section e-e′ in FIG. 9.

FIG. 18B illustrates an example of the enlarged view of the cross section e-e′ in FIG. 9 when the void 302 is generated in the first inactive contact portion 134.

FIG. 18C illustrates another example of the enlarged view of the cross section e-e′ in FIG. 9 when the void 302 is generated in the first inactive contact portion 134.

FIG. 19A illustrates an example of the top view of the semiconductor device 100.

FIG. 19B illustrates an example of a region R in FIG. 19A.

FIG. 20 illustrates an example of a cross section f-f′ in FIG. 19B.

FIG. 21A illustrates an example of an enlarged view of the cross section f-f′ in FIG. 19B.

FIG. 21B illustrates an example of the enlarged view of the cross section f-f′ in FIG. 19B.

FIG. 21C illustrates an example of the enlarged view of the cross section f-f′ in FIG. 19B.

FIG. 21D illustrates an example of the enlarged view of the cross section f-f′ in FIG. 19B when the void 302 is generated in the first inactive contact portion 134.

FIG. 21E illustrates another example of the enlarged view of the cross section f-f′ in FIG. 19B when the void 302 is generated in the first inactive contact portion 134.

FIG. 22 illustrates an example of the cross section f-f′ in FIG. 19B.

FIG. 23A illustrates an example of the enlarged view of the cross section f-f′ in FIG. 19B.

FIG. 23B illustrates an example of the enlarged view of the cross section f-f′ in FIG. 19B.

FIG. 23C illustrates an example of the enlarged view of the cross section f-f′ in FIG. 19B.

FIG. 23D illustrates an example of the enlarged view of the cross section f-f′ in FIG. 19B when the void 302 is generated in the first inactive contact portion 134.

FIG. 23E illustrates another example of the enlarged view of the cross section f-f′ in FIG. 19B when the void 302 is generated in the first inactive contact portion 134.

FIG. 24 illustrates an example of the cross section f-f′ in FIG. 19B.

FIG. 25A illustrates an example of the enlarged view of the cross section f-f′ in FIG. 19B.

FIG. 25B illustrates an example of the enlarged view of the cross section f-f′ in FIG. 19B.

FIG. 25C illustrates an example of the enlarged view of the cross section f-f′ in FIG. 19B when the void 302 is generated in the first inactive contact portion 134.

FIG. 25D illustrates another example of the enlarged view of the cross section f-f′ in FIG. 19B when the void 302 is generated in the first inactive contact portion 134.

FIG. 26 illustrates an example of the cross section f-f′ in FIG. 19B.

FIG. 27A illustrates an example of the enlarged view of the cross section f-f′ in FIG. 19B.

FIG. 27B illustrates an example of the enlarged view of the cross section f-f′ in FIG. 19B.

FIG. 27C illustrates an example of the enlarged view of the cross section f-f′ in FIG. 19B when the void 302 is generated in the first inactive contact portion 134.

FIG. 27D illustrates another example of the enlarged view of the cross section f-f′ in FIG. 19B when the void 302 is generated in the first inactive contact portion 134.

FIG. 28 illustrates an example of a cross section g-g′ in FIG. 19A.

FIG. 29A illustrates an example of a region P in FIG. 19A.

FIG. 29B illustrates another example of the region P in FIG. 19A.

FIG. 29C illustrates another example of the region P in FIG. 19A.

FIG. 30 illustrates another example of the cross section g-g′ in FIG. 19A.

FIG. 31 is a flowchart illustrating an example of a manufacturing step of the semiconductor device 100.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a-Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is ND and the acceptor concentration is NA, the net doping concentration at any position is given as ND-NA. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect which is a combination of vacancy (V), oxygen (O), and hydrogen (H), an Si-i-H defect which is a combination of interstitial silicon (Si-i) and hydrogen, and a CiOi-H defect which is a combination of interstitial carbon (Ci), interstitial oxygen (Oi), and hydrogen that exist in the semiconductor function as a donor for supplying electrons. In the present specification, the VOH defect or the like may be referred to as a hydrogen donor.

In the present specification, a description of a P+ type or an N+ type means a higher doping concentration than that of the P type or the N type, and a description of a P− type or an N− type means a lower doping concentration than that of the P type or the N type. Further, in the specification, a description of a P++ type or an N++ type means a higher doping concentration than that of the P+ type or the N+ type.

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). Further, a carrier concentration measured by spreading resistance profiling (SRP method) may be set as the net doping concentration. The carrier means a charge carrier of an electron or a hole. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

Further, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in carrier mobility occurs when carriers are scattered due to disorder (disorder) of a crystal structure due to a lattice defect or the like. The carrier concentration decreases for the following reason. In the SRP method, the spreading resistance is measured, and the carrier concentration is converted from a measurement value of the spreading resistance. At this time, mobility of the crystalline state is used as the carrier mobility. On the other hand, despite the fact that the carrier mobility has decreased at a position where the lattice defect is introduced, the carrier concentration is calculated by using the carrier mobility of the crystalline state. Therefore, a value lower than an actual carrier concentration, that is, a concentration of the donor or the acceptor, is obtained.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. In the present specification, an SI unit system is adopted. As used herein, a unit of a distance or length may be represented by cm (centimeter). In this case, various calculations may be converted into m (meter) to be calculated. As for numeric representation of power of 10, for example, the representation 1E+16 indicates 1×10¹⁶, and the representation 1E-16 indicates 1×10⁻¹⁶.

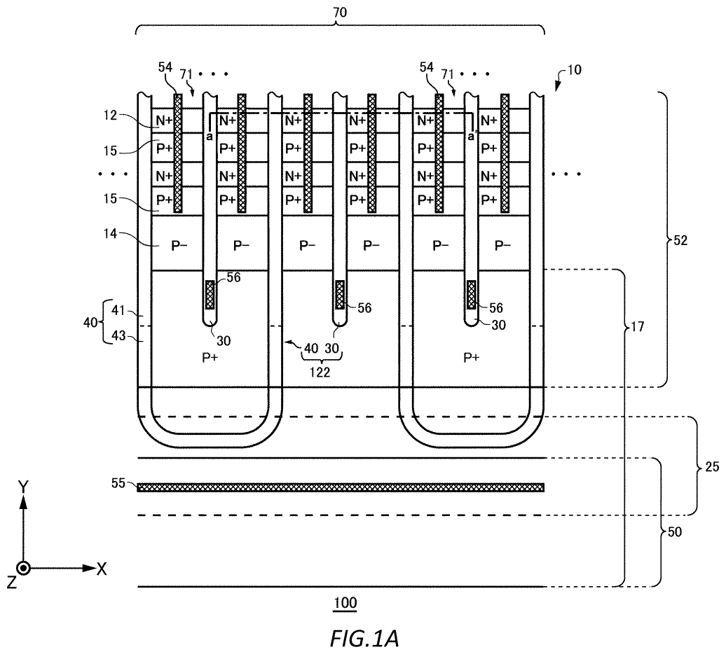

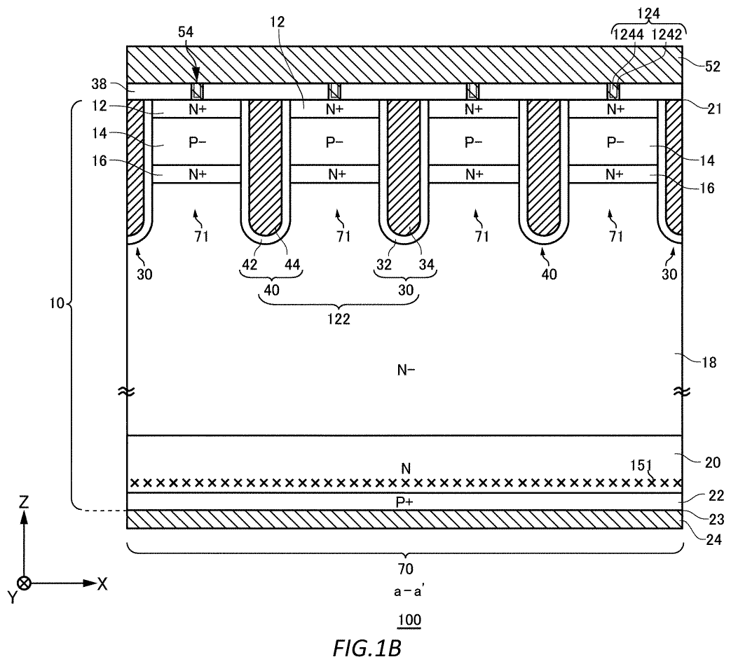

FIG. 1A illustrates an example of an enlarged top view of a semiconductor device 100. The semiconductor device 100 in the present example is a semiconductor chip which includes a transistor portion 70. The semiconductor device 100 is not limited to a transistor as long as it is a semiconductor element in which a semiconductor substrate 10 has a MOS gate structure. A configuration of the present drawing may be repeatedly provided in a positive direction and a negative direction of the X axis.

The transistor portion 70 is a region obtained by projecting a collector region 22 provided on a back surface side of the semiconductor substrate 10 onto an upper surface of the semiconductor substrate 10. The collector region 22 will be described below. The transistor portion 70 includes a transistor such as an IGBT. In the present example, the transistor portion 70 is an IGBT. Note that the transistor portion 70 may be another transistor such as a MOSFET.

The present drawing illustrates a region around an active portion 120 of the semiconductor device 100, and illustration of other regions is omitted. The active portion 120 is a part through which a main current flows between a front surface 21 and a back surface 23 of the semiconductor substrate 10. The active portion 120 will be described below. For example, an edge termination structure portion may be provided in a region on a negative side in the Y axis direction in the semiconductor device 100 in the present example. The edge termination structure portion reduces electric field strength on an upper surface side of the semiconductor substrate 10. For example, the edge termination structure portion has a structure of a guard ring, a field plate, a RESURF, and a combination thereof. Note that although the present example describes an edge on the negative side in the Y axis direction for convenience, the same applies to other edges of the semiconductor device 100.

The semiconductor substrate 10 is a substrate which is formed of a semiconductor material. The semiconductor substrate 10 may be a silicon substrate, a silicon carbide substrate, another compound semiconductor substrate, or a diamond semiconductor substrate. The semiconductor substrate 10 in the present example is the silicon substrate. Note that when simply referred to as a top view in the present specification, it means that the semiconductor substrate 10 is viewed from an upper surface side. As will be described below, the semiconductor substrate 10 includes the front surface 21 and the back surface 23.

The semiconductor device 100 in the present example includes a gate trench portion 40, a dummy trench portion 30, an emitter region 12, a base region 14, a contact region 15, and a well region 17 at the front surface 21 of the semiconductor substrate 10. In addition, the semiconductor device 100 in the present example includes an emitter electrode 52 and a gate metal layer 50 which are provided above the front surface 21 of the semiconductor substrate 10. The emitter electrode 52 and the gate metal layer 50 are examples of a front surface side metal layer. The gate trench portion 40 is an example of the MOS gate structure provided in the semiconductor device 100. Note that although the semiconductor device 100 in the present example is a transistor including the MOS gate structure, the semiconductor device 100 may be a diode including the MOS gate structure.

The emitter electrode 52 is provided above the gate trench portion 40, the dummy trench portion 30, the emitter region 12, the base region 14, the contact region 15, and the well region 17. In addition, the gate metal layer 50 is provided above a connection portion 25 and the well region 17.

The emitter electrode 52 and the gate metal layer 50 are formed of a material containing metal. At least a partial region of the emitter electrode 52 may be formed of metal such as aluminum (Al) or of a metal alloy such as an aluminum-silicon alloy (AlSi) or an aluminum-silicon-copper alloy (AlSiCu). At least a partial region of the gate metal layer 50 may be formed of metal such as aluminum (Al) or of a metal alloy such as an aluminum-silicon alloy (AlSi) or an aluminum-silicon-copper alloy (AlSiCu). The emitter electrode 52 and the gate metal layer 50 may include a barrier metal film formed of titanium, a titanium compound, or the like under a region formed of aluminum or the like. The emitter electrode 52 and the gate metal layer 50 are provided separated from each other.

The emitter electrode 52 and the gate metal layer 50 are provided above the semiconductor substrate 10 with an interlayer dielectric film 38 interposed therebetween. The interlayer dielectric film 38 is omitted in FIG. 1A. A contact hole 54, a contact hole 55, and a contact hole 56 are provided to penetrate the interlayer dielectric film 38.

The contact hole 55 electrically connects the gate metal layer 50 and the gate conductive portion in the transistor portion 70 via the connection portion 25. A barrier metal film formed of titanium, a titanium compound, or the like and/or a plug portion formed of tungsten or the like may be formed inside the contact hole 55.

The contact hole 56 connects the emitter electrode 52 with a dummy conductive portion within the dummy trench portion 30. A barrier metal film formed of titanium, a titanium compound, or the like and/or a plug portion formed of tungsten or the like may be formed inside the contact hole 56.

The connection portion 25 is connected to the front surface side metal layer such as the emitter electrode 52 or the gate metal layer 50. In an example, the connection portion 25 is provided between the gate metal layer 50 and the gate conductive portion. The connection portion 25 in the present example may be provided to extend in the X axis direction and electrically connected to the gate conductive portion. The connection portion 25 may also be provided between the emitter electrode 52 and the dummy conductive portion. In the present example, the connection portion 25 is not provided between the emitter electrode 52 and the dummy conductive portion. The connection portion 25 is a conductive material such as polysilicon doped with impurities. The connection portion 25 in the present example is polysilicon (N+) doped with impurities of the N type. The connection portion 25 is provided above the front surface 21 of the semiconductor substrate 10 via a dielectric film such as an oxide film, or the like.

The gate trench portion 40 is an example of an active trench portion 122 provided at the front surface 21 of the semiconductor substrate 10. That is, the active trench portion 122 may be a trench portion provided in the active portion 120. The gate trench portions 40 are arrayed at a predetermined interval along a predetermined array direction (the X axis direction in the present example). The gate trench portion 40 in the present example may include two extending parts 41 which extend along an extending direction (the Y axis direction in the present example) parallel to the front surface 21 of the semiconductor substrate 10 and perpendicular to the array direction, and a connecting part 43 which connects the two extending parts 41.

At least a part of the connecting part 43 is preferably formed in a curved shape. Connecting end portions of the two extending parts 41 of the gate trench portion 40 can reduce electric field strength at the end portions of the extending parts 41. In the connecting part 43 of the gate trench portion 40, the gate metal layer 50 may be electrically connected to the gate conductive portion via the connection portion 25.

The dummy trench portion 30 is an example of the active trench portion 122 provided at the front surface 21 of the semiconductor substrate 10. That is, the active trench portion 122 may be a trench portion provided in the active portion 120. The dummy trench portion 30 is a trench portion which is electrically connected to the emitter electrode 52. Similarly to the gate trench portions 40, the dummy trench portions 30 are arrayed at a predetermined interval along a predetermined array direction (the X axis direction in the present example). Although the dummy trench portion 30 in the present example has an I shape at the front surface 21 of the semiconductor substrate 10, the dummy trench portion 30 may have a U shape at the front surface 21 of the semiconductor substrate 10, similarly to the gate trench portion 40. That is, the dummy trench portion 30 may include two extending parts extending along an extending direction and a connecting part connecting the two extending parts.

The transistor portion 70 in the present example has a structure in which two gate trench portions 40 and two dummy trench portions 30 are repeatedly arrayed. That is, the transistor portion 70 in the present example has the gate trench portions 40 and the dummy trench portions 30 at a ratio of 1:1. For example, the transistor portion 70 has one dummy trench portion 30 between two extending parts 41.

It is to be noted that the ratio between the gate trench portions 40 and the dummy trench portions 30 is not limited to that in the present example. A ratio of the gate trench portions 40 may be larger than a ratio of the dummy trench portions 30, or the ratio of the dummy trench portions 30 may be larger than the ratio of the gate trench portions 40. The ratio between the gate trench portions 40 and the dummy trench portions 30 may be 2:3, or may be 2:4. In addition, the transistor portion 70 may not include the dummy trench portions 30 with all trench portions being the gate trench portions 40.

The well region 17 is a region of a second conductivity type which is provided on a front surface 21 side of the semiconductor substrate 10 relative to a drift region 18 to described below. The well region 17 is an example of a well region provided in a peripheral side of the active portion 120. The well region 17 is of the P+ type as an example. The well region 17 is formed in a predetermined range from an end portion of an active region on a side where the gate metal layer 50 is provided. A diffusion depth of the well region 17 may be deeper than a depth of the gate trench portion 40 and the dummy trench portion 30. Partial regions of the gate trench portion 40 and the dummy trench portion 30 on a gate metal layer 50 side are formed in the well region 17. Bottoms of ends in the extending direction of the gate trench portion 40 and the dummy trench portion 30 may be covered with the well region 17.

The contact hole 54 is formed above each region of the emitter region 12 and the contact region 15 in the transistor portion 70. The contact hole 54 is not provided above the well regions 17 provided at both ends in the Y axis direction. In this manner, one or more contact holes 54 are formed in the interlayer dielectric film. The one or more contact holes 54 may be provided to extend in an extending direction.

A mesa portion 71 is a mesa portion provided adjacent to the trench portion in a plane parallel to the front surface 21 of the semiconductor substrate 10. The mesa portion may be a part of the semiconductor substrate 10 sandwiched between two trench portions adjacent to each other, and may be a part from the front surface 21 of the semiconductor substrate 10 to a depth of a lowermost bottom portion of each trench portion. The extending part of each trench portion may be defined as one trench portion. That is, a region sandwiched between two extending parts may be defined as a mesa portion.

The mesa portion 71 is provided adjacent to at least one of the dummy trench portion 30 or the gate trench portion 40 in the transistor portion 70. The mesa portion 71 includes the well region 17, the emitter region 12, the base region 14, and the contact region 15 at the front surface 21 of the semiconductor substrate 10. In the mesa portion 71, the emitter regions 12 and the contact regions 15 are alternately provided in an extending direction.

The base region 14 is a region of the second conductivity type which is provided on the front surface 21 side of the semiconductor substrate 10. The base region 14 is of the P− type as an example. The base regions 14 may be provided at both end portions of the mesa portion 71 in the Y axis direction at the front surface 21 of the semiconductor substrate 10. Note that FIG. 1A illustrates only one end portion of the base region 14 in the Y axis direction.

The emitter region 12 is a region of a first conductivity type which has a doping concentration higher than that of the drift region 18. The emitter region 12 in the present example is of the N+ type as an example. Examples of a dopant of the emitter region 12 include arsenic (As). The emitter region 12 is provided in contact with the gate trench portion 40 at the front surface 21 in the mesa portion 71. The emitter region 12 may be provided to extend in the X axis direction from one to another of two trench portions sandwiching the mesa portion 71. The emitter region 12 is also provided below the contact hole 54.

In addition, the emitter region 12 may or may not be in contact with the dummy trench portion 30. The emitter region 12 in the present example is in contact with the dummy trench portion 30.

The contact region 15 is a region of the second conductivity type which is provided above the base region 14 and has a doping concentration higher than that of the base region 14. The contact region 15 in the present example is of the P+ type as an example. The contact region 15 in the present example is provided at the front surface 21 in the mesa portion 71. The contact region 15 may be provided in the X axis direction from one to another of the two trench portions sandwiching the mesa portion 71. The contact region 15 may or may not be in contact with the gate trench portion 40 or the dummy trench portion 30. The contact region 15 in the present example is in contact with the dummy trench portion 30 and the gate trench portion 40. The contact region 15 is also provided below the contact hole 54.

FIG. 1B illustrates an example of a cross section a-a′ in FIG. 1A. The cross section a-a′ is an XZ plane passing through the emitter region 12 in the transistor portion 70. The semiconductor device 100 in the present example includes, in the cross section a-a′, the semiconductor substrate 10, the interlayer dielectric film 38, the emitter electrode 52, a collector electrode 24, and an active contact portion 124. The collector electrode 24 is an example of a back surface side metal layer provided in contact with the back surface 23 of the semiconductor substrate 10. The emitter electrode 52 is formed above the semiconductor substrate 10 and the interlayer dielectric film 38.

The drift region 18 is a region of the first conductivity type which is provided in the semiconductor substrate 10. The drift region 18 in the present example is of the N− type as an example. The drift region 18 may be a region which has remained without another doping region formed in the semiconductor substrate 10. That is, the doping concentration of the drift region 18 may be a doping concentration of the semiconductor substrate 10.

The buffer region 20 is a region of the first conductivity type which is provided on the back surface 23 side of the semiconductor substrate 10 relative to the drift region 18. The buffer region 20 in the present example is of the N type as an example. A doping concentration of the buffer region 20 is higher than the doping concentration of the drift region 18. The buffer region 20 may function as a field stop layer which prevents a depletion layer extending from a lower surface side of the base region 14 from reaching the collector region 22 of the second conductivity type. Note that the buffer region 20 may be omitted.

The collector region 22 is provided below the buffer region 20 in the transistor portion 70. The collector region 22 is of the second conductivity type. The collector region 22 in the present example is of the P+ type as an example.

The collector electrode 24 is formed on the back surface 23 of the semiconductor substrate 10. The collector electrode 24 is formed of a conductive material such as metal. The material of the collector electrode 24 may be the same as or different from the material of the emitter electrode 52.

The base region 14 is a region of the second conductivity type which is provided above the drift region 18. The base region 14 is provided in contact with the gate trench portion 40. The base region 14 may be provided in contact with the dummy trench portion 30.

The emitter region 12 is provided above the base region 14. The emitter region 12 is provided between the base region 14 and the front surface 21. The emitter region 12 is provided in contact with the gate trench portion 40. The emitter region 12 may or may not be in contact with the dummy trench portion 30.

An accumulation region 16 is a region of the first conductivity type which is provided on the front surface 21 side of the semiconductor substrate 10 relative to the drift region 18. The accumulation region 16 in the present example is of the N+ type as an example. It is to be noted that the accumulation region 16 may not be provided.

The accumulation region 16 is provided in contact with the gate trench portion 40. The accumulation region 16 may or may not be in contact with the dummy trench portion 30. The doping concentration of the accumulation region 16 is higher than the doping concentration of the drift region 18. An ion implantation dose amount of the accumulation region 16 may be 1.0E+12 cm⁻² or more and 1.0E+13 cm⁻² or less. In addition, the ion implantation dose amount of the accumulation region 16 may be 3.0E+12 cm⁻² or more and 6.0E+12 cm⁻² or less. Providing the accumulation region 16 can increase a carrier injection enhancement effect (IE effect) to reduce an on-voltage of the transistor portion 70.

One or more gate trench portions 40 and one or more dummy trench portions 30 are provided at the front surface 21. Each trench portion may be the active trench portion 122 included in the active portion 120. Each trench portion is provided from the front surface 21 to the drift region 18. In a region provided with at least one of the emitter region 12, the base region 14, the contact region 15, or the accumulation region 16, each trench portion also penetrates these regions to reach the drift region 18. The configuration of the trench portion penetrating the doping region is not limited to the one manufactured in the order of forming the doping region and then forming the trench portion. The configuration of the trench portion penetrating the doping region includes a configuration of the doping region being formed between the trench portions after forming the trench portion.

The gate trench portion 40 includes a gate trench formed at the front surface 21, a gate dielectric film 42, and a gate conductive portion 44. The gate dielectric film 42 is formed to cover an inner wall of the gate trench. The gate dielectric film 42 may be formed by oxidizing or nitriding a semiconductor on the inner wall of the gate trench. The gate conductive portion 44 is formed inside from the gate dielectric film 42 inside the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes a region opposing the adjacent base region 14 on a mesa portion 71 side with the gate dielectric film 42 interposed therebetween, in the depth direction of the semiconductor substrate 10. When a predetermined voltage is applied to the gate conductive portion 44, a channel is formed by an electron inversion layer in a surface layer of the base region 14 at an interface in contact with the gate trench.

The dummy trench portion 30 may have the same structure as that of the gate trench portion 40. The dummy trench portion 30 includes a dummy trench formed on the front surface 21 side, a dummy dielectric film 32, and a dummy conductive portion 34. The dummy dielectric film 32 is formed to cover an inner wall of the dummy trench. The dummy conductive portion 34 is formed inside the dummy trench, and is formed inside from the dummy dielectric film 32. The dummy dielectric film 32 insulates the dummy conductive portion 34 from the semiconductor substrate 10. The dummy trench portion 30 may be covered with the interlayer dielectric film 38 on the front surface 21.

The interlayer dielectric film 38 is provided above the semiconductor substrate 10. The interlayer dielectric film 38 in the present example is provided in contact with the front surface 21. The emitter electrode 52 is provided above the interlayer dielectric film 38. The interlayer dielectric film 38 is provided with one or more contact holes 54 for electrically connecting the emitter electrode 52 to the semiconductor substrate 10. Similarly, the contact hole 55 and the contact hole 56 may also be provided to penetrate the interlayer dielectric film 38. The interlayer dielectric film 38 may be a Boro-phospho Silicate Glass (BPSG) film, may be a borosilicate glass (BSG) film, may be a Phosphosilicate glass (PSG) film, may be an HTO film, or may be a stack of these materials. A film thickness of the interlayer dielectric film 38 is, for example, 1.0 μm, but is not limited thereto.

The active contact portion 124 is provided at the front surface 21 of the semiconductor substrate 10. The active contact portion 124 may include the contact hole 54 and a metal layer with which an inside of the contact hole 54 is filled. The inside of the contact hole 54 may be filled with the same material as that of the emitter electrode 52, or a material different from that of the emitter electrode 52. The active contact portion 124 may include a barrier metal film 1242 provided in the contact hole 54 and in contact with the semiconductor substrate 10. The active contact portion 124 may include a plug portion 1244 which is in contact with the barrier metal film 1242 and is provided so as to be embedded into the contact hole 54. The barrier metal film 1242 of the active contact portion 124 may contain titanium, a titanium compound, or the like. The plug portion 1244 of the active contact portion 124 may contain a plug metal such as tungsten. The contact hole 55 and the contact hole 56, and a metal layer with which the insides of the contact hole 55 and the contact hole 56 are filled may also have similar configurations. The active portion 120 may include a plurality of active contact portions 124 provided at the front surface 21 of the semiconductor substrate 10. Note that an alloy layer which consists of an alloy of a metal included in the barrier metal film 1242 and a layer of the semiconductor substrate 10 or the like located below the contact holes 54, 55, and 56 may be formed in contact with the barrier metal film 1242. In addition, in the layer of the semiconductor substrate 10 or the like located below the contact hole 54, the contact hole 55, and the contact hole 56, a region having a high impurity concentration may be formed at a position in contact with the alloy layer. Note that the active contact portion 124 in the present example has a planar contact structure, but may have a trench contact structure as described below.

A back surface side lifetime control region 151 may be provided in the transistor portion 70. It is to be noted that the back surface side lifetime control region 151 may be omitted. The back surface side lifetime control region 151 is a region where a lifetime killer has intentionally been formed, for example, by implanting impurities inside the semiconductor substrate 10. In an example, the back surface side lifetime control region 151 is formed by implanting helium into the semiconductor substrate 10. The back surface side lifetime control region 151 may also be formed by implanting protons. By providing the back surface side lifetime control region 151, a turn-off time can be reduced, and by suppressing a tail current, losses during switching can be reduced.

The lifetime killer is a recombination center of carriers. The lifetime killer may be a lattice defect. For example, the lifetime killer may be a vacancy, a divacancy, a defect complex of these with elements constituting the semiconductor substrate 10, or dislocation. In addition, the lifetime killer may be a noble gas element such as helium and neon, a metal element such as platinum, or the like. An electron beam or a proton may be used for forming the lattice defect.

A lifetime killer concentration is a concentration at the recombination center of carriers. The lifetime killer concentration may be a concentration of the lattice defect. For example, the lifetime killer concentration may be a vacancy concentration of a vacancy, a divacancy, or the like, may be a defect complex concentration of these vacancies with elements constituting the semiconductor substrate 10, or may be a dislocation concentration. In addition, the lifetime killer concentration may be a chemical concentration of the noble gas element such as helium and neon, or may be a chemical concentration of the metal element such as platinum.

The back surface side lifetime control region 151 may be formed by implantation from the back surface 23 side. Accordingly, it becomes easy to avoid an effect on the front surface 21 side of the semiconductor device 100. For example, the back surface side lifetime control region 151 is formed by radiating helium or protons from the back surface 23 side. Herein, which of the front surface 21 side and the back surface 23 side the implantation is performed from for forming the back surface side lifetime control region 151 can be determined by acquiring a state of the front surface 21 side by the SRP method or a measurement of a leakage current.

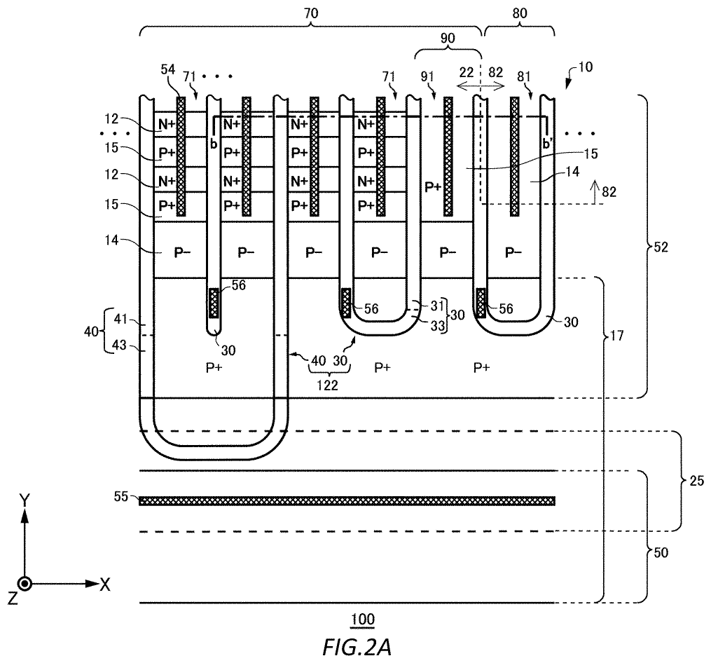

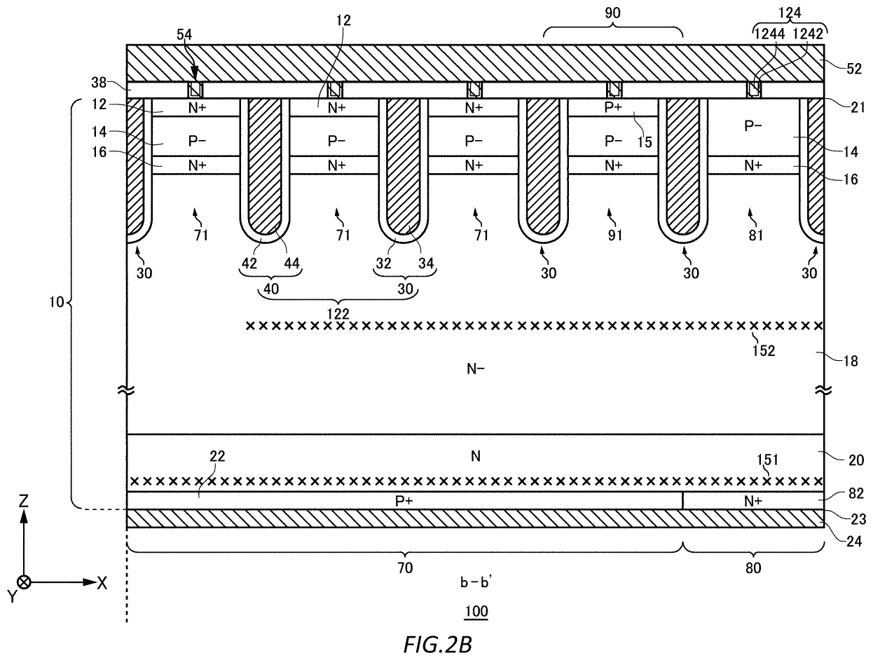

FIG. 2A illustrates an enlarged top view of a modification of the semiconductor device 100. The semiconductor device 100 in the present example includes the transistor portion 70 and a diode portion 80. A configuration of the present drawing may be repeatedly provided in a positive direction and a negative direction of the X axis.

The semiconductor device 100 in the present example includes the gate trench portion 40, the dummy trench portion 30, the emitter region 12, the base region 14, the contact region 15, and the well region 17 which are provided inside the semiconductor substrate 10 on the front surface 21 side. Each of the gate trench portion 40 and the dummy trench portion 30 is an example of the active trench portion 122.

Similarly to the gate trench portion 40, the dummy trench portion 30 in the present example may have a U shape at the front surface 21 of the semiconductor substrate 10. That is, the dummy trench portion 30 may include two extending parts 31 extending along the extending direction and a connecting part 33 connecting the two extending parts 31.

The semiconductor device 100 in the present example includes the emitter electrode 52 and the gate metal layer 50 which are provided above the front surface 21 of the semiconductor substrate 10. The emitter electrode 52 and the gate metal layer 50 are provided separated from each other. The transistor portion 70 in the present example includes a boundary portion 90 which is located at a boundary between the transistor portion 70 and the diode portion 80. It is to be noted that the semiconductor device 100 does not need to include the boundary portion 90.

The boundary portion 90 is a region which is provided in the transistor portion 70 and is in direct contact with the diode portion 80. The boundary portion 90 includes the contact region 15 at the front surface 21 of the semiconductor substrate 10. The boundary portion 90 in the present example does not include the emitter region 12. In an example, trench portions in the boundary portion 90 are the dummy trench portions 30. The boundary portion 90 in the present example is arranged such that both ends thereof in the X axis direction become the dummy trench portions 30.

The contact hole 54 is provided above the base region 14 in the diode portion 80. The contact hole 54 is provided above the contact region 15 in the boundary portion 90. No contact hole 54 is provided above the well regions 17 provided at both ends in the Y axis direction.

A mesa portion 91 is provided in the boundary portion 90. The mesa portion 91 includes the contact region 15 at the front surface 21 of the semiconductor substrate 10. The mesa portion 91 in the present example has the base region 14 and the well region 17 on a negative side in the Y axis direction.

A mesa portion 81 is provided in a region sandwiched between the dummy trench portions 30 adjacent to each other in the diode portion 80. The mesa portion 81 includes the base region 14 at the front surface 21 of the semiconductor substrate 10. The mesa portion 81 in the present example includes the well region 17 on the negative side in the Y axis direction.

The emitter region 12 is provided in the mesa portion 71, but does not need to be provided in the mesa portion 81 and the mesa portion 91. The contact region 15 is provided in the mesa portion 71 and the mesa portion 91, but does not need to be provided in the mesa portion 81.

FIG. 2B illustrates an example of a cross section b-b′ in FIG. 2A. The semiconductor device 100 in the present example includes the back surface side lifetime control region 151 and a front surface side lifetime control region 152. It is to be noted that the semiconductor device 100 may not include one of the back surface side lifetime control region 151 or the front surface side lifetime control region 152. The semiconductor device 100 in the present example includes the collector region 22 and a cathode region 82 on the back surface 23 side of the buffer region 20.

The contact region 15 is provided above the base region 14 in the mesa portion 91. The contact region 15 is provided in contact with the dummy trench portion 30 in the mesa portion 91. In another cross section, the contact region 15 may be provided at the front surface 21 in the mesa portion 71.

The accumulation region 16 is provided in the transistor portion 70 and the diode portion 80. The accumulation region 16 in the present example is provided at entire surfaces of the transistor portion 70 and the diode portion 80. It is to be noted that the accumulation region 16 does not need to be provided in the diode portion 80.

The cathode region 82 is provided below the buffer region 20 in the diode portion 80. A boundary between the collector region 22 and the cathode region 82 is the boundary between the transistor portion 70 and the diode portion 80. That is, the collector region 22 is provided below the boundary portion 90 in the present example.

The back surface side lifetime control region 151 may be provided in both the transistor portion 70 and the diode portion 80, may be provided only in the transistor portion 70, or may be provided only in the diode portion 80. Accordingly, the semiconductor device 100 in the present example can further improve a switching loss by accelerating a turn-off operation of the transistor portion 70 or a reverse recovery operation in the diode portion 80. The back surface side lifetime control region 151 may be formed by a method similar to that of the back surface side lifetime control region 151 in another example.

The front surface side lifetime control region 152 is provided on the front surface 21 side relative to a center of the semiconductor substrate 10 in the depth direction of the semiconductor substrate 10. The front surface side lifetime control region 152 in the present example is provided in the drift region 18. The front surface side lifetime control region 152 may be provided in both the transistor portion 70 and the diode portion 80, or may be provided only in the diode portion 80. The front surface side lifetime control region 152 may be provided in the diode portion 80 and the boundary portion 90 and not be provided in a part of the transistor portion 70. The front surface side lifetime control region 152 can suppress implantation of holes from the transistor portion 70 and the diode portion 80, to reduce a reverse recovery loss.

The front surface side lifetime control region 152 may be formed by any method of the methods for forming the back surface side lifetime control region 151. An element, a dose amount, and the like for forming the back surface side lifetime control region 151 may be the same as or different from those for forming the front surface side lifetime control region 152.

The front surface side lifetime control region 152 is provided to extend from the diode portion 80 to the transistor portion 70. The front surface side lifetime control region 152 may be formed by introducing a lifetime killer from the front surface 21 of the semiconductor substrate 10. The front surface side lifetime control region 152 may also be formed by irradiation from the back surface 23 side of the semiconductor substrate 10. The front surface side lifetime control region 152 in the present example is provided below the gate trench portion 40. Particle beams or the like for forming the front surface side lifetime control region 152 may pass through the MOS gate structure of the semiconductor device 100, thereby causing defects at an interface between a gate oxide film and the semiconductor substrate.

The semiconductor device 100 may be a power semiconductor device for performing power control or the like. The semiconductor device 100 in the present example may have a vertical semiconductor structure in which the back surface side metal layer is provided on the back surface 23 side of the semiconductor substrate 10. It is to be noted that the semiconductor device 100 may have a horizontal semiconductor structure in which the metal layer is not provided on the back surface 23 side.

Note that, in the present example, an RC-IGBT having a trench gate structure is described as an example of the semiconductor device 100. It is to be noted that the semiconductor device 100 may be a semiconductor device having a planar gate structure, or may be another semiconductor device such as a diode. The semiconductor device 100 may include an N-channel MOSFET or P-channel MOSFET.

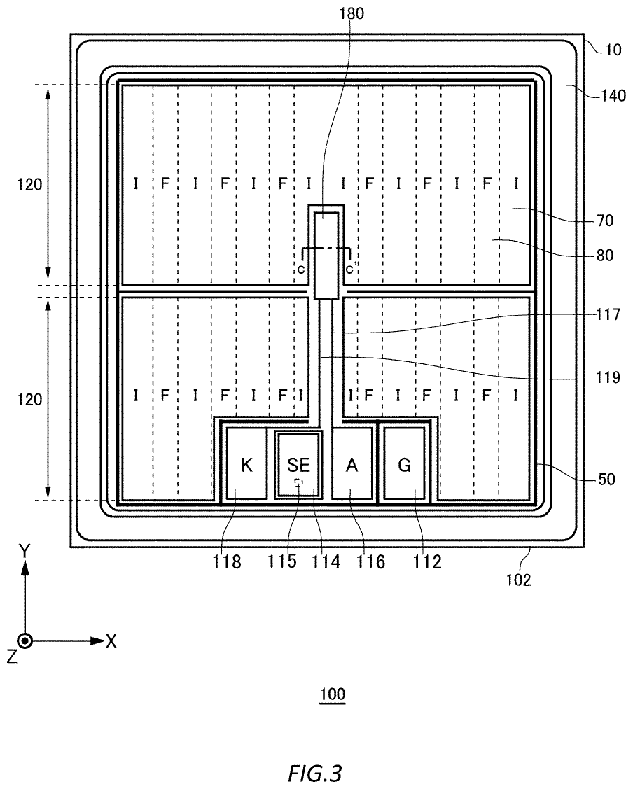

FIG. 3 illustrates an example of a top view of the semiconductor device 100. The semiconductor device 100 in the present example includes a temperature sensitive portion 180. In the present example, merely some members of the semiconductor device 100 are illustrated, and illustration of some members is omitted.

The semiconductor substrate 10 has an end side 102 in top view. The semiconductor substrate 10 in the present example has two sets of end sides 102 facing each other in top view. In the present example, the X axis and the Y axis are parallel to any of the end sides 102.

The semiconductor substrate 10 is provided with the active portion 120. The active portion 120 is a region through which a principal current flows in the depth direction between the front surface 21 and the back surface 23 of the semiconductor substrate 10 when the semiconductor device 100 is operated. The emitter electrode 52 is provided above the active portion 120, but is omitted in the present drawing.

The active portion 120 may be provided with at least one of the transistor portion 70 including a transistor element such as an IGBT or the diode portion 80 including a diode element such as a free wheel diode (FWD). In the example of FIG. 3, the transistor portions 70 and the diode portions 80 are alternately arranged along a predetermined array direction (the X axis direction in the present example) in the front surface 21 of the semiconductor substrate 10. In another example, the active portion 120 may be provided with only one of the transistor portion 70 and the diode portion 80. That is, only the transistor portion 70 may be provided in the active portion 120 as illustrated in FIG. 1A, both the transistor portion 70 and the diode portion 80 may be provided as illustrated in FIG. 2A, or only the diode portion 80 may be provided.

In the present example, a region where the transistor portion 70 is arranged is indicated by a symbol “I”, and a region where the diode portion 80 is arranged is indicated by a symbol “F”. Each of the transistor portion 70 and the diode portion 80 may be elongated in an extending direction. In other words, a length of the transistor portion 70 in the Y axis direction is larger than its width in the X axis direction. Similarly, a length of the diode portion 80 in the Y axis direction is larger than its width in the X axis direction. The extending direction of the transistor portion 70 and the diode portion 80 may be the same as a longitudinal direction of the gate trench portion 40 and the dummy trench portion 30.

The diode portion 80 may be a region obtained by projecting the cathode region 82 provided on the back surface 23 side of the semiconductor substrate 10 onto the upper surface of the semiconductor substrate 10. The region obtained by projecting the cathode region 82 on the upper surface of the semiconductor substrate 10 may be located inside from the diode portion 80. In the back surface 23 of the semiconductor substrate 10, the collector region 22 of the P+ type may be provided in a region other than the cathode region 82.

An edge termination structure portion 140 is provided at the front surface 21 of the semiconductor substrate 10. The edge termination structure portion 140 is provided between the active portion 120 and the end side 102 in top view. The edge termination structure portion 140 reduces electric field strength on the front surface 21 side of the semiconductor substrate 10. The edge termination structure portion 140 may include at least one of a guard ring, a field plate, or a RESURF which is annularly provided to enclose the active portion 120.

The semiconductor device 100 may include one or more pads above the semiconductor substrate 10. The semiconductor device 100 in the present example includes a gate pad 112, a sensing electrode 114, an anode pad 116, and a cathode pad 118. Each pad may be arranged in a vicinity of the end side 102 of the semiconductor substrate 10. The vicinity of the end side 102 refers to a region between the end side 102 and the emitter electrode 52 in top view. When the semiconductor device 100 is mounted, each pad may be connected to an external circuit via a wiring line such as a wire.

A gate potential is applied to the gate pad 112. The gate pad 112 is electrically connected to the gate conductive portion 44 of the gate trench portion 40 of the active portion 120. The semiconductor device 100 may include a gate runner which connects the gate pad 112 and the gate trench portion 40. The gate runner may be constituted by either one of the gate metal layer 50 or the connection portion 25, or may be constituted by a combination of both as appropriate.

The sensing electrode 114 is electrically connected to a current sensing portion 115 provided below the sensing electrode 114. The sensing electrode 114 detects a current flowing through the current sensing portion 115. The current sensing portion 115 detects a current flowing through the transistor portion 70. The current sensing portion 115 has a structure corresponding to the transistor portion 70. A current flowing through the current sensing portion 115 is smaller than the current flowing through the transistor portion 70. In the current sensing portion 115, a current proportional to the current flowing through the transistor portion 70 may flow by simulating an operation of the transistor portion 70. A ratio of the current flowing through the current sensing portion 115 to the current flowing through the transistor portion 70 is appropriately set. By using the current sensing portion 115, the current flowing through the transistor portion 70 can be monitored.

The temperature sensitive portion 180 is provided above or inside the semiconductor substrate 10. The temperature sensitive portion 180 in the present example is provided between the transistor portions 70 in a central portion of the semiconductor device 100. The temperature sensitive portion 180 senses a temperature of the active portion 120. The temperature sensitive portion 180 may include a diode formed of monocrystalline or polycrystalline silicon. The temperature sensitive portion 180 is used to detect a temperature of the semiconductor device 100 and protect the semiconductor chip (semiconductor substrate 10) from overheating. The temperature sensitive portion 180 is connected to a constant current source. When the temperature of the semiconductor device 100 changes, a forward voltage of a current flowing through the temperature sensitive portion 180 changes. The semiconductor device 100 can detect the temperature based on the change in the forward voltage of the temperature sensitive portion 180.

The anode pad 116 is electrically connected to a temperature sensitive anode region 182 of the temperature sensitive portion 180. The anode pad 116 is electrically connected to the temperature sensitive anode region 182 of the temperature sensitive portion 180 by an anode wiring portion 117 electrically connected to the temperature sensitive anode region 182. The temperature sensitive anode region 182 will be described below.

The cathode pad 118 is electrically connected to a temperature sensitive cathode region 181 of the temperature sensitive portion 180. The cathode pad 118 is electrically connected to the temperature sensitive cathode region 181 of the temperature sensitive portion 180 by a cathode wiring portion 119 electrically connected to the temperature sensitive cathode region 181. The temperature sensitive cathode region 181 will be described below.

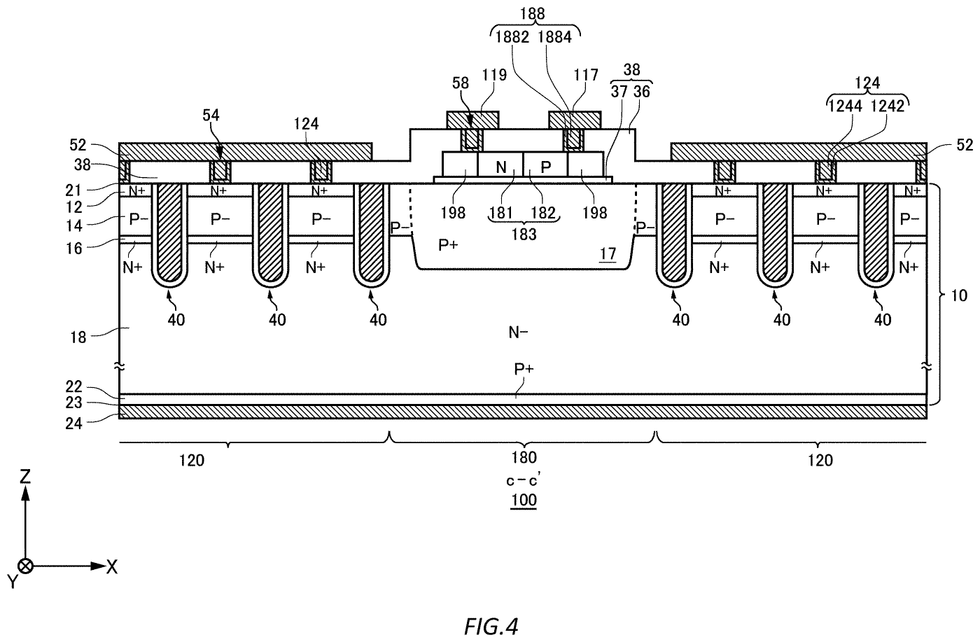

FIG. 4 illustrates an example of a cross section of the semiconductor device 100 including the temperature sensitive portion 180. The temperature sensitive portion 180 includes a temperature sensitive diode 183, a first interlayer dielectric film 36, a temperature sensitive contact portion 188, and a housing portion 198. The temperature sensitive portion 180 may include a second interlayer dielectric film 37.

The temperature sensitive diode 183 is provided above the semiconductor substrate 10. The temperature sensitive diode 183 may be a PN diode including a temperature sensitive anode region 182 which is provided above the semiconductor substrate 10 and a temperature sensitive cathode region 181 which is provided above the semiconductor substrate 10 and is provided in contact with the temperature sensitive anode region 182. The temperature sensitive cathode region 181 is formed of a semiconductor of the N type and may function as a cathode of the PN diode. The temperature sensitive anode region 182 is formed of a semiconductor of the P type, and may function as an anode of the PN diode. Materials of the temperature sensitive cathode region 181 and the temperature sensitive anode region 182 may be a polycrystalline semiconductor, and may be polysilicon as an example.

Below the temperature sensitive diode 183, the well region 17 may be provided in the semiconductor substrate 10. The well region 17 provided below the temperature sensitive diode 183 may be the same as the well region 17 provided on the peripheral side of the active portion 120 in FIG. 1A, or may be formed in the same step.

The first interlayer dielectric film 36 is provided above the temperature sensitive diode 183. The term “above” may be a positive direction in the Z axis direction with respect to the front surface 21 of the semiconductor substrate 10. The first interlayer dielectric film 36 may be the interlayer dielectric film 38. That is, the interlayer dielectric film 38 may be a concept including both the first interlayer dielectric film 36 and a second interlayer dielectric film 37 to be described below. The first interlayer dielectric film 36 may be a BPSG film, a BSG film, a PSG film, an HTO film, or a stack of these materials.

The temperature sensitive contact portion 188 is provided to extend from an upper surface to a lower surface of the first interlayer dielectric film 36. The contact hole 58 may be provided to penetrate the first interlayer dielectric film 36. The temperature sensitive contact portion 188 may include the contact hole 58 and a metal layer with which an inside of the contact hole 58 is filled. A detailed configuration of the temperature sensitive contact portion 188 will be described below.

The cathode wiring portion 119 is electrically connected to the temperature sensitive cathode region 181 via the contact hole 58. The cathode wiring portion 119 may be formed of a metal material. The cathode wiring portion 119 may be formed of the same material as that of the emitter electrode 52. The temperature sensitive cathode region 181 may be electrically connected to the cathode pad 118 by the cathode wiring portion 119.

The anode wiring portion 117 is electrically connected to the temperature sensitive anode region 182 via the contact hole 58. The anode wiring portion 117 may be formed of a metal material. The anode wiring portion 117 may be formed of the same material as that of the emitter electrode 52. The temperature sensitive anode region 182 may be electrically connected to the anode pad 116 by the anode wiring portion 117.

The housing portion 198 is provided below the temperature sensitive contact portion 188. A material of the housing portion 198 may be the same as a material of the first interlayer dielectric film 36, the same as a material of the second interlayer dielectric film 37, or the same as a material of the temperature sensitive diode 183. A detailed configuration of the housing portion 198 will be described below.

The second interlayer dielectric film 37 may be provided between the temperature sensitive diode 183 and the semiconductor substrate 10 in the depth direction of the semiconductor substrate 10. The second interlayer dielectric film 37 may be the interlayer dielectric film 38. That is, the interlayer dielectric film 38 may be a concept including both the first interlayer dielectric film 36 and the second interlayer dielectric film 37. The second interlayer dielectric film 37 may be a BPSG film, a BSG film, a PSG film, an HTO film, or a stack of these materials.

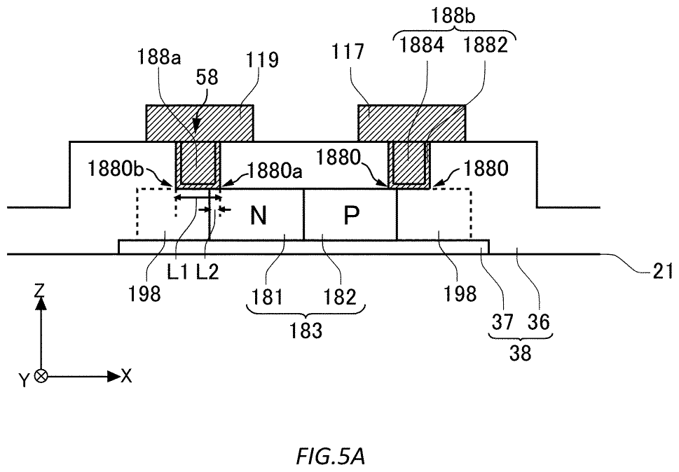

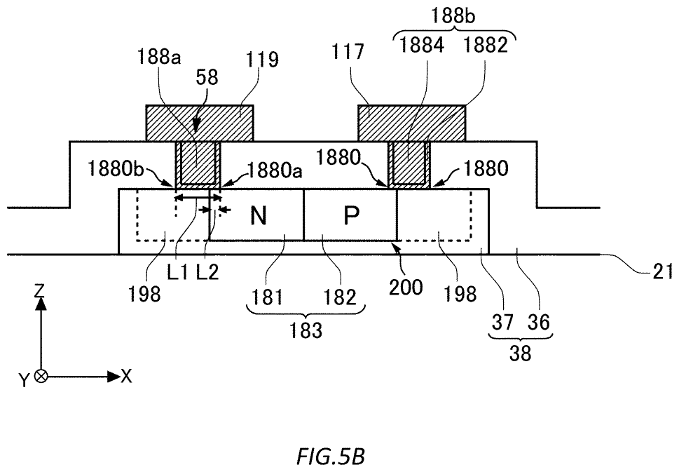

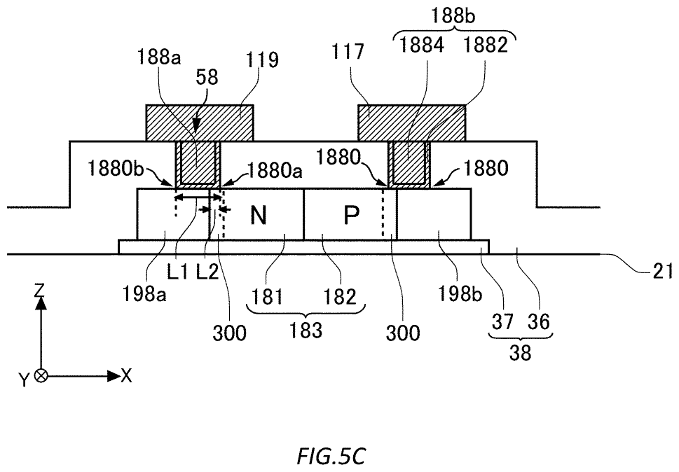

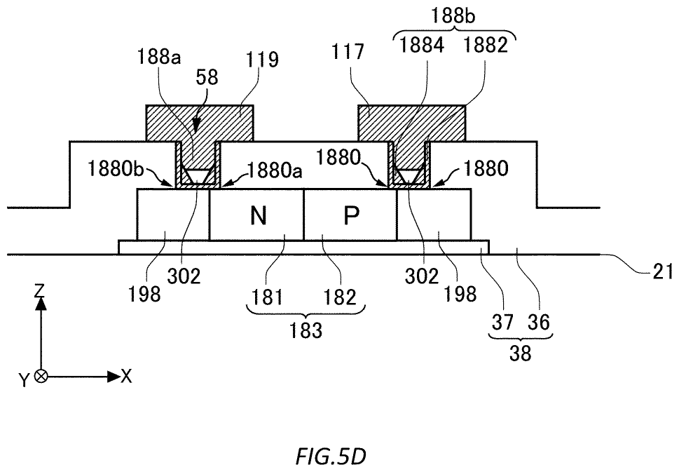

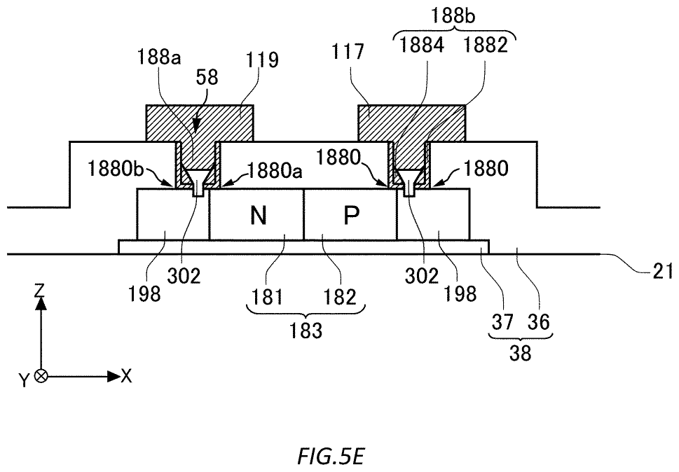

FIG. 5A illustrates an example of an enlarged view of a cross section of the semiconductor device 100. The present drawing illustrates a region above the front surface 21 of the semiconductor substrate 10 in the temperature sensitive portion 180.

A bottom surface corner portion 1880 of the temperature sensitive contact portion 188 may be in contact with the temperature sensitive diode 183. The bottom surface corner portion 1880 of the temperature sensitive contact portion 188 may be an intersection of a bottom surface of the temperature sensitive contact portion 188 and a side surface of the temperature sensitive contact portion 188. The bottom surface corner portion 1880 being in contact with the temperature sensitive diode 183 may mean being in contact with the temperature sensitive diode 183 on an upper surface of the temperature sensitive diode 183, may mean being in contact with the temperature sensitive diode 183 on a side surface of the temperature sensitive diode 183, or may mean being in contact with the temperature sensitive diode 183 in a region inside the temperature sensitive diode 183. The bottom surface corner portion 1880 in the present example is in contact with the temperature sensitive diode 183 on the upper surface of the temperature sensitive diode 183.

The temperature sensitive contact portion 188 in the present example includes two bottom surface corner portions 1880. One of the two bottom surface corner portions 1880 may be in contact with the temperature sensitive diode 183. Another of the two bottom surface corner portions 1880 may be in contact with the housing portion 198 or may not be in contact with the housing portion 198. In a temperature sensitive contact portion 188a in the present example, one bottom surface corner portion 1880a is in contact with the temperature sensitive cathode region 181 of the temperature sensitive diode 183, and another bottom surface corner portion 1880b is in contact with the housing portion 198.

The bottom surface of the temperature sensitive contact portion 188 may be in contact with the housing portion 198. The bottom surface of the temperature sensitive contact portion 188 may be a surface between two bottom surface corner portions 1880 of the temperature sensitive contact portion 188. The bottom surface of the temperature sensitive contact portion 188 being in contact with the housing portion 198 may mean that the bottom surface is in contact with the housing portion 198 on an upper surface of the housing portion 198, or may mean that the bottom surface is in contact with the housing portion 198 in a region inside the housing portion 198. In the temperature sensitive contact portion 188 in the present example, the bottom surface is in contact with the housing portion 198 on the upper surface of the housing portion 198.

The bottom surface of the temperature sensitive contact portion 188 may be in contact with the temperature sensitive diode 183 and the housing portion 198. In the temperature sensitive contact portion 188a in the present example, one bottom surface corner portion 1880a is in contact with the temperature sensitive cathode region 181 of the temperature sensitive diode 183, and another bottom surface corner portion 1880b is in contact with the housing portion 198, so that a bottom surface of the temperature sensitive contact portion 188a is in contact with the temperature sensitive diode 183 and the housing portion 198.

The temperature sensitive diode 183 may be in contact with the bottom surface of the temperature sensitive contact portion 188, from the bottom surface corner portion 1880 to a region of 10% or more and 40% or less of the bottom surface of the temperature sensitive contact portion 188. That is, a ratio of an area of a surface, which is in contact with the temperature sensitive diode 183, in the bottom surface of the temperature sensitive contact portion 188 to an area of the bottom surface of the temperature sensitive contact portion 188 may be 10% or more and 40% or less. With reference to FIG. 5A, a length L1 is a length of the bottom surface of the temperature sensitive contact portion 188 in a cross section perpendicular to the front surface 21 of the semiconductor substrate 10. A length L2 is a length of the bottom surface, which is in contact with the temperature sensitive diode 183, in the bottom surface of the temperature sensitive contact portion 188 in the cross section perpendicular to the front surface 21 of the semiconductor substrate 10. Therefore, a ratio of the length L2 to the length L1 may be 10% or more and 40% or less. The temperature sensitive diode 183 in the present example is in contact with the bottom surface of the temperature sensitive contact portion 188a, from the bottom surface corner portion 1880a to the region of 25% of the bottom surface of the temperature sensitive contact portion 188. That is, the ratio of the length L2 to the length L1 in the present example is 25%.

In above description, the bottom surface of the temperature sensitive contact portion 188a in contact with the temperature sensitive cathode region 181, the bottom surface corner portion 1880a, and the bottom surface corner portion 1880b have been described as examples, but the same may be applied to the temperature sensitive contact portion 188b in contact with the temperature sensitive anode region 182. That is, the bottom surface corner portion 1880 of the temperature sensitive contact portion 188b may be in contact with the temperature sensitive diode 183, a bottom surface of the temperature sensitive contact portion 188b may be in contact with the housing portion 198, the bottom surface of the temperature sensitive contact portion 188b may be in contact with the temperature sensitive diode 183 and the housing portion 198, and the temperature sensitive diode 183 may be in contact with the bottom surface of the temperature sensitive contact portion 188b, from the bottom surface corner portion 1880 to a region of 10% or more and 40% or less of the bottom surface of the temperature sensitive contact portion 188b. In addition, the length L1 and the length L2 for the temperature sensitive contact portion 188b may also satisfy the same condition as that of the lengths for the temperature sensitive contact portion 188a.

The temperature sensitive contact portion 188 in the present example is provided such that the bottom surface corner portion 1880 is in contact with the temperature sensitive diode 183 and its bottom surface is in contact with the housing portion 198. Accordingly, it is possible to reliably secure electrical connection between the anode pad 116 and the cathode pad 118, and the temperature sensitive diode 183. In the etch-back step of the plug portion 1884, when the plug portion 1884 and the barrier metal film 1882 near a center of the bottom surface of the temperature sensitive contact portion 188 are removed due to over-etching, a void may be generated inside the temperature sensitive contact portion 188. Even in this case, the electrical connection can be secured by the barrier metal film 1882 and/or the plug portion 1884 remaining at the bottom surface corner portion 1880 of the temperature sensitive contact portion 188. The barrier metal film 1882 and the plug portion 1884 will be described below.

The bottom surface of the temperature sensitive contact portion 188 in the present example is provided in contact with the housing portion 198. Therefore, even when a void is generated inside the temperature sensitive contact portion, near the center of its bottom surface, an influence on electrical connection at the bottom surface corner portion 1880 between the temperature sensitive contact portion 188 and the temperature sensitive diode 183 is suppressed. Accordingly, it is possible to improve a yield of the semiconductor device 100 having desired characteristics. In the electrical connection between the temperature sensitive contact portion 188 and the temperature sensitive diode 183, the temperature sensitive portion 180 in the present example secures the electrical connection through the bottom surface corner portion 1880, rather than a central portion of the bottom surface of the temperature sensitive contact portion 188. As a result, even when a void is formed in a region near the center of the temperature sensitive contact portion 188 in contact with the housing portion 198, it is possible to obtain stable quality and improve the yield.

The temperature sensitive contact portion 188 may include the barrier metal film 1882 and the plug portion 1884. The barrier metal film 1882 and the plug portion 1884 in the present example are formed of different materials, but may be formed of the same material.

The barrier metal film 1882 may be provided on the bottom surface corner portion 1880 of the temperature sensitive contact portion 188. The barrier metal film 1882 in the present example is provided over the entire side surfaces and bottom surface of the temperature sensitive contact portion 188, but is not limited thereto. The barrier metal film 1882 may be provided so as to cover at least the bottom surface corner portion 1880, or may be provided without covering the central portion of the bottom surface of the temperature sensitive contact portion 188. The barrier metal film 1882 may be provided to protrude from the contact hole 58 and reach above the first interlayer dielectric film 36. A material of the barrier metal film 1882 may be titanium, a titanium compound, or the like.

The plug portion 1884 may be provided in contact with an inside of the barrier metal film 1882. The plug portion 1884 in the present example is provided to fill the temperature sensitive contact portion 188, but is not limited thereto. The plug portion 1884 may be provided in a part of the temperature sensitive contact portion 188, and may be provided to protrude from the contact hole 58 and reach above the first interlayer dielectric film 36. When the plug portion 1884 is provided in a part of the temperature sensitive contact portion 188, a remaining region of the temperature sensitive contact portion 188 may be filled with the same material as that of the anode wiring portion 117 or the cathode wiring portion 119. A material of the plug portion 1884 may be a plug metal such as tungsten.

The side surface of the temperature sensitive diode 183 may be in contact with a side surface of the housing portion 198. In the temperature sensitive diode 183 in the present example, a side surface of each of the temperature sensitive cathode region 181 and the temperature sensitive anode region 182 is in contact with the side surface of the housing portion 198.

An upper surface of the second interlayer dielectric film 37 may be in contact with a lower surface of the temperature sensitive diode 183 and a lower surface of the housing portion 198. The upper surface of the second interlayer dielectric film 37 in the present example is provided in contact with the lower surface of the housing portion 198 provided in contact with the temperature sensitive cathode region 181, a lower surface of the temperature sensitive cathode region 181, the lower surface of the temperature sensitive anode region 182, and the lower surface of the housing portion 198 provided in contact with the temperature sensitive anode region 182.

The housing portion 198 may be a region, which is provided below the temperature sensitive contact portion 188, in the first interlayer dielectric film 36. The housing portion 198 may be formed in a step of providing the first interlayer dielectric film 36, and may be formed of the same material as that of the first interlayer dielectric film 36. When the housing portion 198 is formed as the region, which is provided below the temperature sensitive contact portion 188, in the first interlayer dielectric film 36, the housing portion 198 is a virtual region as indicated by a dotted line in FIG. 5A. That is, the housing portion 198 may be integrally formed as a part of the first interlayer dielectric film 36.

FIG. 5B illustrates an enlarged view of a cross section of a modification of the semiconductor device 100. The present drawing illustrates the region above the front surface 21 of the semiconductor substrate 10 in the temperature sensitive portion 180. The semiconductor device 100 in the present example is different from that in the example of FIG. 5A in that shapes of the first interlayer dielectric film 36 and the second interlayer dielectric film 37 are different. In the present example, the difference from the example of FIG. 5A will be particularly described, and other configurations may be the same as those in the example of FIG. 5A.

The second interlayer dielectric film 37 may include a recess 200 on its upper surface side. The temperature sensitive diode 183 may be provided in the recess 200 of the second interlayer dielectric film 37. The recess 200 may be formed by etching the upper surface of the second interlayer dielectric film 37. The upper surface of the temperature sensitive diode 183 in the present example may be the same as an upper surface of the recess 200 or may be lower than the upper surface of the recess 200.

The housing portion 198 may be the second interlayer dielectric film 37 provided above the semiconductor substrate 10. The housing portion 198 may be formed in a step of providing the second interlayer dielectric film 37, and may be formed of the same material as that of the second interlayer dielectric film 37. When the housing portion 198 is formed as the second interlayer dielectric film 37, the housing portion 198 is a virtual region as indicated by a dotted line in FIG. 5B. That is, the housing portion 198 may be integrally formed as a part of the second interlayer dielectric film 37. Note that when the upper surface of the temperature sensitive diode 183 is above the upper surface of the recess 200, the lower end of the temperature sensitive contact portion 188 does not reach the second interlayer dielectric film 37 but is located in the first interlayer dielectric film 36. The housing portion 198 may be considered as a part of the first interlayer dielectric film 36, or may be considered as consisting of both the first interlayer dielectric film 36 and the second interlayer dielectric film 37. In addition, even when the second interlayer dielectric film 37 has a narrow part not having the recess 200, and the lower end of the temperature sensitive contact portion 188 is located at a boundary between the first interlayer dielectric film 36 and the second interlayer dielectric film 37, the housing portion 198 may be considered as a part of the second interlayer dielectric film 37, or may be considered as consisting of both the first interlayer dielectric film 36 and the second interlayer dielectric film 37.

FIG. 5C illustrates an enlarged view of a cross section of a modification of the semiconductor device 100. The present drawing illustrates the region above the front surface 21 of the semiconductor substrate 10 in the temperature sensitive portion 180. The semiconductor device 100 in the present example is different from those in the examples of FIGS. 5A and 5B in that the housing portion 198 is provided separately from the first interlayer dielectric film 36 and the second interlayer dielectric film 37. In the present example, the difference from the examples of FIGS. 5A and 5B will be particularly described, and other configurations may be the same as those in the examples of FIGS. 5A and/or 5B. The housing portion 198 in the present example is provided in a region of the first interlayer dielectric film 36 corresponding to the housing portion 198 of FIG. 5A, but may be provided in a region of the second interlayer dielectric film 37 corresponding to the housing portion 198 of FIG. 5B.

The housing portion 198 may include polysilicon of a conductivity type different from that of a contact region 300 of the temperature sensitive diode 183. The contact region 300 of the temperature sensitive diode 183 may be the temperature sensitive cathode region 181 or the temperature sensitive anode region 182 of the temperature sensitive diode 183 in contact with the housing portion 198.

A housing portion 198a in the present example is in contact with the temperature sensitive cathode region 181. Therefore, the housing portion 198a may have polysilicon of a conductivity type different from that of the temperature sensitive cathode region 181 which is the contact region 300 of the temperature sensitive diode 183. That is, the housing portion 198a may have polysilicon of the P type or non-doped polysilicon.

A housing portion 198b in the present example is in contact with the temperature sensitive anode region 182. Therefore, the housing portion 198b may have polysilicon of a conductivity type different from that of the temperature sensitive anode region 182 which is the contact region 300 of the temperature sensitive diode 183. That is, the housing portion 198b may have polysilicon of the N type or non-doped polysilicon.

In the temperature sensitive contact portion 188 in the present example, the bottom surface corner portion 1880 of the temperature sensitive contact portion 188 is in contact with the temperature sensitive diode 183. The temperature sensitive contact portion 188 in the present example is provided such that the bottom surface of the temperature sensitive contact portion 188 is in contact with the housing portion 198. The housing portion 198 and the contact region 300 of the temperature sensitive diode 183 in contact with the housing portion 198 may have the same potential.

When the housing portion 198 and the contact region 300 of the temperature sensitive diode 183 have the same potential, no current flows between the housing portion 198 and the temperature sensitive diode 183, and an operation of the temperature sensitive diode 183 is not affected by the housing portion 198. As an example, when the housing portion 198a has polysilicon of the P type which is a conductivity type different from that of the temperature sensitive cathode region 181, the housing portion 198a and the temperature sensitive cathode region 181 have the same potential, so that substantially no current flows through a PN junction at a contact interface. Therefore, the operation of the temperature sensitive diode 183 is not affected by the housing portion 198. Similarly, even when the housing portion 198b has polysilicon of the N type which is a conductivity type different from that of the temperature sensitive anode region 182, the housing portion 198b and the temperature sensitive anode region 182 have the same potential, so that the PN junction at the contact interface does not function and the operation of the temperature sensitive diode 183 is not hindered.

The housing portion 198 may have the same conductivity type as that of the contact region 300 of the temperature sensitive diode 183, and may have polysilicon having a doping concentration lower than that of the contact region 300. The housing portion 198a in the present example is in contact with the temperature sensitive cathode region 181. Therefore, the housing portion 198a may have the same conductivity type as that of the temperature sensitive cathode region 181 which is the contact region 300 of the temperature sensitive diode 183, and may have polysilicon having a doping concentration lower than that of the temperature sensitive cathode region 181. That is, the housing portion 198a may have polysilicon of the N− type. The housing portion 198b in the present example is in contact with the temperature sensitive anode region 182. Therefore, the housing portion 198b may have the same conductivity type as that of the temperature sensitive anode region 182 which is the contact region 300 of the temperature sensitive diode 183, and may have polysilicon having a doping concentration lower than that of the temperature sensitive anode region 182. That is, the housing portion 198b may have polysilicon of the P− type.

Even when the housing portion 198 has the same conductivity type as that of the contact region 300 of the temperature sensitive diode 183, a doping concentration of the housing portion 198 is lower than the doping concentration of the contact region 300, so that an influence on the operation of the temperature sensitive diode 183 is small. Therefore, the housing portion 198 hardly hinders the operation of the temperature sensitive diode 183.

As described above, the housing portion 198a in contact with the temperature sensitive cathode region 181 of the temperature sensitive diode 183 may have polysilicon of the P type, non-doped polysilicon, or polysilicon of the N− type, and the housing portion 198b in contact with the temperature sensitive anode region 182 of the temperature sensitive diode 183 may have polysilicon of the N type, non-doped polysilicon, or polysilicon of the P− type. Note that when a width of polysilicon is narrow, a part of the lower end of the temperature sensitive contact portion 188 may come into contact with the interlayer dielectric film 38. In this case, it can also be considered that the housing portion 198 consists of a mixed form of polysilicon and the first interlayer dielectric film 36 and/or the second interlayer dielectric film 37.

FIG. 5D illustrates an example of an enlarged view of a cross section of the semiconductor device 100 when a void 302 is generated in the temperature sensitive contact portion 188. The present example illustrates a case where, in the etch-back step of the plug portion 1884, the plug portion 1884 near the center of the bottom surface of the temperature sensitive contact portion 188 is removed due to over-etching. In this case, it is difficult to fill the temperature sensitive contact portion 188 with the metal material of the anode wiring portion 117 or the cathode wiring portion 119, and the void 302 may be generated near the center of the bottom surface of the temperature sensitive contact portion 188.

The temperature sensitive contact portion 188 in the present example is provided such that the bottom surface corner portion 1880 is in contact with the temperature sensitive diode 183 and its bottom surface is in contact with the housing portion 198. Therefore, even when the void 302 is generated inside the temperature sensitive contact portion, near the center of its bottom surface, the influence on the electrical connection at the bottom surface corner portion 1880 between the temperature sensitive contact portion 188 and the temperature sensitive diode 183 is suppressed. Accordingly, it is possible to improve the yield of the semiconductor device 100 having desired characteristics. In the electrical connection between the temperature sensitive contact portion 188 and the temperature sensitive diode 183, the temperature sensitive portion 180 in the present example secures the electrical connection through the bottom surface corner portion 1880, rather than the central portion of the bottom surface of the temperature sensitive contact portion 188. As a result, even when the void 302 is formed in the region near the center of the temperature sensitive contact portion 188 in contact with the housing portion 198, it is possible to obtain stable quality and improve the yield.

FIG. 5E illustrates another example of the enlarged view of the cross section of the semiconductor device 100 when the void 302 is generated in the temperature sensitive contact portion 188. The present example illustrates a case where, in the etch-back step of the plug portion 1884, the plug portion 1884 and the barrier metal film 1882 near the center of the bottom surface of the temperature sensitive contact portion 188 are removed due to over-etching, and further, the housing portion 198 is also over-etched. In this case, it is difficult to fill the temperature sensitive contact portion 188 with the metal material of the anode wiring portion 117 or the cathode wiring portion 119, and the void 302 may be generated near the center of the bottom surface of the temperature sensitive contact portion 188.

In the electrical connection between the temperature sensitive contact portion 188 and the temperature sensitive diode 183, the temperature sensitive portion 180 in the present example secures the electrical connection through the bottom surface corner portion 1880, rather than the central portion of the bottom surface of the temperature sensitive contact portion 188. As a result, similarly to the example of FIG. 5D, even when the void 302 is formed in the region near the center of the temperature sensitive contact portion 188 in contact with the housing portion 198, it is possible to obtain stable quality and improve the yield.

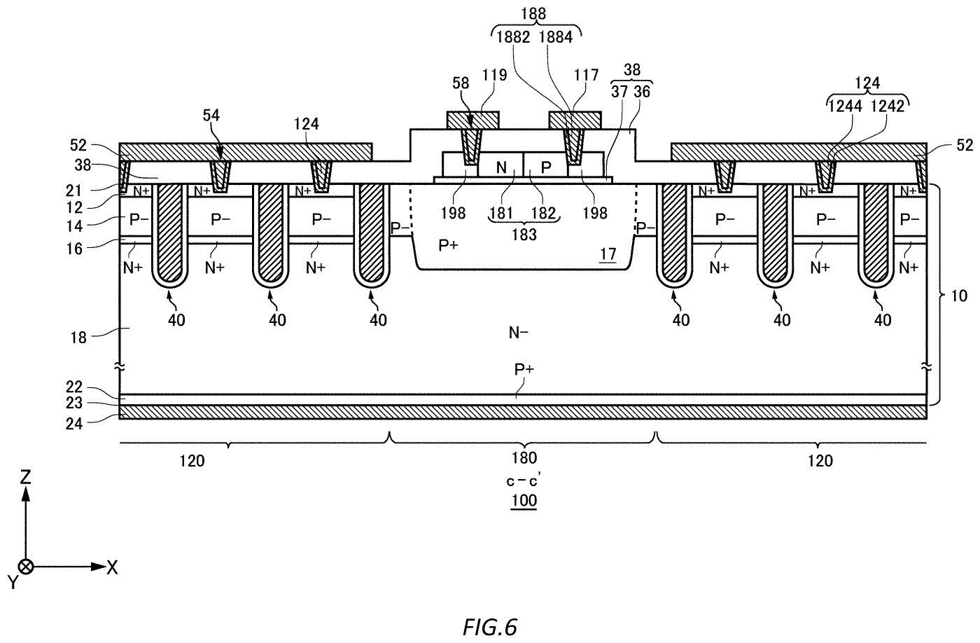

FIG. 6 illustrates a cross section of a modification of the semiconductor device 100 including the temperature sensitive portion 180. The semiconductor device 100 in the present example is different from that in the example of FIG. 4 in that the temperature sensitive contact portion 188 and the active contact portion 124 have a trench contact structure. Other configurations may be the same as those in the example of FIG. 4. When the temperature sensitive contact portion 188 has a trench contact structure, the temperature sensitive contact portion 188 may extend from the upper surface of the temperature sensitive diode 183 in the depth direction of the semiconductor substrate 10. When the active contact portion 124 has a trench contact structure, the active contact portion 124 may extend from the front surface 21 in the depth direction of the semiconductor substrate 10. The bottom surface of the active contact portion 124 may be shallower or deeper than the lower end of the emitter region in the depth direction of the semiconductor substrate 10.

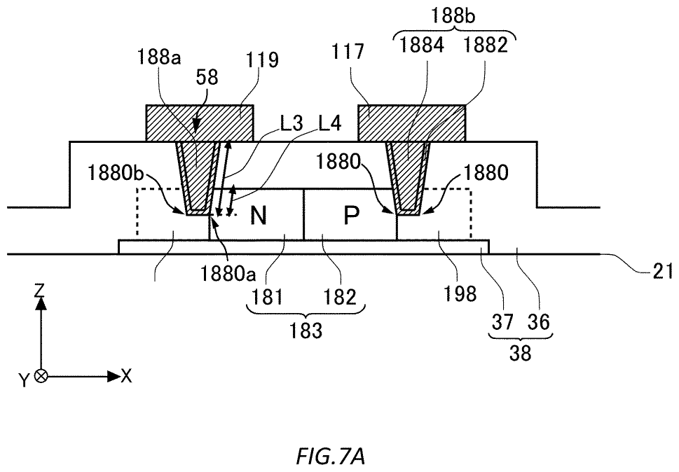

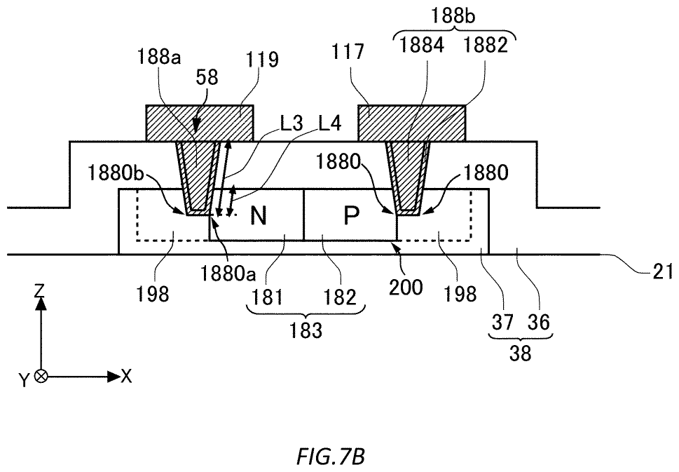

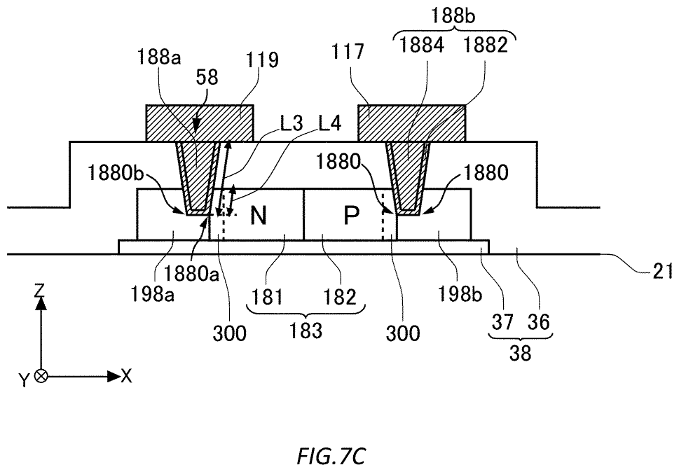

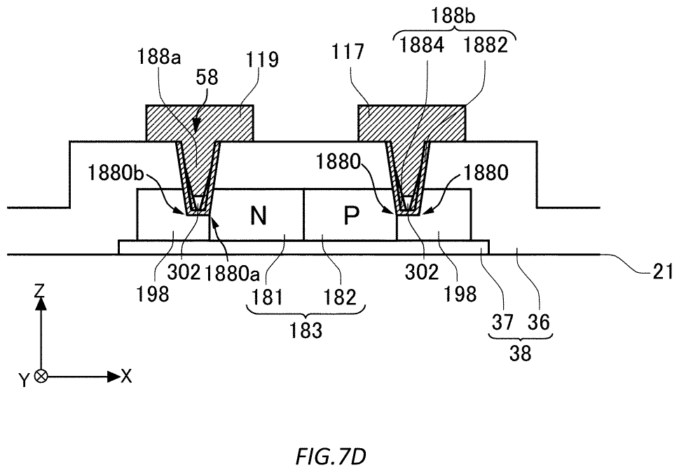

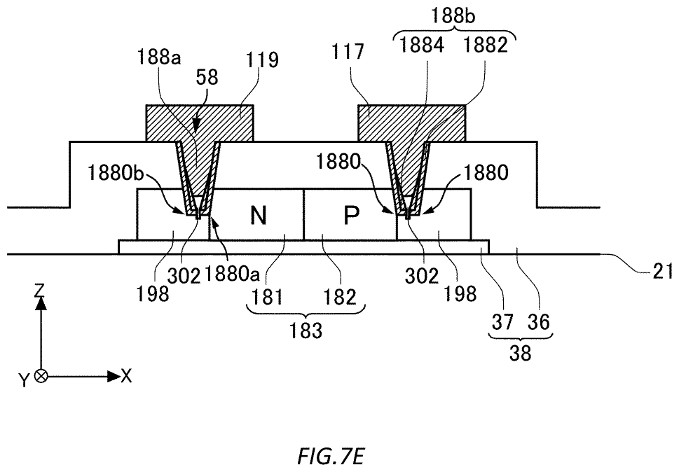

FIG. 7A illustrates an enlarged view of a cross section of a modification of the semiconductor device 100. The present drawing illustrates the region above the front surface 21 of the semiconductor substrate 10 in the temperature sensitive portion 180. The semiconductor device 100 in the present example is different from that in the example of FIG. 5A in that the temperature sensitive contact portion 188 is different in structure. In the present example, the difference from the example of FIG. 5A will be particularly described, and other configurations may be the same as those in the example of FIG. 5A.

Side walls of the temperature sensitive contact portion 188 may have a trench contact structure in contact with the side surface of the temperature sensitive diode 183. The bottom surface corner portion 1880 of the temperature sensitive contact portion 188 in the present example is in contact with the temperature sensitive diode 183 on the side surface of the temperature sensitive diode 183.

A side wall of the temperature sensitive contact portion 188 may be in contact with the temperature sensitive diode 183 and the first interlayer dielectric film 36. The temperature sensitive diode 183 may be in contact with the side wall of the temperature sensitive contact portion 188, from the bottom surface corner portion 1880 to a region of 10% or more and 90% or less of the side wall of the temperature sensitive contact portion. That is, a ratio of an area of the side wall, which is in contact with the temperature sensitive diode 183, in the side wall of the temperature sensitive contact portion 188 to an area of the side wall, on a side in contact with the temperature sensitive diode 183, among the side walls of the temperature sensitive contact portion 188 may be 10% or more and 90% or less. With reference to FIG. 7A, a length L3 is a length of the side wall of the temperature sensitive contact portion 188 in the cross section perpendicular to the front surface 21 of the semiconductor substrate 10, and a length L4 is a length of the side wall, which is in contact with the temperature sensitive diode 183, in the side wall of the temperature sensitive contact portion 188 in the cross section perpendicular to the front surface 21 of the semiconductor substrate 10. Therefore, a ratio of the length L4 to the length L3 may be 10% or more and 90% or less. The temperature sensitive diode 183 in the present example is in contact with the side wall of the temperature sensitive contact portion 188, from the bottom surface corner portion 1880 to a region of 36% of the side wall of the temperature sensitive contact portion 188. That is, the ratio of the length L4 to the length L3 in the present example is 36%.

FIG. 7B illustrates an enlarged view of a cross section of a modification of the semiconductor device 100. The present drawing illustrates the region above the front surface 21 of the semiconductor substrate 10 in the temperature sensitive portion 180. The semiconductor device 100 in the present example is different from that in the example of FIG. 7A in that the housing portion 198 is the second interlayer dielectric film 37 provided above the semiconductor substrate 10. Other configurations may be the same as those in the example of FIG. 7A.

FIG. 7C illustrates an enlarged view of a cross section of a modification of the semiconductor device 100. The present drawing illustrates the region above the front surface 21 of the semiconductor substrate 10 in the temperature sensitive portion 180. The semiconductor device 100 in the present example is different from those in the examples of FIGS. 7A and 7B in that the housing portion 198 includes polysilicon. Other configurations may be the same as those in the examples of FIGS. 7A and/or 7B.

FIG. 7D illustrates an example of an enlarged view of a cross section of the semiconductor device 100 when the void 302 is generated in the temperature sensitive contact portion 188. The present example illustrates a case where, in the etch-back step of the plug portion 1884, the plug portion 1884 near the center of the bottom surface of the temperature sensitive contact portion 188 is removed due to over-etching. In this case, it is difficult to fill the temperature sensitive contact portion 188 with the metal material of the anode wiring portion 117 or the cathode wiring portion 119, and the void 302 may be generated near the center of the bottom surface of the temperature sensitive contact portion 188.

The temperature sensitive contact portion 188 in the present example is provided such that the bottom surface corner portion 1880 is in contact with the temperature sensitive diode 183 and its bottom surface is in contact with the housing portion 198. Therefore, even when the void 302 is generated inside the temperature sensitive contact portion, near the center of its bottom surface, the influence on the electrical connection at the bottom surface corner portion 1880 between the temperature sensitive contact portion 188 and the temperature sensitive diode 183 is suppressed. Accordingly, it is possible to improve the yield of the semiconductor device 100 having desired characteristics. In the electrical connection between the temperature sensitive contact portion 188 and the temperature sensitive diode 183, the temperature sensitive portion 180 in the present example secures the electrical connection through the bottom surface corner portion 1880, rather than the central portion of the bottom surface of the temperature sensitive contact portion 188. As a result, even when the void 302 is formed in the region near the center of the temperature sensitive contact portion 188 in contact with the housing portion 198, it is possible to obtain stable quality and improve the yield.

FIG. 7E illustrates another example of the enlarged view of the cross section of the semiconductor device 100 when the void 302 is generated in the temperature sensitive contact portion 188. The present example illustrates a case where, in the etch-back step of the plug portion 1884, the plug portion 1884 and the barrier metal film 1882 near the center of the bottom surface of the temperature sensitive contact portion 188 are removed due to over-etching, and further, the housing portion 198 is also over-etched. In this case, it is difficult to fill the temperature sensitive contact portion 188 with the metal material of the anode wiring portion 117 or the cathode wiring portion 119, and the void 302 may be generated near the center of the bottom surface of the temperature sensitive contact portion 188.

In the electrical connection between the temperature sensitive contact portion 188 and the temperature sensitive diode 183, the temperature sensitive portion 180 in the present example secures the electrical connection through the bottom surface corner portion 1880, rather than the central portion of the bottom surface of the temperature sensitive contact portion 188. As a result, similarly to the example of FIG. 7D, even when the void 302 is formed in the region near the center of the temperature sensitive contact portion 188 in contact with the housing portion 198, it is possible to obtain stable quality and improve the yield.

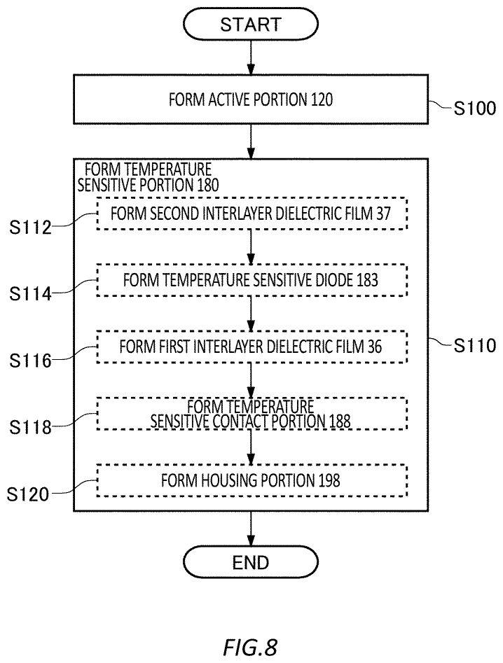

FIG. 8 is a flowchart illustrating an example of a manufacturing step of the semiconductor device 100. The manufacturing step in the present example includes step S100 of forming the active portion 120 in the semiconductor substrate 10 and step S110 of forming the temperature sensitive portion 180 above the semiconductor substrate 10. An order of step S100 of forming the active portion 120 and step S110 of forming the temperature sensitive portion 180 is not limited thereto. The active portion 120 may be formed after the temperature sensitive portion 180 is formed, and a part of the step of forming the active portion 120 and a part of the step of forming the temperature sensitive portion 180 may be the same step.

Step S110 of forming the temperature sensitive portion 180 includes step S114 of forming the temperature sensitive diode 183, step S116 of forming the first interlayer dielectric film 36, step S118 of forming the temperature sensitive contact portion 188, and step S120 of forming the housing portion 198. Step S110 of forming the temperature sensitive portion 180 may include step S112 of forming the second interlayer dielectric film 37.

In step S112, the second interlayer dielectric film 37 is formed above the semiconductor substrate 10. The second interlayer dielectric film 37 may be formed by stacking a plurality of dielectric films. When the second interlayer dielectric film 37 is not provided in the semiconductor device 100, step S112 may be omitted. When a dielectric film (such as a thermal oxide film and an HTO) formed in step S100 is the second interlayer dielectric film 37, step S112 may be omitted.

In step S114, the temperature sensitive diode 183 is formed above the semiconductor substrate 10. The temperature sensitive diode 183 may be formed by a method that is conventional to persons skilled in the art. As an example, the temperature sensitive diode 183 may be formed by depositing non-doped polysilicon above the semiconductor substrate 10, then implanting impurity ions, and performing annealing processing.

Step S114 of forming the temperature sensitive diode 183 may include a step of etching the second interlayer dielectric film 37 to form a recess. In this case, as illustrated in the example of FIG. 5B or 7B, the temperature sensitive diode 183 may be provided in the recess of the second interlayer dielectric film 37.

In step S116, the first interlayer dielectric film 36 is formed above the temperature sensitive diode. The first interlayer dielectric film 36 may be formed by stacking a plurality of dielectric films. Step S116 of forming the first interlayer dielectric film 36 may be a step of forming the interlayer dielectric film 38 in the active portion 120. However, the first interlayer dielectric film 36 and the interlayer dielectric film 38 of the active portion 120 may be formed in different steps.

In step S118, the temperature sensitive contact portion 188 extending from the upper surface to the lower surface of the first interlayer dielectric film 36 is formed. Step S118 of forming the temperature sensitive contact portion 188 may be a step of forming, in the active portion 120, the active contact portion 124 extending from the upper surface to the lower surface of the interlayer dielectric film 38. However, the temperature sensitive contact portion 188 and the active contact portion 124 may be formed in different steps.

Step S118 of forming the temperature sensitive contact portion 188 may include a step of etching the first interlayer dielectric film 36 to form the contact hole 58. In this step, the contact hole 54, the contact hole 55, and the contact hole 56 may be formed in the interlayer dielectric film 38. However, the contact hole 58 of the temperature sensitive contact portion 188, the contact hole 54, the contact hole 55, and the contact hole 56 may be formed in different steps. In addition, in step S116 of forming the first interlayer dielectric film 36, the first interlayer dielectric film 36 may be formed so as to include the contact hole 58.

Step S118 of forming the temperature sensitive contact portion 188 may include a step of forming the barrier metal film 1882. The barrier metal film 1882 may be formed by forming a metal film inside the contact hole 58 and then performing annealing in a nitrogen atmosphere. As an example, the barrier metal film 1882 may be formed by forming a Ti film inside the contact hole 58 and then performing annealing in the nitrogen atmosphere. In this case, a TiN film may be formed by annealing the Ti film. In this step, a barrier metal film may be formed on the active contact portion 124.

Step S118 of forming the temperature sensitive contact portion 188 may include a step of forming the plug portion 1884. As an example, the plug portion 1884 may be formed by forming tungsten so as to be embedded into the contact hole 58 by a chemical vapor deposition (CVD) method. In this step, a plug portion may be formed in the active contact portion 124.

Step S118 of forming the temperature sensitive contact portion 188 may include a step of performing etch-back on the plug portion 1884. Accordingly, an unnecessary tungsten film outside the contact hole 58 may be removed. However, the plug portion 1884 may be provided in a part of the temperature sensitive contact portion 188, or may be provided to protrude from the contact hole 58 and reach above the first interlayer dielectric film 36. The etch-back may be performed by dry etching or chemical mechanical polishing (CMP). When the tungsten film is removed, the barrier metal film 1882 may also be removed. The barrier metal film 1882 may be removed in a step different from the etch-back of the plug portion 1884. In this step, the plug portion of the active contact portion 124 may be etched back.

When the barrier metal film 1882 and the plug portion 1884 are not provided in the temperature sensitive contact portion 188, the above-described step may be omitted. In this case, simultaneously with the step of providing the anode wiring portion 117 and the cathode wiring portion 119, the inside of the contact hole 58 may be filled to form the temperature sensitive contact portion 188.

In step S118 of forming the temperature sensitive contact portion 188, the temperature sensitive contact portion 188 may be formed such that the bottom surface corner portion 1880 of the temperature sensitive contact portion 188 is in contact with the temperature sensitive diode 183. In step S118 of forming the temperature sensitive contact portion 188, the temperature sensitive contact portion 188 may be formed such that the bottom surface of the temperature sensitive contact portion 188 is in contact with the housing portion 198.

The bottom surface corner portion 1880 of the temperature sensitive contact portion 188 in the present example is provided in contact with the temperature sensitive diode 183, and the bottom surface thereof is provided in contact with the housing portion 198, so that it is possible to reliably secure electrical connection between the anode pad 116 and the cathode pad 118, and the temperature sensitive diode 183. Since the bottom surface of the temperature sensitive contact portion 188 in the present example is provided in contact with the housing portion 198, even when the plug portion 1884 and the barrier metal film 1882 near the center of the bottom surface of the temperature sensitive contact portion 188 are removed due to over-etching in the etch-back step of the plug portion 1884 and a void is generated inside the temperature sensitive contact portion 188, it is possible to suppress the influence on the electrical connection at the bottom surface corner portion 1880 between the temperature sensitive contact portion 188 and the temperature sensitive diode 183 and to improve the yield of the semiconductor device 100 having desired characteristics. That is, in the electrical connection between the temperature sensitive contact portion 188 and the temperature sensitive diode 183, the electrical connection through the bottom surface corner portion 1880 is secured rather than the electrical connection through the central portion of the bottom surface of the temperature sensitive contact portion 188, so that even when a void is formed in the region near the center of the temperature sensitive contact portion 188 in contact with the housing portion 198, it is possible to obtain stable quality and improve the yield.

In step S120, the housing portion 198 is formed below the temperature sensitive contact portion 188. An order of step S120 of forming the housing portion 198 is not limited thereto. Step S120 of forming the housing portion 198 may be included in step S112 of forming the second interlayer dielectric film 37, may be included in step S114 of forming the temperature sensitive diode 183, or may be included in step S116 of forming the first interlayer dielectric film 36.

As an example, in the example illustrated in FIG. 5A or 7A, the housing portion 198 is the region, which is provided below the temperature sensitive contact portion 188, in the first interlayer dielectric film 36. In this case, step S120 of forming the housing portion 198 may be included in step S116 of forming the first interlayer dielectric film 36.

As another example, in the example illustrated in FIG. 5B or 7B, the housing portion 198 is the second interlayer dielectric film 37 provided above the semiconductor substrate 10. In this case, step S120 of forming the housing portion 198 may be included in step S112 of forming the second interlayer dielectric film 37.

As another example, in the example illustrated in FIG. 5C or 7C, the housing portion 198b has polysilicon. In this case, step S120 of forming the housing portion 198 may be included in step S114 of forming the temperature sensitive diode 183. The temperature sensitive diode 183 and the housing portion 198 may be formed by stacking non-doped polysilicon in regions to be the housing portion 198 and the temperature sensitive diode 183, implanting impurity ions of a conductivity type corresponding to each region, and performing annealing processing, or may be formed by stacking high-concentration polysilicon of the N type or the P type in the regions to be the housing portion 198 and the temperature sensitive diode 183, and implanting impurity ions in a region having another conductivity type to invert the conductivity type.

In the above description, the connection between the temperature sensitive contact portion 188 and the temperature sensitive diode 183 has been described as an example, but the same may be applied to a contact portion provided in another contact hole. As an example, a bottom surface corner portion of a contact portion which electrically connects the polysilicon of the connection portion 25 and the gate metal layer 50 may be provided so as to be in contact with the polysilicon. Even in these cases, electrical connection in each contact portion can be secured. These cases will be described below.

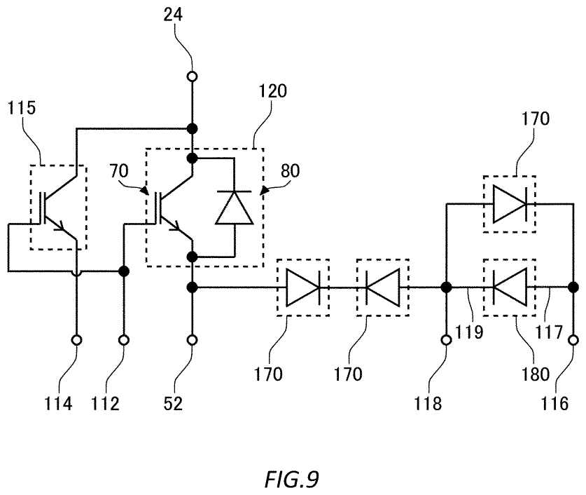

FIG. 9 is an example of the electrical connection of each portion of the semiconductor device 100 illustrated in FIG. 3. In the present example, a Zener diode portion 170 is provided in anti-parallel to protect a withstand voltage between the cathode pad 118 and the anode pad 116. The Zener diode portion 170 may have a configuration similar to that of the temperature sensitive diode 183. A forward voltage of the Zener diode portion 170 in this case may be different from a forward voltage of the temperature sensitive diode 183. When the temperature sensitive diode 183 consists of a plurality of temperature sensitive cathode regions 181 and a plurality of temperature sensitive anode regions 182 connected in series, the Zener diode portion 170 may be provided between the temperature sensitive cathode region 181 and the temperature sensitive anode region 182. In addition, when the Zener diode portion 170 is provided between the temperature sensitive portion 180 and the active portion 120 for electric field protection, the Zener diode portion 170 may have a configuration similar to that of the temperature sensitive diode 183. A breakdown voltage of the Zener diode portion 170 in this case may be different from a breakdown voltage of the temperature sensitive diode 183. A plurality of Zener diode portions 170 may be connected in series. In another example, the Zener diode portion 170 may be connected to a different position, and the Zener diode portion 170 may not be provided.

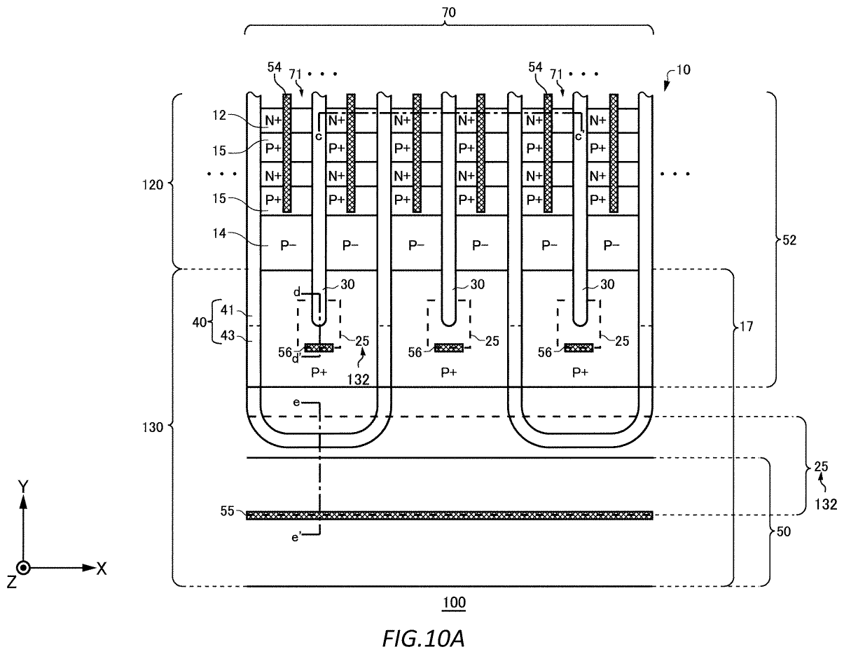

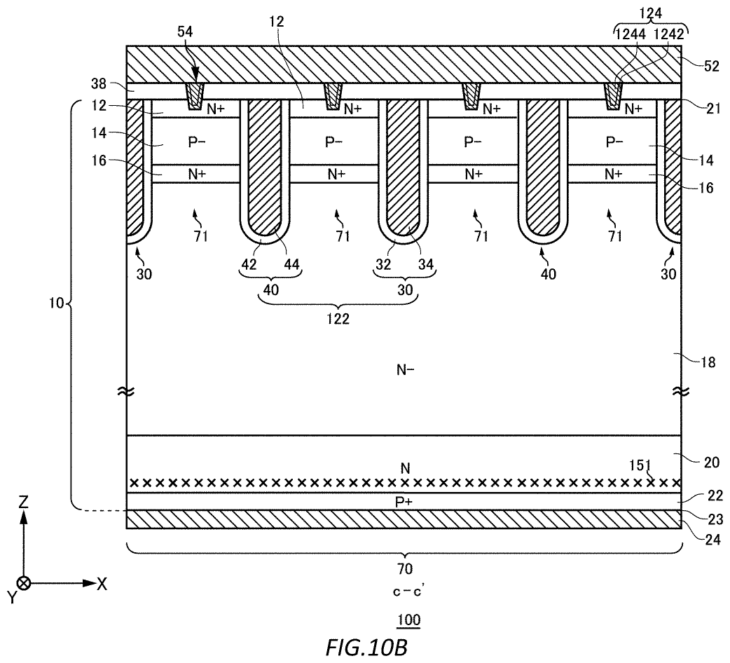

FIG. 10A illustrates an example of an enlarged top view of the semiconductor device 100. The semiconductor device 100 in the present example is different from that in the example of FIG. 1A in that the connection portion 25 is provided between the emitter electrode 52 and the dummy conductive portion 34. In the present example, the difference from the example of FIG. 1A will be particularly described, and other configurations may be the same as those in the example of FIG. 1A. Similarly to the example of FIG. 1A, the configuration of the present drawing may be repeatedly provided in the positive direction and the negative direction of the X axis.

The semiconductor device 100 includes the active portion 120 which is a part through which a main current flows between the front surface 21 and the back surface 23 of the semiconductor substrate 10, and an inactive portion 130 which is a remaining part. For example, a boundary between the active portion 120 and the inactive portion 130 is a boundary between the base region 14 and the well region 17.

The interlayer dielectric film 38 is provided above the active portion 120 and the inactive portion 130, but the interlayer dielectric film 38 is omitted in FIG. 10A. The contact hole 54, the contact hole 55, and the contact hole 56 are provided to penetrate the interlayer dielectric film 38.

The contact hole 55 electrically connects the gate metal layer 50 and the gate conductive portion 44 in the transistor portion 70 via the connection portion 25. The contact hole 56 electrically connects the emitter electrode 52 and the dummy conductive portion 34 in the dummy trench portion 30 via the connection portion 25. The connection portion 25 is a conductive material such as polysilicon doped with impurities. The connection portion 25 in the present example is polysilicon (N+) doped with impurities of the N type. The polysilicon is an example of a polycrystalline semiconductor. The connection portion 25 is an example of a polycrystalline portion 132 provided above the semiconductor substrate 10. The connection portion 25 is an example of the polycrystalline portion 132 included in the inactive portion 130.

FIG. 10B illustrates an example of a cross section c-c′ in FIG. 9. The semiconductor device 100 in the present example is different from that in the example of FIG. 1B in that the active contact portion 124 has a trench shape. Other configurations may be the same as those in the example of FIG. 1B.

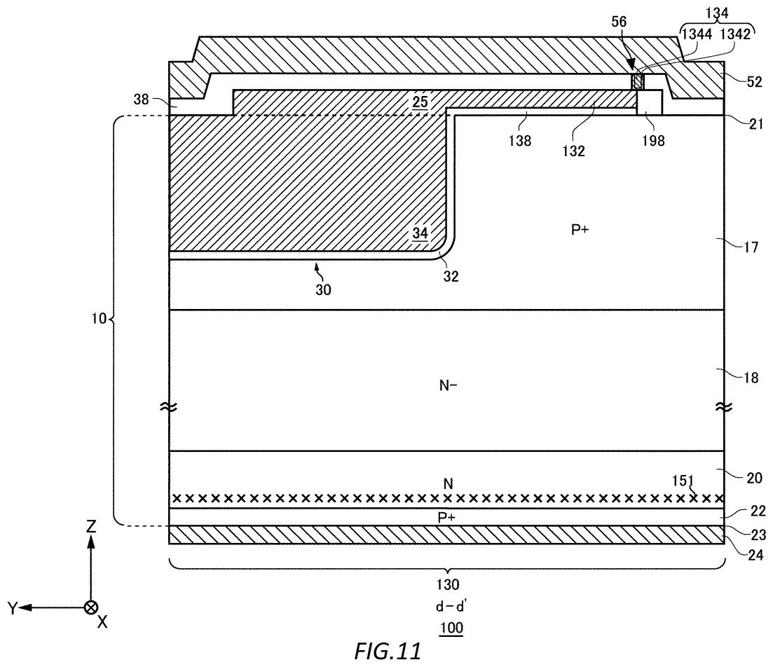

FIG. 11 illustrates an example of a cross section d-d′ in FIG. 9. The cross section d-d′ is a YZ plane passing through the contact hole 56 in the inactive portion 130. The semiconductor device 100 in the present example includes, in the cross section d-d′, the semiconductor substrate 10, the interlayer dielectric film 38, the emitter electrode 52, the collector electrode 24, and a first inactive contact portion 134. Note that, in the present example, the contact hole 56 which is elongated in the X axis direction is described as an example, but a longitudinal direction of the contact hole 56 may be along the Y axis direction or may be along another direction.

The polycrystalline portion 132 is provided above the semiconductor substrate. The polycrystalline portion 132 in the present example is the connection portion 25. The polycrystalline portion 132 may be provided above a third interlayer dielectric film 138. The third interlayer dielectric film 138 may be, for example, the same material as that of the dummy dielectric film 32. The third interlayer dielectric film 138 may be a thermal oxide film. In another example, the third interlayer dielectric film 138 may be a material different from that of the dummy dielectric film 32. The interlayer dielectric film 38 is provided above the polycrystalline portion 132.

The first inactive contact portion 134 is provided to extend from the upper surface to the lower surface of the interlayer dielectric film 38. The contact hole 56 may be provided to penetrate the interlayer dielectric film 38. The first inactive contact portion 134 may include the contact hole 56 and a metal layer with which an inside of the contact hole 56 is filled. A detailed configuration of the first inactive contact portion 134 will be described below. The housing portion 198 is provided below the first inactive contact portion 134.

The polycrystalline portion 132 may be connected to the emitter electrode 52 via the first inactive contact portion 134. The polycrystalline portion 132 may be connected to the dummy conductive portion 34. The connection portion 25 in the present example is connected to the emitter electrode 52 via the first inactive contact portion 134 and is connected to the dummy conductive portion 34.

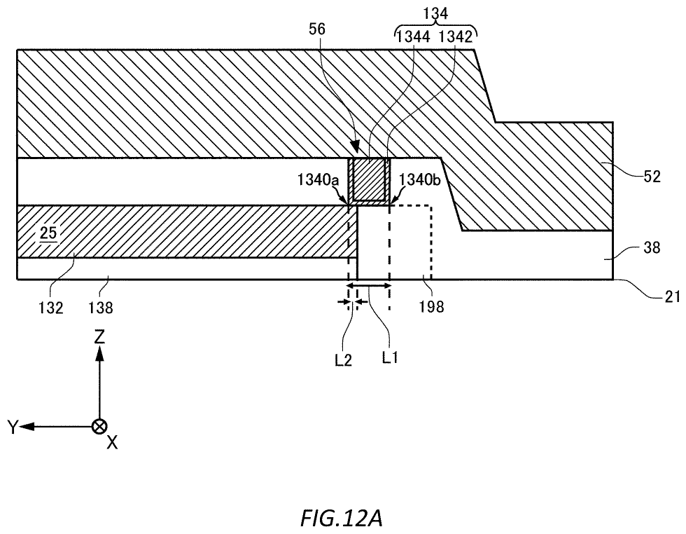

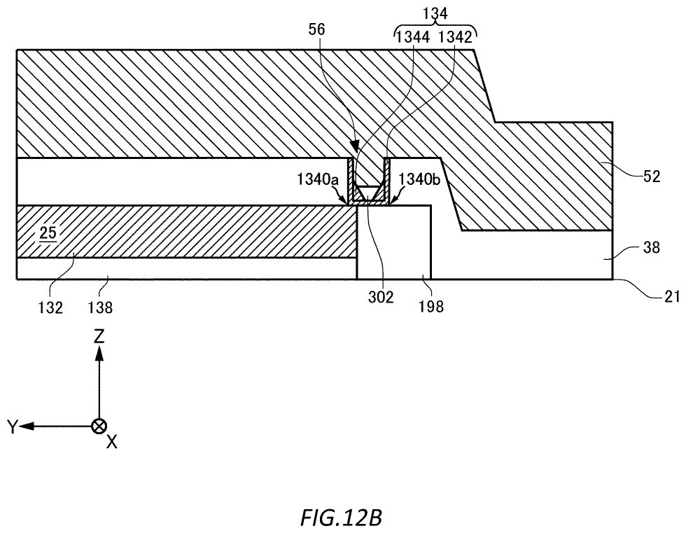

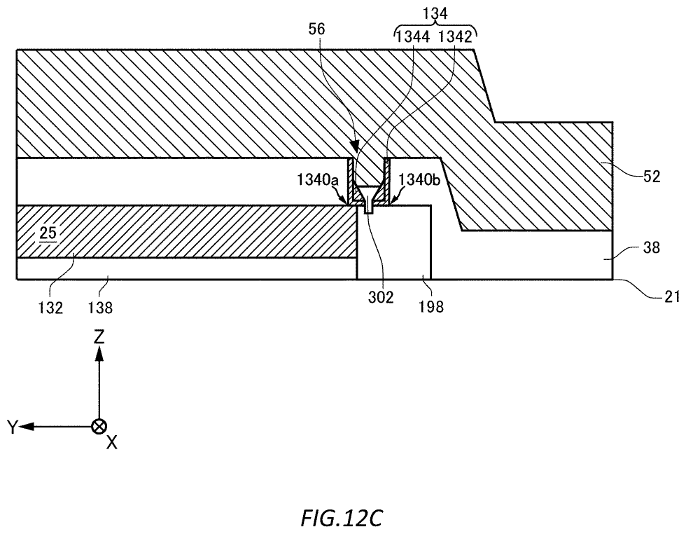

FIG. 12A illustrates an example of an enlarged view of a cross section d-d′ in FIG. 9. The present drawing illustrates a region above the front surface 21 of the semiconductor substrate 10 in the inactive portion 130.

A bottom surface corner portion 1340 of the first inactive contact portion 134 may be in contact with the polycrystalline portion 132. The bottom surface corner portion 1340 of the first inactive contact portion 134 may be an intersection of a bottom surface of the first inactive contact portion 134 and a side surface of the first inactive contact portion 134. The bottom surface corner portion 1340 being in contact with the polycrystalline portion 132 may mean being in contact with the polycrystalline portion 132 on an upper surface of the polycrystalline portion 132, may mean being in contact with the polycrystalline portion 132 on a side surface of the polycrystalline portion 132, or may mean being in contact with the polycrystalline portion 132 in a region inside the polycrystalline portion 132. The bottom surface corner portion 1340 in the present example is in contact with the polycrystalline portion 132 on the upper surface of the polycrystalline portion 132.

The first inactive contact portion 134 in the present example includes two bottom surface corner portions 1340. One of the two bottom surface corner portions 1340 may be in contact with the polycrystalline portion 132. Another of the two bottom surface corner portions 1340 may be in contact with the housing portion 198 or may not be in contact with the housing portion 198. In the first inactive contact portion 134 in the present example, one bottom surface corner portion 1340a is in contact with the polycrystalline portion 132, and another bottom surface corner portion 1340b is in contact with the housing portion 198.

The bottom surface of the first inactive contact portion 134 may be in contact with the housing portion 198. The bottom surface of the first inactive contact portion 134 may be a surface between the two bottom surface corner portions 1340 of the first inactive contact portion 134. The bottom surface of the first inactive contact portion 134 being in contact with the housing portion 198 may mean that the bottom surface is in contact with the housing portion 198 on the upper surface of the housing portion 198, or may mean that the bottom surface is in contact with the housing portion 198 in a region inside the housing portion 198. In the first inactive contact portion 134 in the present example, the bottom surface is in contact with the housing portion 198 on the upper surface of the housing portion 198.

The first inactive contact portion 134 in the present example is provided such that the bottom surface corner portion 1340 is in contact with the polycrystalline portion 132 and its bottom surface is in contact with the housing portion 198. Accordingly, it is possible to reliably secure electrical connection between the emitter electrode 52 and the polycrystalline portion 132. In the etch-back step of the plug portion 1344, when the plug portion 1344 and the barrier metal film 1342 near a center of the bottom surface of the first inactive contact portion 134 are removed due to over-etching, a void may be generated inside the first inactive contact portion 134. Even in this case, the electrical connection can be secured by the barrier metal film 1342 and/or the plug portion 1344 remaining at the bottom surface corner portion 1340 of the first inactive contact portion 134. The barrier metal film 1342 and the plug portion 1344 will be described below.

The bottom surface of the first inactive contact portion 134 in the present example is provided in contact with the housing portion 198. Therefore, even when a void is generated inside the first inactive contact portion 134, near the center of its bottom surface, an influence on electrical connection at the bottom surface corner portion 1340 between the first inactive contact portion 134 and the polycrystalline portion 132 is suppressed. Accordingly, it is possible to improve the yield of the semiconductor device 100 having desired characteristics. In the electrical connection between the first inactive contact portion 134 and the polycrystalline portion 132, the inactive portion 130 in the present example secures the electrical connection through the bottom surface corner portion 1340, rather than a central portion of the bottom surface of the first inactive contact portion 134. As a result, even when a void is formed in a region near the center of the first inactive contact portion 134 in contact with the housing portion 198, it is possible to obtain stable quality and improve the yield.

The bottom surface of the first inactive contact portion 134 may be in contact with the polycrystalline portion 132 and the housing portion 198. In the first inactive contact portion 134 in the present example, one bottom surface corner portion 1340a is in contact with the polycrystalline portion 132, and another bottom surface corner portion 1340b is in contact with the housing portion 198, so that the bottom surface of the first inactive contact portion 134 is in contact with the polycrystalline portion 132 and the housing portion 198.

The polycrystalline portion 132 may be in contact with the bottom surface of the first inactive contact portion 134, from the bottom surface corner portion 1340 to a region of 10% or more and 40% or less of the bottom surface of the first inactive contact portion 134. That is, a ratio of an area of a surface, which is in contact with the polycrystalline portion 132, in the bottom surface of the first inactive contact portion 134 to an area of the bottom surface of the first inactive contact portion 134 may be 10% or more and 40% or less. With reference to FIG. 12A, the length L1 is a length of the bottom surface of the first inactive contact portion 134 in the cross section perpendicular to the front surface 21 of the semiconductor substrate 10. The length L2 is a length of the bottom surface, which is in contact with the polycrystalline portion 132, in the bottom surface of the first inactive contact portion 134 in the cross section perpendicular to the front surface 21 of the semiconductor substrate 10. Therefore, the ratio of the length L2 to the length L1 may be 10% or more and 40% or less. The polycrystalline portion 132 in the present example is in contact with the bottom surface of the first inactive contact portion 134, from the bottom surface corner portion 1340a to a region of 20% of the bottom surface of the first inactive contact portion 134. That is, the ratio of the length L2 to the length L1 in the present example is 20%.

The first inactive contact portion 134 may include the barrier metal film 1342 and the plug portion 1344. The barrier metal film 1342 and the plug portion 1344 in the present example are formed of different materials, but may be formed of the same material.

The barrier metal film 1342 may be provided on the bottom surface corner portion 1340 of the first inactive contact portion 134. The barrier metal film 1342 in the present example is provided over the entire side surfaces and bottom surface of the first inactive contact portion 134, but is not limited thereto. The barrier metal film 1342 may be provided so as to cover at least the bottom surface corner portion 1340, or may be provided without covering the central portion of the bottom surface of the first inactive contact portion 134. The barrier metal film 1342 may be provided to protrude from the contact hole 56 and reach above the interlayer dielectric film 38. A material of the barrier metal film 1342 may be titanium, a titanium compound, or the like.

The plug portion 1344 may be provided in contact with an inside of the barrier metal film 1342. The plug portion 1344 in the present example is provided to fill the first inactive contact portion 134, but is not limited thereto. The plug portion 1344 may be provided in a part of the first inactive contact portion 134, and may be provided to protrude from the contact hole 56 and reach above the interlayer dielectric film 38. When the plug portion 1344 is provided in a part of the first inactive contact portion 134, a remaining region of the first inactive contact portion 134 may be filled with the same material as that of the emitter electrode 52. A material of the plug portion 1344 may be a plug metal such as tungsten.

The side surface of the polycrystalline portion 132 may be in contact with the side surface of the housing portion 198. The housing portion 198 may be a region, which is provided below the first inactive contact portion 134, in the interlayer dielectric film 38. The housing portion 198 may be formed in a step of providing the interlayer dielectric film 38, and may be formed of the same material as that of the interlayer dielectric film 38. When the housing portion 198 is formed as the region, which is provided below the first inactive contact portion 134, in the interlayer dielectric film 38, the housing portion 198 is a virtual region as indicated by a dotted line in FIG. 12A. That is, the housing portion 198 may be integrally formed as a part of the interlayer dielectric film 38. In another example, the housing portion 198 may be the third interlayer dielectric film 138 provided above the semiconductor substrate 10. The housing portion 198 may be formed in a step of providing the third interlayer dielectric film 138, and may be formed of the same material as that of the third interlayer dielectric film 138. That is, the housing portion 198 may be integrally formed as a part of the third interlayer dielectric film 138. In this case, the polycrystalline portion 132 may be provided within a recess provided by etching the upper surface of the third interlayer dielectric film 138 provided thickly. In still another example, the housing portion 198 may be polysilicon having an impurity concentration lower than that of the polycrystalline portion 132 or non-doped polysilicon.

FIG. 12B illustrates an example of the enlarged view of the cross section d-d′ in FIG. 9 when the void 302 is generated in the first inactive contact portion 134. The present example illustrates a case where, in the etch-back step of the plug portion 1344, the plug portion 1344 near the center of the bottom surface of the first inactive contact portion 134 is removed due to over-etching. In this case, it is difficult to fill the first inactive contact portion 134 with the metal material of the emitter electrode 52, and the void 302 may be generated near the center of the bottom surface of the first inactive contact portion 134.

The first inactive contact portion 134 in the present example is provided such that the bottom surface corner portion 1340 is in contact with the polycrystalline portion 132 and its bottom surface is in contact with the housing portion 198. Therefore, even when the void 302 is generated inside the first inactive contact portion 134, near the center of its bottom surface, the influence on the electrical connection at the bottom surface corner portion 1340 between the first inactive contact portion 134 and the polycrystalline portion 132 is suppressed. Accordingly, it is possible to improve the yield of the semiconductor device 100 having desired characteristics. In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, even when the void 302 is formed in the region near the center of the first inactive contact portion 134 in contact with the housing portion 198, it is possible to obtain stable quality and improve the yield.

FIG. 12C illustrates another example of the enlarged view of the cross section d-d′ in FIG. 9 when the void 302 is generated in the first inactive contact portion 134. The present example illustrates a case where, in the etch-back step of the plug portion 1344, the plug portion 1344 and the barrier metal film 1342 near the center of the bottom surface of the first inactive contact portion 134 are removed due to over-etching, and further, the housing portion 198 is also over-etched. In this case, it is difficult to fill the first inactive contact portion 134 with the metal material of the emitter electrode 52, and the void 302 may be generated near the center of the bottom surface of the first inactive contact portion 134.

In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, similarly to the example of FIG. 12B, even when the void 302 is formed in the region near the center of the first inactive contact portion 134 in contact with the housing portion 198, it is possible to obtain stable quality and improve the yield.

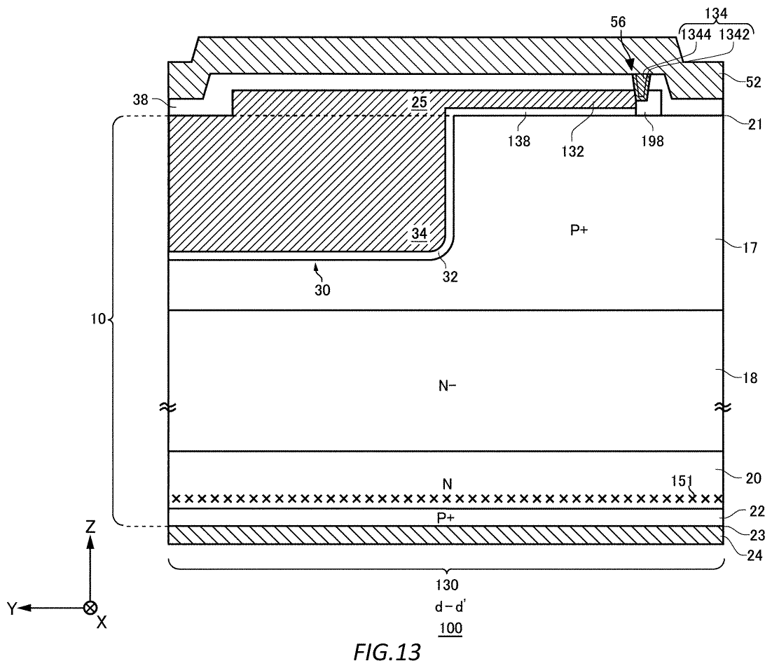

FIG. 13 illustrates an example of the cross section d-d′ in FIG. 9. The semiconductor device 100 in the present example is different from that in the example of FIG. 11 in that the first inactive contact portion 134 has a trench contact structure. Other configurations may be the same as those in the example of FIG. 11. When the first inactive contact portion 134 has a trench contact structure, the first inactive contact portion 134 may extend from the upper surface of the polycrystalline portion 132 in the depth direction of the semiconductor substrate 10. The active contact portion 124 may have the planar contact structure of FIG. 1B or the trench contact structure of FIG. 10B.

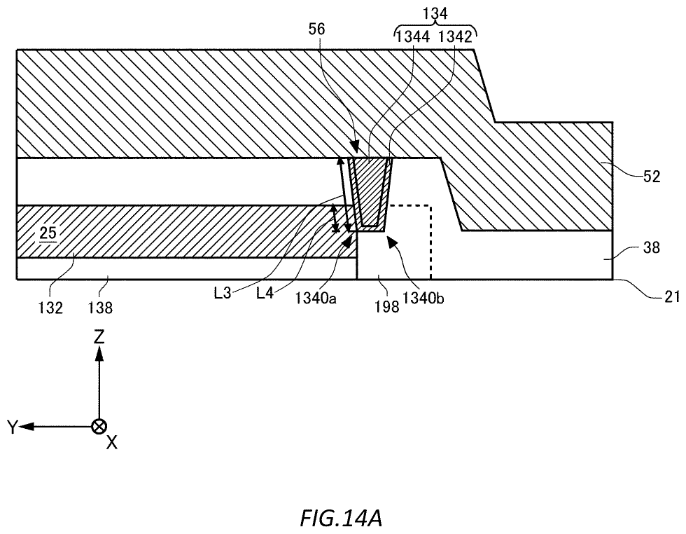

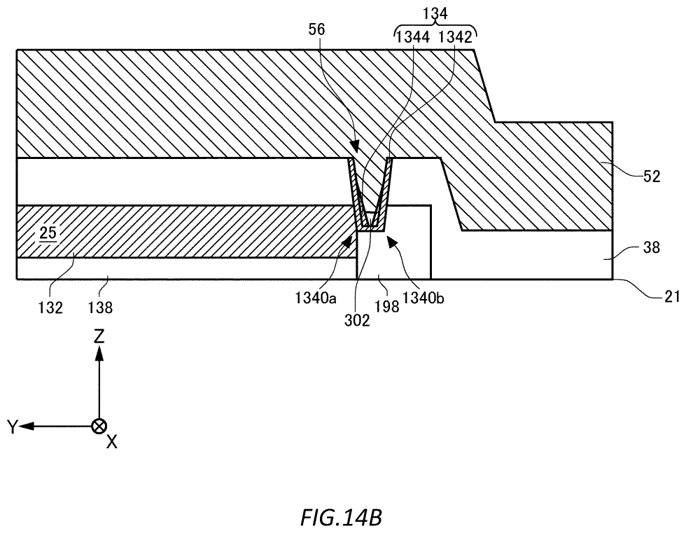

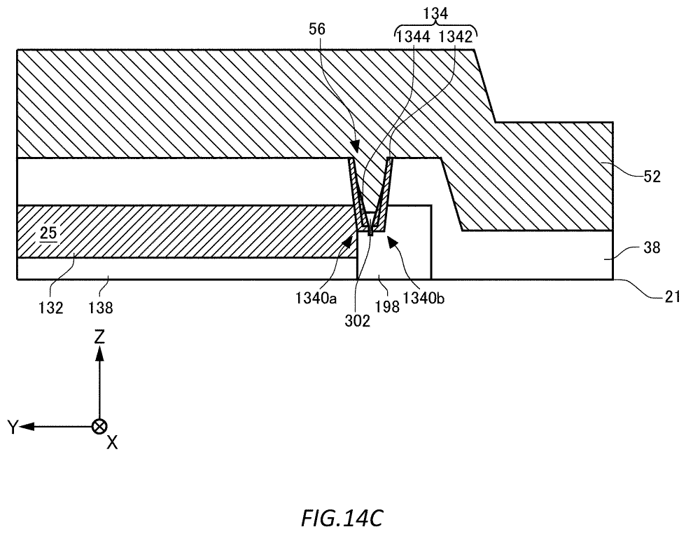

FIG. 14A illustrates an example of the enlarged view of the cross section d-d′ in FIG. 9. The present drawing illustrates the region above the front surface 21 of the semiconductor substrate 10 in the inactive portion 130. The semiconductor device 100 in the present example is different from that in the example of FIG. 12A in that the first inactive contact portion 134 is different in structure. In the present example, the difference from the example of FIG. 12A will be particularly described, and other configurations may be the same as those in the example of FIG. 12A.

Side walls of the first inactive contact portion 134 may have a trench contact structure in contact with the side surface of the polycrystalline portion 132. The bottom surface corner portion 1340 of the first inactive contact portion 134 in the present example is in contact with the polycrystalline portion 132 on the side surface of the polycrystalline portion 132.

A side wall of the first inactive contact portion 134 may be in contact with the polycrystalline portion 132 and the interlayer dielectric film 38. The polycrystalline portion 132 may be in contact with the side wall of the first inactive contact portion 134, from the bottom surface corner portion 1340 to a region of 10% or more and 90% or less of the side wall of the first inactive contact portion 134. That is, a ratio of an area of the side wall, which is in contact with the polycrystalline portion 132, in the side wall of the first inactive contact portion 134 to an area of the side wall, on a side in contact with the polycrystalline portion 132, among the side walls of the first inactive contact portion 134 may be 10% or more and 90% or less. With reference to FIG. 14A, the length L3 is a length of the side wall of the first inactive contact portion 134 in the cross section perpendicular to the front surface 21 of the semiconductor substrate 10, and the length L4 is a length of the side wall, which is in contact with the polycrystalline portion 132, in the side wall of the first inactive contact portion 134 in the cross section perpendicular to the front surface 21 of the semiconductor substrate 10. Therefore, the ratio of the length L4 to the length L3 may be 10% or more and 90% or less. The polycrystalline portion 132 in the present example is in contact with the side wall of the first inactive contact portion 134, from the bottom surface corner portion 1340 to a region of 35% of the side wall of the first inactive contact portion 134. That is, the ratio of the length L4 to the length L3 in the present example is 35%.

FIG. 14B illustrates an example of the enlarged view of the cross section d-d′ in FIG. 9 when the void 302 is generated in the first inactive contact portion 134. The present example illustrates a case where, in the etch-back step of the plug portion 1344, the plug portion 1344 near the center of the bottom surface of the first inactive contact portion 134 is removed due to over-etching. In this case, it is difficult to fill the first inactive contact portion 134 with the metal material of the emitter electrode 52, and the void 302 may be generated near the center of the bottom surface of the first inactive contact portion 134.

The first inactive contact portion 134 in the present example is provided such that the bottom surface corner portion 1340 is in contact with the polycrystalline portion 132 and its bottom surface is in contact with the housing portion 198. Therefore, even when the void 302 is generated inside the first inactive contact portion 134, near the center of its bottom surface, the influence on the electrical connection at the bottom surface corner portion 1340 between the first inactive contact portion 134 and the polycrystalline portion 132 is suppressed. Accordingly, it is possible to improve the yield of the semiconductor device 100 having desired characteristics. In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, even when the void 302 is formed in the region near the center of the first inactive contact portion 134 in contact with the housing portion 198, it is possible to obtain stable quality and improve the yield.

FIG. 14C illustrates another example of the enlarged view of the cross section d-d′ in FIG. 9 when the void 302 is generated in the first inactive contact portion 134. The present example illustrates a case where, in the etch-back step of the plug portion 1344, the plug portion 1344 and the barrier metal film 1342 near the center of the bottom surface of the first inactive contact portion 134 are removed due to over-etching, and further, the housing portion 198 is also over-etched. In this case, it is difficult to fill the first inactive contact portion 134 with the metal material of the emitter electrode 52, and the void 302 may be generated near the center of the bottom surface of the first inactive contact portion 134.

In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, similarly to the example of FIG. 14B, even when the void 302 is formed in the region near the center of the first inactive contact portion 134 in contact with the housing portion 198, it is possible to obtain stable quality and improve the yield.

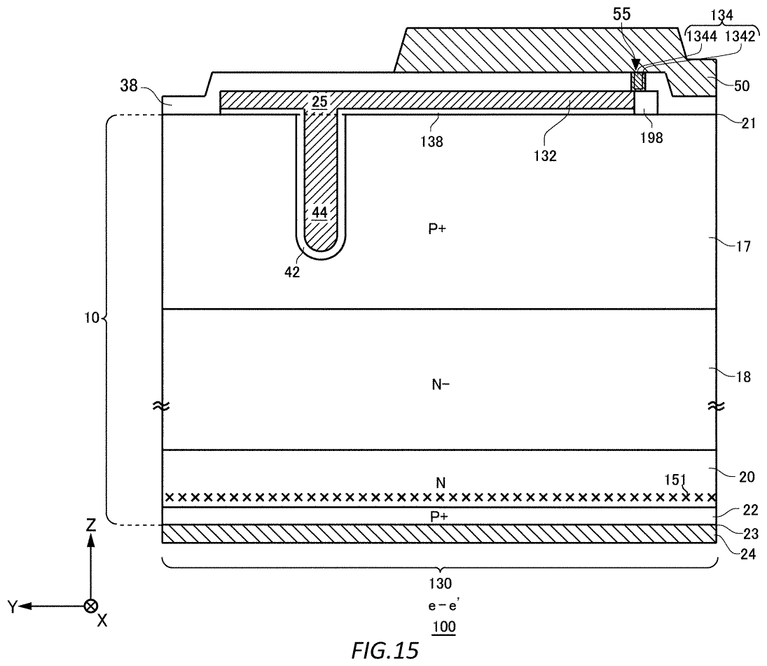

FIG. 15 illustrates an example of a cross section e-e′ in FIG. 9. The cross section e-e′ is a YZ plane passing through the contact hole 55 in the inactive portion 130. The semiconductor device 100 in the present example includes, in the cross section e-e′, the semiconductor substrate 10, the interlayer dielectric film 38, the gate metal layer 50, the collector electrode 24, and the first inactive contact portion 134.

The polycrystalline portion 132 is provided above the semiconductor substrate. The polycrystalline portion 132 in the present example is the connection portion 25. The polycrystalline portion 132 may be provided above the third interlayer dielectric film 138. The third interlayer dielectric film 138 may be, for example, the same material as that of the gate dielectric film 42. The third interlayer dielectric film 138 may be a thermal oxide film. In another example, the third interlayer dielectric film 138 may be a material different from that of the gate dielectric film 42. The interlayer dielectric film 38 is provided above the polycrystalline portion 132.

The first inactive contact portion 134 is provided to extend from the upper surface to the lower surface of the interlayer dielectric film 38. The contact hole 55 may be provided to penetrate the interlayer dielectric film 38. The first inactive contact portion 134 may include the contact hole 55 and a metal layer with which an inside of the contact hole 55 is filled. The housing portion 198 is provided below the first inactive contact portion 134.

The polycrystalline portion 132 may be connected to the gate metal layer 50 via the first inactive contact portion 134. The polycrystalline portion 132 may be connected to the gate conductive portion 44. The connection portion 25 in the present example is connected to the gate metal layer 50 via the first inactive contact portion 134 and is connected to the gate conductive portion 44.

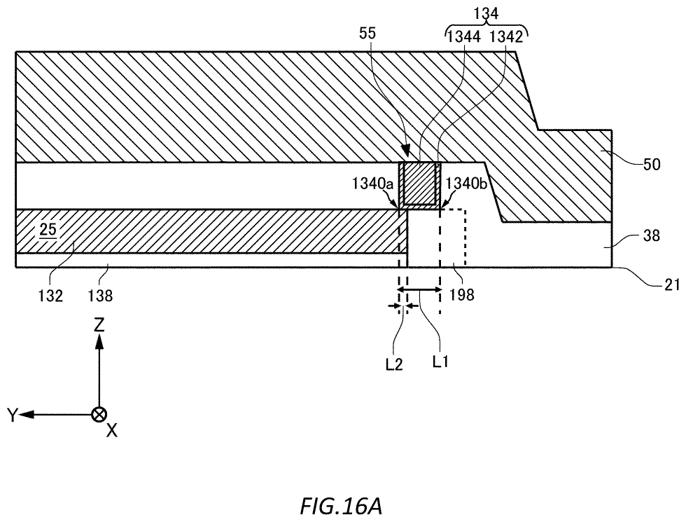

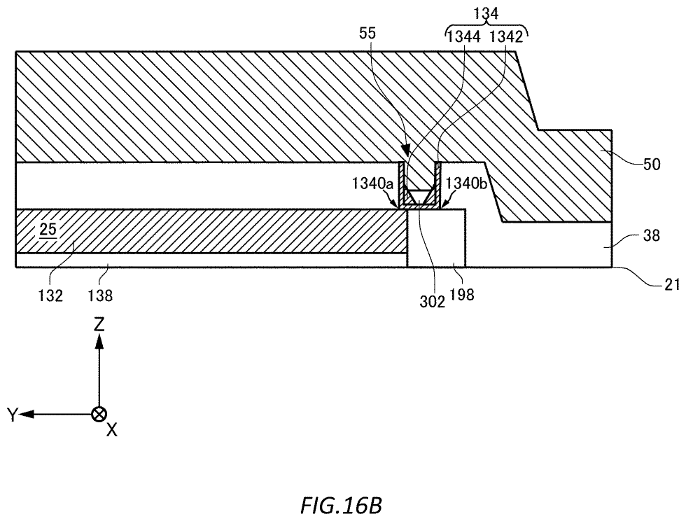

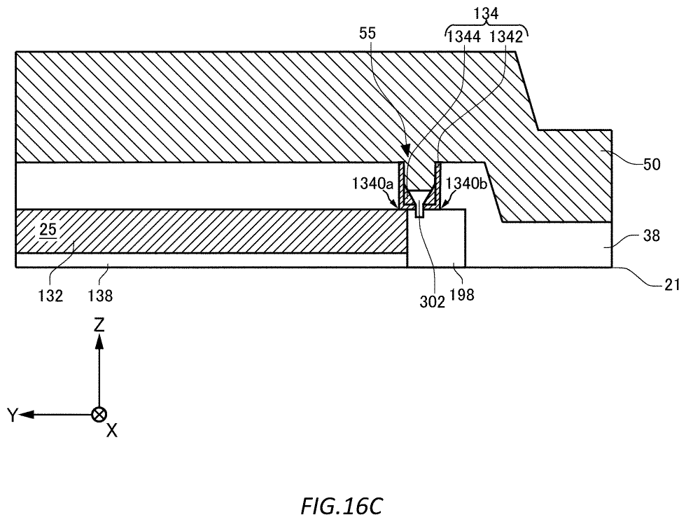

FIG. 16A illustrates an example of an enlarged view of the cross section e-e′ in FIG. 9. The present drawing illustrates the region above the front surface 21 of the semiconductor substrate 10 in the inactive portion 130.

The bottom surface corner portion 1340 of the first inactive contact portion 134 may be in contact with the polycrystalline portion 132. The bottom surface corner portion 1340 in the present example is in contact with the polycrystalline portion 132 on the upper surface of the polycrystalline portion 132.

A bottom surface of the first inactive contact portion 134 may be in contact with the housing portion 198. In the first inactive contact portion 134 in the present example, the bottom surface is in contact with the housing portion 198 on the upper surface of the housing portion 198. The first inactive contact portion 134 in the present example is provided such that the bottom surface corner portion 1340 is in contact with the polycrystalline portion 132 and its bottom surface is in contact with the housing portion 198. Accordingly, it is possible to reliably secure electrical connection between the gate metal layer 50 and the polycrystalline portion 132. In the etch-back step of the plug portion 1344, when the plug portion 1344 and the barrier metal film 1342 near the center of the bottom surface of the first inactive contact portion 134 are removed due to over-etching, a void may be generated inside the first inactive contact portion 134. Even in this case, the electrical connection can be secured by the barrier metal film 1342 and/or the plug portion 1344 remaining at the bottom surface corner portion 1340 of the first inactive contact portion 134.

The bottom surface of the first inactive contact portion 134 in the present example is provided in contact with the housing portion 198. Therefore, even when a void is generated inside the temperature sensitive contact portion, near the center of its bottom surface, the influence on the electrical connection at the bottom surface corner portion 1340 between the first inactive contact portion 134 and the polycrystalline portion 132 is suppressed. Accordingly, it is possible to improve the yield of the semiconductor device 100 having desired characteristics. In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, even when a void is formed in a region near the center of the first inactive contact portion 134 in contact with the housing portion 198, it is possible to obtain stable quality and improve the yield.

The bottom surface of the first inactive contact portion 134 may be in contact with the polycrystalline portion 132 and the housing portion 198. In the first inactive contact portion 134 in the present example, one bottom surface corner portion 1340a is in contact with the polycrystalline portion 132, and another bottom surface corner portion 1340b is in contact with the housing portion 198, so that the bottom surface of the first inactive contact portion 134 is in contact with the polycrystalline portion 132 and the housing portion 198.

The polycrystalline portion 132 may be in contact with the bottom surface of the first inactive contact portion 134, from the bottom surface corner portion 1340 to a region of 10% or more and 40% or less of the bottom surface of the first inactive contact portion 134. The polycrystalline portion 132 in the present example is in contact with the bottom surface of the first inactive contact portion 134, from the bottom surface corner portion 1340a to a region of 20% of the bottom surface of the first inactive contact portion 134. That is, the ratio of the length L2 to the length L1 in the present example is 20%.

The barrier metal film 1342 may be provided on the bottom surface corner portion 1340 of the first inactive contact portion 134. The barrier metal film 1342 in the present example is provided over the entire side surfaces and bottom surface of the first inactive contact portion 134, but is not limited thereto. The barrier metal film 1342 may be provided so as to cover at least the bottom surface corner portion 1340, or may be provided without covering the central portion of the bottom surface of the first inactive contact portion 134. The barrier metal film 1342 may be provided to protrude from the contact hole 55 and reach above the interlayer dielectric film 38. The material of the barrier metal film 1342 may be titanium, a titanium compound, or the like.

The plug portion 1344 may be provided in contact with the inside of the barrier metal film 1342. The plug portion 1344 in the present example is provided to fill the first inactive contact portion 134, but is not limited thereto. The plug portion 1344 may be provided in a part of the first inactive contact portion 134, and may be provided to protrude from the contact hole 55 and reach above the interlayer dielectric film 38. When the plug portion 1344 is provided in a part of the first inactive contact portion 134, a remaining region of the first inactive contact portion 134 may be filled with the same material as that of the gate metal layer 50. The material of the plug portion 1344 may be a plug metal such as tungsten.

The side surface of the polycrystalline portion 132 may be in contact with the side surface of the housing portion 198. The housing portion 198 may be a region, which is provided below the first inactive contact portion 134, in the interlayer dielectric film 38. The housing portion 198 may be formed in a step of providing the interlayer dielectric film 38, and may be formed of the same material as that of the interlayer dielectric film 38. When the housing portion 198 is formed as the region, which is provided below the first inactive contact portion 134, in the interlayer dielectric film 38, the housing portion 198 is a virtual region as indicated by a dotted line in FIG. 16A. That is, the housing portion 198 may be integrally formed as a part of the interlayer dielectric film 38. In another example, the housing portion 198 may be the third interlayer dielectric film 138 provided above the semiconductor substrate 10. The housing portion 198 may be formed in a step of providing the third interlayer dielectric film 138, and may be formed of the same material as that of the third interlayer dielectric film 138. That is, the housing portion 198 may be integrally formed as a part of the third interlayer dielectric film 138. In still another example, the housing portion 198 may be polysilicon having an impurity concentration lower than that of the polycrystalline portion 132 or non-doped polysilicon.

FIG. 16B illustrates an example of the enlarged view of the cross section e-e′ in FIG. 9 when the void 302 is generated in the first inactive contact portion 134. The present example illustrates a case where, in the etch-back step of the plug portion 1344, the plug portion 1344 near the center of the bottom surface of the first inactive contact portion 134 is removed due to over-etching. In this case, it is difficult to fill the first inactive contact portion 134 with the metal material of the gate metal layer 50, and the void 302 may be generated near the center of the bottom surface of the first inactive contact portion 134.

The first inactive contact portion 134 in the present example is provided such that the bottom surface corner portion 1340 is in contact with the polycrystalline portion 132 and its bottom surface is in contact with the housing portion 198. Therefore, even when the void 302 is generated inside the first inactive contact portion 134, near the center of its bottom surface, the influence on the electrical connection at the bottom surface corner portion 1340 between the first inactive contact portion 134 and the polycrystalline portion 132 is suppressed. Accordingly, it is possible to improve the yield of the semiconductor device 100 having desired characteristics. In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, even when the void 302 is formed in the region near the center of the first inactive contact portion 134 in contact with the housing portion 198, it is possible to obtain stable quality and improve the yield.

FIG. 16C illustrates another example of the enlarged view of the cross section e-e′ in FIG. 9 when the void 302 is generated in the first inactive contact portion 134. The present example illustrates a case where, in the etch-back step of the plug portion 1344, the plug portion 1344 and the barrier metal film 1342 near the center of the bottom surface of the first inactive contact portion 134 are removed due to over-etching, and further, the housing portion 198 is also over-etched. In this case, it is difficult to fill the first inactive contact portion 134 with the metal material of the gate metal layer 50, and the void 302 may be generated near the center of the bottom surface of the first inactive contact portion 134.

In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, similarly to the example of FIG. 16B, even when the void 302 is formed in the region near the center of the first inactive contact portion 134 in contact with the housing portion 198, it is possible to obtain stable quality and improve the yield.

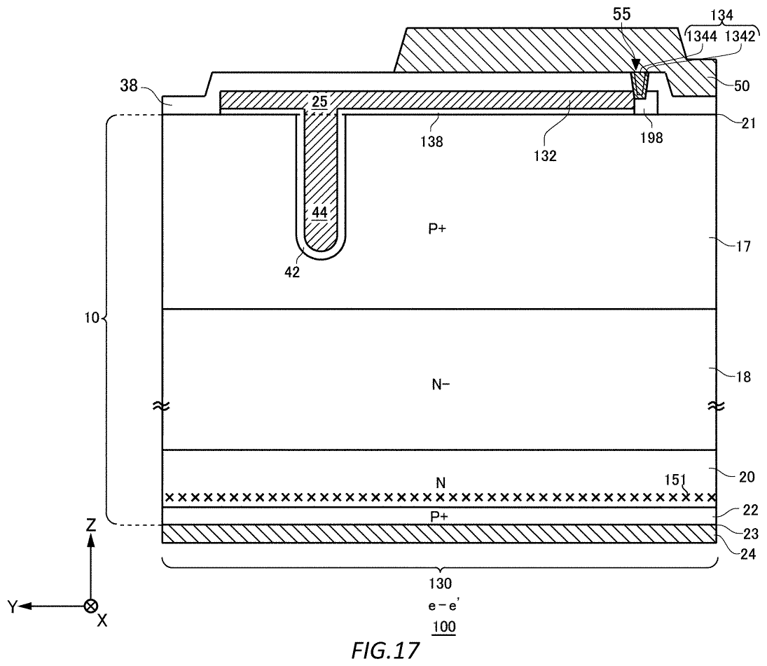

FIG. 17 illustrates an example of the cross section e-e′ in FIG. 9. The semiconductor device 100 in the present example is different from that in the example of FIG. 15 in that the first inactive contact portion 134 has a trench contact structure. Other configurations may be the same as those in the example of FIG. 15.

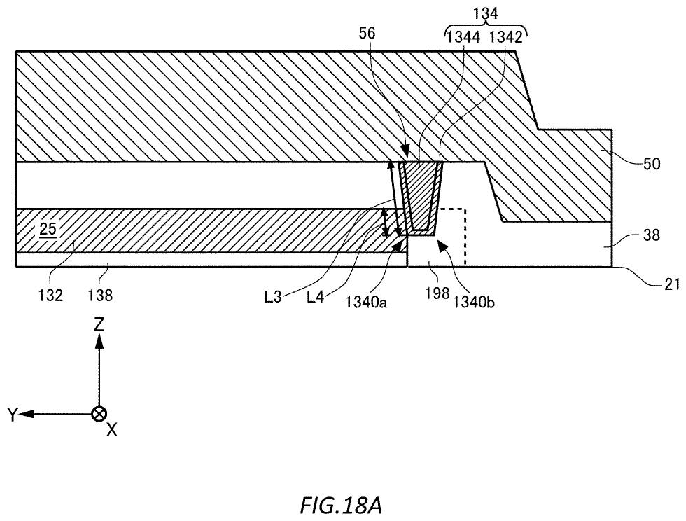

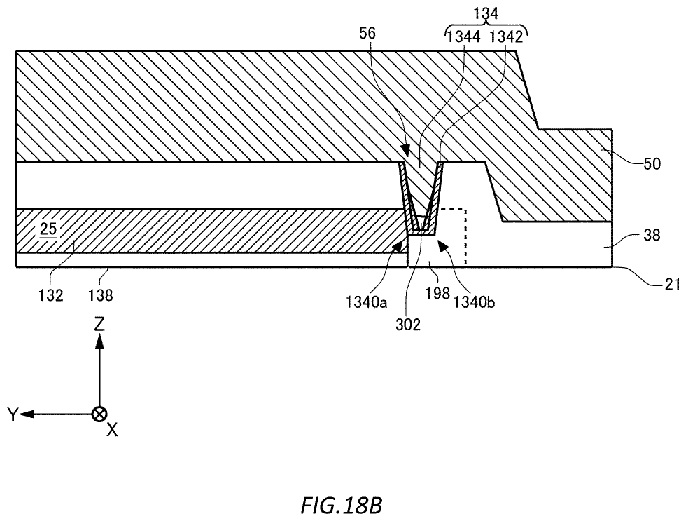

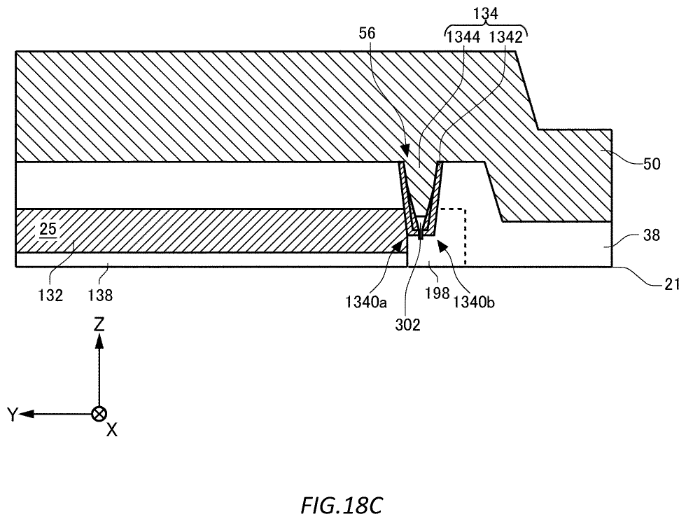

FIG. 18A illustrates an example of the enlarged view of the cross section e-e′ in FIG. 9. The present drawing illustrates the region above the front surface 21 of the semiconductor substrate 10 in the inactive portion 130. The semiconductor device 100 in the present example is different from that in the example of FIG. 16A in that the first inactive contact portion 134 is different in structure. In the present example, the difference from the example of FIG. 16A will be particularly described, and other configurations may be the same as those in the example of FIG. 16A.

The side walls of the first inactive contact portion 134 may have a trench contact structure in contact with the side surface of the polycrystalline portion 132. The bottom surface corner portion 1340 of the first inactive contact portion 134 in the present example is in contact with the polycrystalline portion 132 on the side surface of the polycrystalline portion 132.

The side wall of the first inactive contact portion 134 may be in contact with the polycrystalline portion 132 and the interlayer dielectric film 38. The polycrystalline portion 132 may be in contact with the side wall of the first inactive contact portion 134, from the bottom surface corner portion 1340 to a region of 10% or more and 90% or less of the side wall of the first inactive contact portion 134. The polycrystalline portion 132 in the present example is in contact with the side wall of the first inactive contact portion 134, from the bottom surface corner portion 1340 to a region of 35% of the side wall of the first inactive contact portion 134. That is, the ratio of the length L4 to the length L3 in the present example is 35%.

FIG. 18B illustrates an example of the enlarged view of the cross section e-e′ in FIG. 9 when the void 302 is generated in the first inactive contact portion 134. The present example illustrates a case where, in the etch-back step of the plug portion 1344, the plug portion 1344 near the center of the bottom surface of the first inactive contact portion 134 is removed due to over-etching. In this case, it is difficult to fill the first inactive contact portion 134 with the metal material of the gate metal layer 50, and the void 302 may be generated near the center of the bottom surface of the first inactive contact portion 134.

The first inactive contact portion 134 in the present example is provided such that the bottom surface corner portion 1340 is in contact with the polycrystalline portion 132 and its bottom surface is in contact with the housing portion 198. Therefore, even when the void 302 is generated inside the first inactive contact portion 134, near the center of its bottom surface, the influence on the electrical connection at the bottom surface corner portion 1340 between the first inactive contact portion 134 and the polycrystalline portion 132 is suppressed. Accordingly, it is possible to improve the yield of the semiconductor device 100 having desired characteristics. In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, even when the void 302 is formed in the region near the center of the first inactive contact portion 134 in contact with the housing portion 198, it is possible to obtain stable quality and improve the yield.

FIG. 18C illustrates another example of the enlarged view of the cross section e-e′ in FIG. 9 when the void 302 is generated in the first inactive contact portion 134. The present example illustrates a case where, in the etch-back step of the plug portion 1344, the plug portion 1344 and the barrier metal film 1342 near the center of the bottom surface of the first inactive contact portion 134 are removed due to over-etching, and further, the housing portion 198 is also over-etched. In this case, it is difficult to fill the first inactive contact portion 134 with the metal material of the gate metal layer 50, and the void 302 may be generated near the center of the bottom surface of the first inactive contact portion 134.

In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, similarly to the example of FIG. 18B, even when the void 302 is formed in the region near the center of the first inactive contact portion 134 in contact with the housing portion 198, it is possible to obtain stable quality and improve the yield.

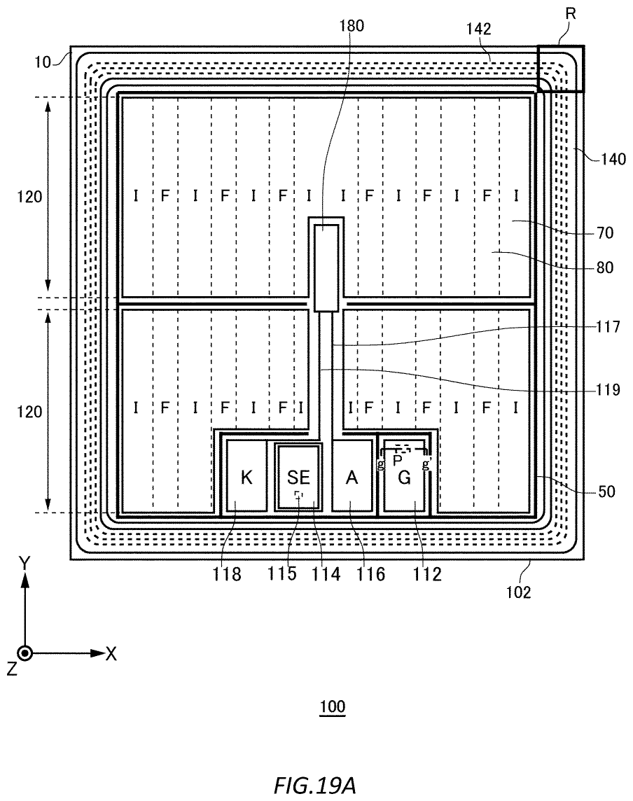

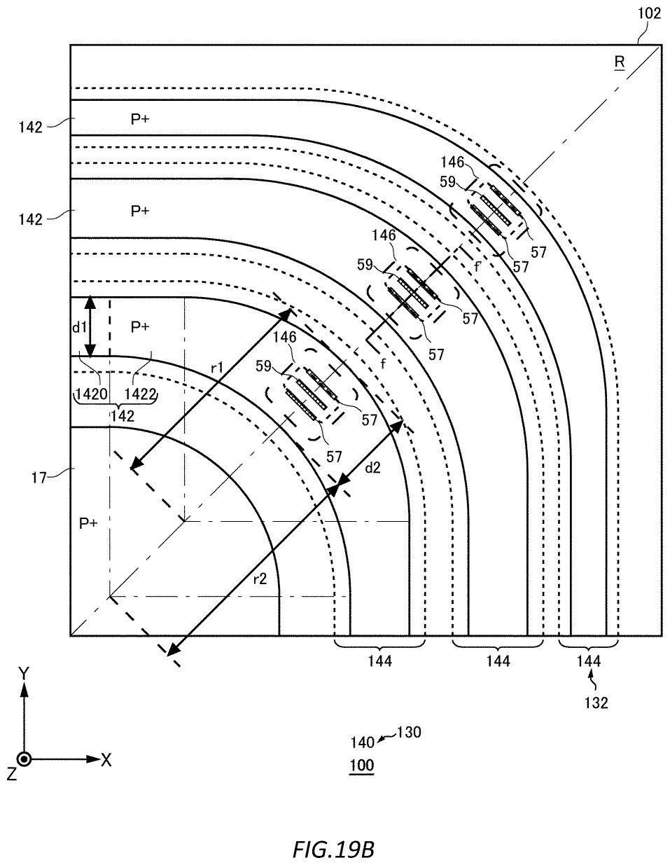

FIG. 19A illustrates an example of the top view of the semiconductor device 100. The semiconductor device 100 in the present example includes a guard ring 142 in the edge termination structure portion 140. The semiconductor device 100 may include a plurality of guard rings 142. The guard ring 142 is a region of the second conductivity type which is provided between the active portion 120 and the end side 102 of the semiconductor substrate 10 at the front surface 21 of the semiconductor substrate 10. The guard ring 142 is of the P+ type as an example. The guard ring 142 may enclose the active portion 120 in top view. In the present example, the well region 17 adjacent to the active portion 120 may also be included in the guard ring 142. In addition, a plurality of guard rings 142 may be provided. The guard ring 142 arranged on an outside may enclose the guard ring 142 arranged on an inside. The outside refers to a side close to the end side 102, and the inside refers to a side close to a center of the semiconductor substrate 10 in top view. By providing the guard ring 142, the depletion layer on the front surface 21 side of the active portion 120 can be extended to the end side 102 side, and a withstand voltage of the semiconductor device 100 can be improved. The guard ring 142, which is spaced apart from the well region 17 adjacent to the active portion 120, may also be formed in the same diffusion process as that of the well region 17, and its inner and outer diffusion shapes may be substantially the same. In another example, the guard ring 142 may be a VLD in which a depth becomes shallower toward the outer side. In still another example, the guard ring 142 may be formed in the same diffusion process as that of the base region 14. The semiconductor device 100 may further include at least one of a field plate or a RESURF provided to enclose the active portion 120 in the edge termination structure portion 140.

FIG. 19B illustrates an example of a region R in FIG. 19A. The semiconductor device 100 in the present example includes the guard ring 142 and a field plate 144 in the edge termination structure portion 140. The edge termination structure portion 140 is an example of the inactive portion 130. The semiconductor device 100 may include the interlayer dielectric film 38, an edge metal layer 146, and a field dielectric film 148 in the edge termination structure portion 140. The interlayer dielectric film 38 and the field dielectric film 148 are omitted in FIG. 19B. A contact hole 57 and a contact hole 59 are provided to penetrate the interlayer dielectric film 38.

The field plate 144 is a conductive member provided above the semiconductor substrate 10. The field plate 144 in the present example is formed of polysilicon doped with impurities. The field plate 144 is an example of the polycrystalline portion 132. The field plate 144 is provided above the guard ring 142. The field plate 144 may be electrically connected to the guard ring 142 corresponding thereto.

The guard ring 142 has a non-corner region 1420 and a corner region 1422. The non-corner region 1420 is, for example, a region of the guard ring 142 extending along the end side 102 of the semiconductor substrate 10, and the corner region 1422 is, for example, a part connecting the regions of the guard ring 142 extending along the end side 102 of the semiconductor substrate 10.

The contact hole 57 connects the edge metal layer 146 and the field plate 144. A barrier metal film formed of titanium, a titanium compound, or the like and/or a plug portion formed of tungsten or the like may be formed inside the contact hole 57.

The contact hole 59 connects the edge metal layer 146 and the guard ring 142. A barrier metal film formed of titanium, a titanium compound, or the like and/or a plug portion formed of tungsten or the like may be formed inside the contact hole 59. The field plate 144 may not be provided around the contact hole 59.

The contact hole 57 and the contact hole 59 may be provided above the corner region 1422 of the guard ring 142. However, at least one of the contact hole 57 or the contact hole 59 may be provided above the non-corner region 1420 of the guard ring 142, or both the contact hole 57 and the contact hole 59 may be provided above the non-corner region 1420 of the guard ring 142. The contact hole 57 and the contact hole 59 in the present example are elongated in a direction in which the guard ring 142 and the field plate 144 extend, and are provided side by side from a center side to the end side 102 side. In another example, the contact hole 57 and the contact hole 59 may be arrayed in the direction in which the guard ring 142 and the field plate 144 extend, the longitudinal direction of each contact hole may be a direction from the center side to the end side 102 side, and each contact hole may include a plurality of contact holes.

A width d2 of the corner region 1422 may be wider than a width d1 of the non-corner region 1420. That is, a curvature radius r1 on the end side 102 side (outside) may be smaller than a sum of a curvature radius r2 on the center side (inside) and d1. In the present example, r1 is smaller than r2. The edge metal layer 146 may be provided at a widest portion of the corner region 1422 or in a vicinity thereof. In another example, the width d2 of the corner region 1422 may be equal to the width d1 of the non-corner region 1420. In addition, in still another example, the edge metal layer 146 may be provided in the non-corner region 1420, or may be provided across the non-corner region 1420 and the corner region 1422.

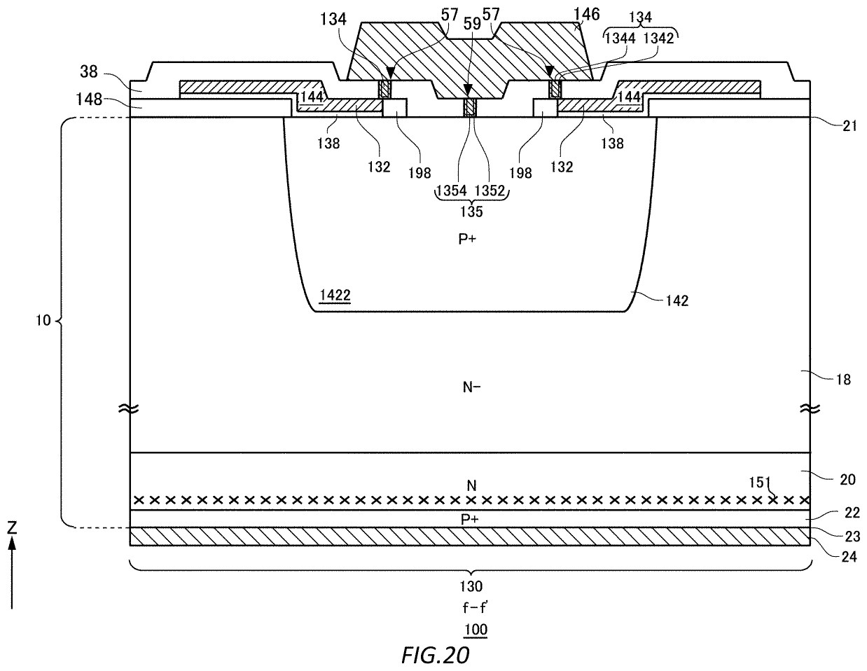

FIG. 20 illustrates an example of a cross section f-f′ in FIG. 19B. The cross section f-f′ is a plane, in the inactive portion 130, passing through the contact hole 57 and the contact hole 59 and parallel to the Z axis direction. The semiconductor device 100 in the present example includes, in the cross section f-f′, the semiconductor substrate 10, the interlayer dielectric film 38, the field dielectric film 148, the edge metal layer 146, the collector electrode 24, the first inactive contact portion 134, and a second inactive contact portion 135.

The field dielectric film 148 is provided above the semiconductor substrate 10. The field dielectric film 148 may be provided so as to cover the drift region 18 exposed on the front surface 21 of the semiconductor substrate 10 between the well region 17 adjacent to the active portion 120 and the guard ring 142 and between the guard rings 142. The field dielectric film 148 may be provided so as to enclose the active portion 120 along the guard ring 142.

The field dielectric film 148 may include a dielectric film obtained by oxidizing or nitriding the semiconductor substrate 10, may include a dielectric film deposited by CVD or the like, or may include another dielectric film. The field dielectric film 148 may be a dielectric film with a single layer, or may be a dielectric film in which a plurality of films formed by different methods are stacked.

The edge metal layer 146 is provided above the semiconductor substrate 10 and is electrically connected to the guard ring 142. The edge metal layer 146 is provided above the semiconductor substrate 10 with the interlayer dielectric film 38 interposed therebetween. The edge metal layer 146 may be electrically connected to the field plate 144. The edge metal layer 146 may be electrically floating. For example, when a voltage V is applied to the collector electrode 24 in a state where the gate of the semiconductor device 100 is off, the edge metal layer 146 is at a predetermined voltage lower than the voltage V. When the guard ring 142 is the well region 17 adjacent to the active portion 120, the edge metal layer 146 may be at the same potential as that of the emitter electrode 52.

The edge metal layer 146 is formed of a material containing metal. At least a partial region of the edge metal layer 146 may be formed of metal such as aluminum (Al) or of a metal alloy such as an aluminum-silicon alloy (AlSi) or an aluminum-silicon-copper alloy (AlSiCu). The polycrystalline portion 132 is provided above the semiconductor substrate. The polycrystalline portion 132 in the present example is the field plate 144. The polycrystalline portion 132 may be provided above the third interlayer dielectric film 138. The third interlayer dielectric film 138 may be, for example, the same material as that of the gate dielectric film 42 and/or the dummy dielectric film 32. The third interlayer dielectric film 138 may be a thermal oxide film. In another example, the third interlayer dielectric film 138 may be a material different from that of the gate dielectric film 42 and/or the dummy dielectric film 32. The interlayer dielectric film 38 is provided above the polycrystalline portion 132.

The first inactive contact portion 134 is provided to extend from the upper surface to the lower surface of the interlayer dielectric film 38. The contact hole 57 may be provided to penetrate the interlayer dielectric film 38. The first inactive contact portion 134 may include the contact hole 57 and a metal layer with which an inside of the contact hole 57 is filled. The housing portion 198 is provided below the first inactive contact portion 134. The field dielectric film 148 may be provided below the interlayer dielectric film 38. The polycrystalline portion 132 may be connected to the edge metal layer 146 via the first inactive contact portion 134. The field plate 144 in the present example is connected to the edge metal layer 146 via the first inactive contact portion 134.

The second inactive contact portion 135 is provided to extend from the upper surface to the lower surface of the interlayer dielectric film 38. The contact hole 59 may be provided to penetrate the interlayer dielectric film 38. The second inactive contact portion 135 may include the contact hole 59 and a metal layer with which an inside of the contact hole 59 is filled. The guard ring 142 may be connected to the edge metal layer 146 via the second inactive contact portion 135. The guard ring 142 in the present example is connected to the edge metal layer 146 via the second inactive contact portion 135. The second inactive contact portion 135 may have a configuration similar to that of the active contact portion 124. That is, the second inactive contact portion 135 may include a barrier metal film 1352 and a plug portion 1354.

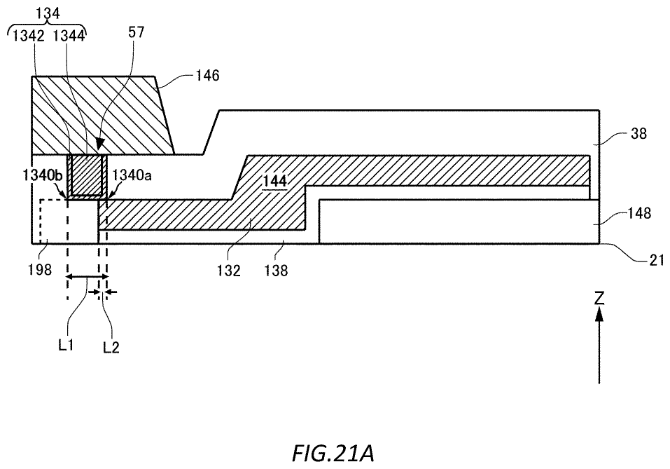

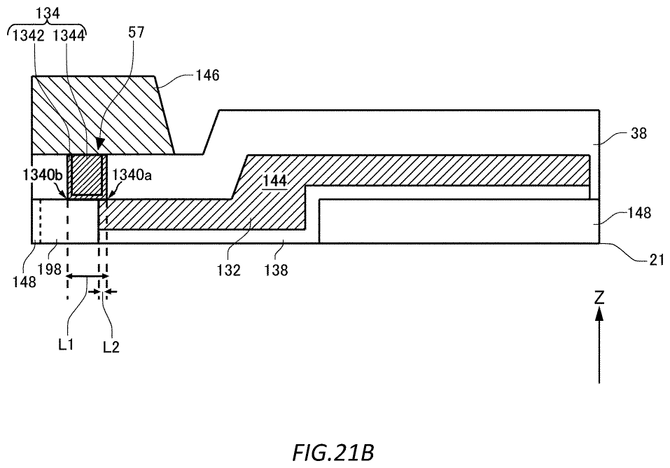

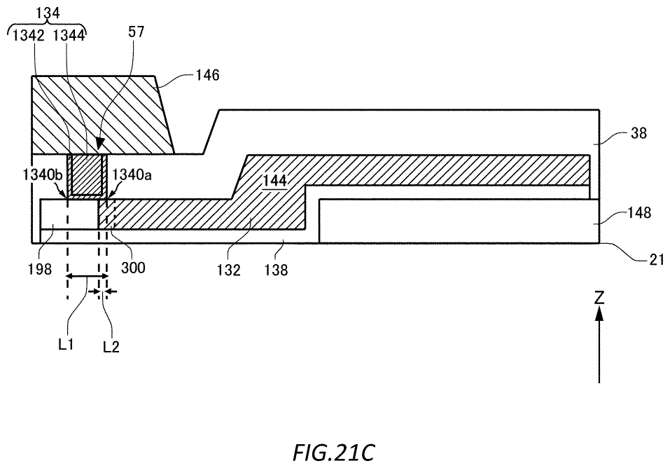

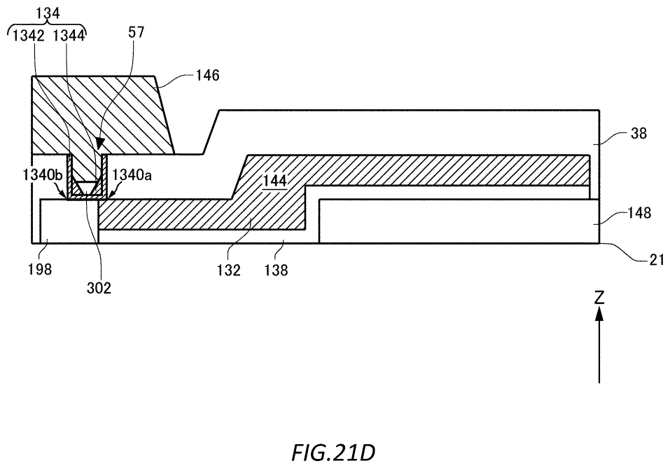

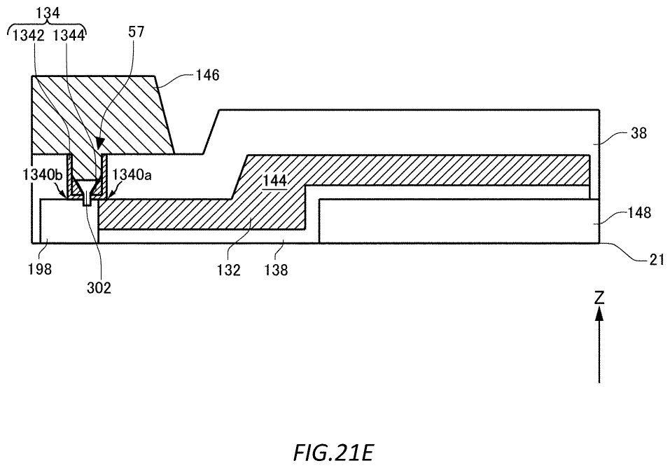

FIG. 21A illustrates an example of an enlarged view of the cross section f-f′ in FIG. 19B. The present drawing illustrates the region above the front surface 21 of the semiconductor substrate 10 in the inactive portion 130.

The bottom surface corner portion 1340 of the first inactive contact portion 134 may be in contact with the polycrystalline portion 132. The bottom surface corner portion 1340 in the present example is in contact with the polycrystalline portion 132 on the upper surface of the polycrystalline portion 132.

The bottom surface of the first inactive contact portion 134 may be in contact with the housing portion 198. In the first inactive contact portion 134 in the present example, the bottom surface is in contact with the housing portion 198 on the upper surface of the housing portion 198.

The first inactive contact portion 134 in the present example is provided such that the bottom surface corner portion 1340 is in contact with the polycrystalline portion 132 and its bottom surface is in contact with the housing portion 198. Accordingly, it is possible to reliably secure electrical connection between the edge metal layer 146 and the polycrystalline portion 132. In the etch-back step of the plug portion 1344, when the plug portion 1344 and the barrier metal film 1342 near the center of the bottom surface of the first inactive contact portion 134 are removed due to over-etching, a void may be generated inside the first inactive contact portion 134. Even in this case, the electrical connection can be secured by the barrier metal film 1342 and/or the plug portion 1344 remaining at the bottom surface corner portion 1340 of the first inactive contact portion 134.

The bottom surface of the first inactive contact portion 134 in the present example is provided in contact with the housing portion 198. Therefore, even when a void is generated inside the temperature sensitive contact portion, near the center of its bottom surface, the influence on the electrical connection at the bottom surface corner portion 1340 between the first inactive contact portion 134 and the polycrystalline portion 132 is suppressed. Accordingly, it is possible to improve the yield of the semiconductor device 100 having desired characteristics. In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, even when a void is formed in a region near the center of the first inactive contact portion 134 in contact with the housing portion 198, it is possible to obtain stable quality and improve the yield.

The bottom surface of the first inactive contact portion 134 may be in contact with the polycrystalline portion 132 and the housing portion 198. In the first inactive contact portion 134 in the present example, one bottom surface corner portion 1340a is in contact with the polycrystalline portion 132, and another bottom surface corner portion 1340b is in contact with the housing portion 198, so that the bottom surface of the first inactive contact portion 134 is in contact with the polycrystalline portion 132 and the housing portion 198.

The polycrystalline portion 132 may be in contact with the bottom surface of the first inactive contact portion 134, from the bottom surface corner portion 1340 to a region of 10% or more and 40% or less of the bottom surface of the first inactive contact portion 134. The polycrystalline portion 132 in the present example is in contact with the bottom surface of the first inactive contact portion 134, from the bottom surface corner portion 1340a to a region of 20% of the bottom surface of the first inactive contact portion 134. That is, the ratio of the length L2 to the length L1 in the present example is 20%.

The barrier metal film 1342 may be provided on the bottom surface corner portion 1340 of the first inactive contact portion 134. The barrier metal film 1342 in the present example is provided over the entire side surfaces and bottom surface of the first inactive contact portion 134, but is not limited thereto. The barrier metal film 1342 may be provided so as to cover at least the bottom surface corner portion 1340, or may be provided without covering the central portion of the bottom surface of the first inactive contact portion 134. The barrier metal film 1342 may be provided to protrude from the contact hole 57 and reach above the interlayer dielectric film 38. The material of the barrier metal film 1342 may be titanium, a titanium compound, or the like.

The plug portion 1344 may be provided in contact with the inside of the barrier metal film 1342. The plug portion 1344 in the present example is provided to fill the first inactive contact portion 134, but is not limited thereto. The plug portion 1344 may be provided in a part of the first inactive contact portion 134, and may be provided to protrude from the contact hole 57 and reach above the interlayer dielectric film 38. When the plug portion 1344 is provided in a part of the first inactive contact portion 134, a remaining region of the first inactive contact portion 134 may be filled with the same material as that of the edge metal layer 146. The material of the plug portion 1344 may be a plug metal such as tungsten.

The side surface of the polycrystalline portion 132 may be in contact with the side surface of the housing portion 198. The housing portion 198 may be a region, which is provided below the first inactive contact portion 134, in the interlayer dielectric film 38. The housing portion 198 may be formed in a step of providing the interlayer dielectric film 38, and may be formed of the same material as that of the interlayer dielectric film 38. When the housing portion 198 is formed as the region, which is provided below the first inactive contact portion 134, in the interlayer dielectric film 38, the housing portion 198 is a virtual region as indicated by a dotted line in FIG. 21A. That is, the housing portion 198 may be integrally formed as a part of the interlayer dielectric film 38. In another example, the housing portion 198 may be the third interlayer dielectric film 138 provided above the semiconductor substrate 10. The housing portion 198 may be formed in a step of providing the third interlayer dielectric film 138, and may be formed of the same material as that of the third interlayer dielectric film 138. That is, the housing portion 198 may be integrally formed as a part of the third interlayer dielectric film 138.

FIG. 21B illustrates an example of the enlarged view of the cross section f-f′ in FIG. 19B. The present drawing illustrates the region above the front surface 21 of the semiconductor substrate 10 in the inactive portion 130. The semiconductor device 100 in the present example is different from that in the example of FIG. 21A in that the housing portion 198 is a region, which is provided below the first inactive contact portion 134, in the field dielectric film 148. Other configurations may be the same as those in the example of FIG. 21A.

FIG. 21C illustrates an example of the enlarged view of the cross section f-f′ in FIG. 19B. The present drawing illustrates the region above the front surface 21 of the semiconductor substrate 10 in the inactive portion 130. The semiconductor device 100 in the present example is different from those in the examples of FIGS. 21A and 21B in that the housing portion 198 is provided separately from the interlayer dielectric film 38 and the field dielectric film 148. In the present example, the difference from the examples of FIGS. 21A and 21B will be particularly described, and other configurations may be the same as those in the examples of FIGS. 21A and/or 21B.

The housing portion 198 may include polysilicon having an impurity concentration lower than that of the contact region 300 of the polycrystalline portion 132. The contact region 300 of the polycrystalline portion 132 may be a region of the polycrystalline portion 132 in contact with the housing portion 198. For example, the housing portion 198 includes polysilicon having an impurity concentration lower than that of the polycrystalline portion 132 or non-doped polysilicon. FIG. 21D illustrates an example of the enlarged view of the cross section f-f′ in FIG. 19B when the void 302 is generated in the first inactive contact portion 134. The present example illustrates a case where, in the etch-back step of the plug portion 1344, the plug portion 1344 near the center of the bottom surface of the first inactive contact portion 134 is removed due to over-etching. In this case, it is difficult to fill the first inactive contact portion 134 with the metal material of the edge metal layer 146, and the void 302 may be generated near the center of the bottom surface of the first inactive contact portion 134.

The first inactive contact portion 134 in the present example is provided such that the bottom surface corner portion 1340 is in contact with the polycrystalline portion 132 and its bottom surface is in contact with the housing portion 198. Therefore, even when the void 302 is generated inside the first inactive contact portion 134, near the center of its bottom surface, the influence on the electrical connection at the bottom surface corner portion 1340 between the first inactive contact portion 134 and the polycrystalline portion 132 is suppressed. Accordingly, it is possible to improve the yield of the semiconductor device 100 having desired characteristics. In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, even when the void 302 is formed in the region near the center of the first inactive contact portion 134 in contact with the housing portion 198, it is possible to obtain stable quality and improve the yield.

FIG. 21E illustrates another example of the enlarged view of the cross section f-f′ in FIG. 19B when the void 302 is generated in the first inactive contact portion 134. The present example illustrates a case where, in the etch-back step of the plug portion 1344, the plug portion 1344 and the barrier metal film 1342 near the center of the bottom surface of the first inactive contact portion 134 are removed due to over-etching, and further, the housing portion 198 is also over-etched. In this case, it is difficult to fill the first inactive contact portion 134 with the metal material of the edge metal layer 146, and the void 302 may be generated near the center of the bottom surface of the first inactive contact portion 134.

In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, similarly to the example of FIG. 21D, even when the void 302 is formed in the region near the center of the first inactive contact portion 134 in contact with the housing portion 198, it is possible to obtain stable quality and improve the yield.

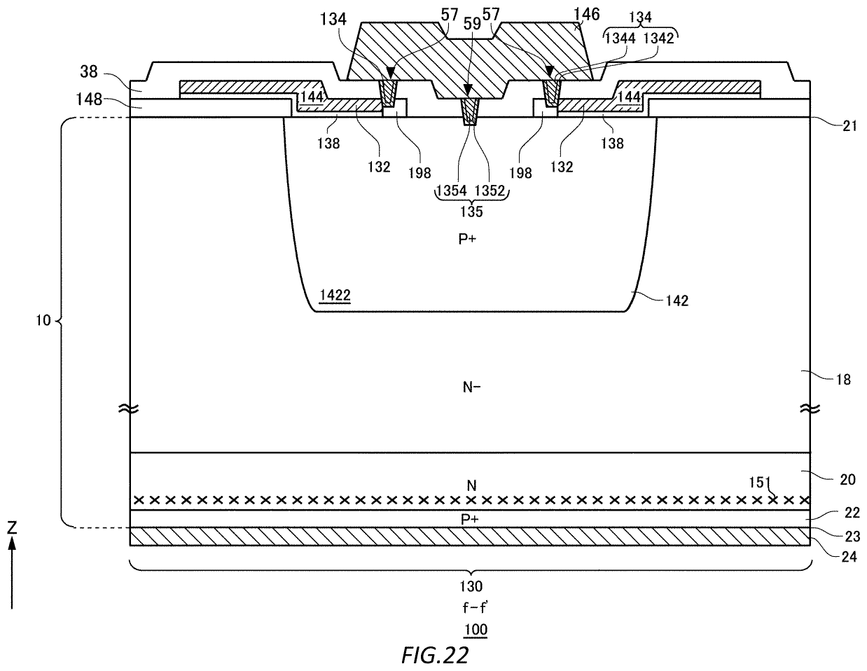

FIG. 22 illustrates an example of the cross section f-f′ in FIG. 19B. The semiconductor device 100 in the present example is different from that in the example of FIG. 20 in that the first inactive contact portion 134 has a trench contact structure. Other configurations may be the same as those in the example of FIG. 20.

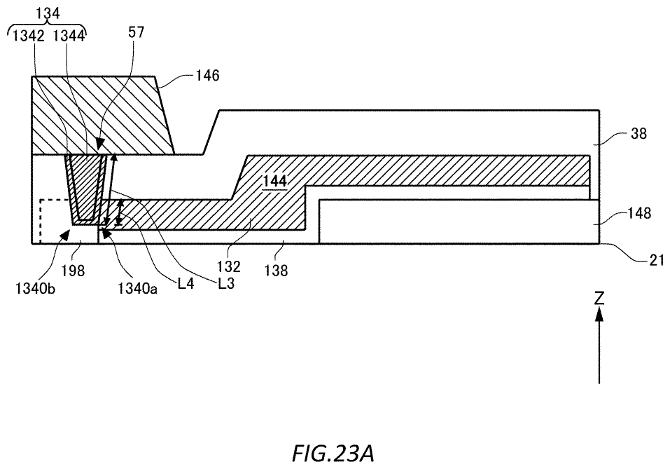

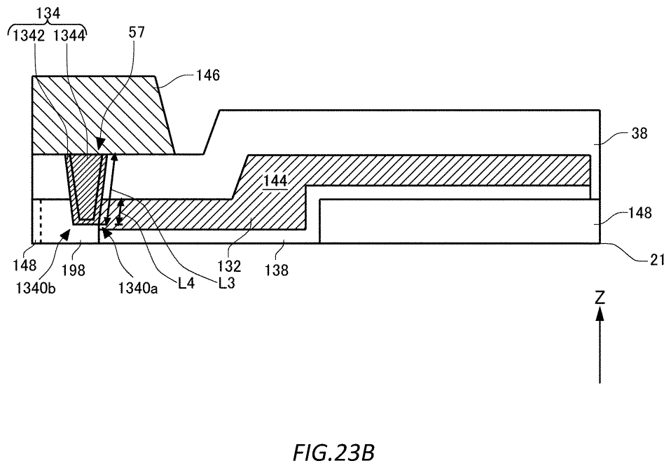

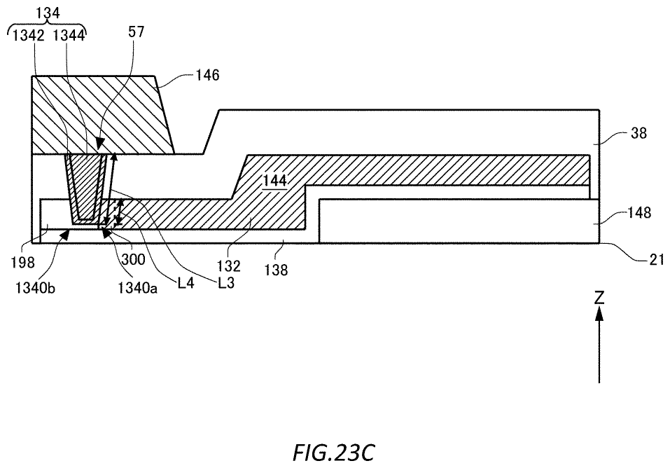

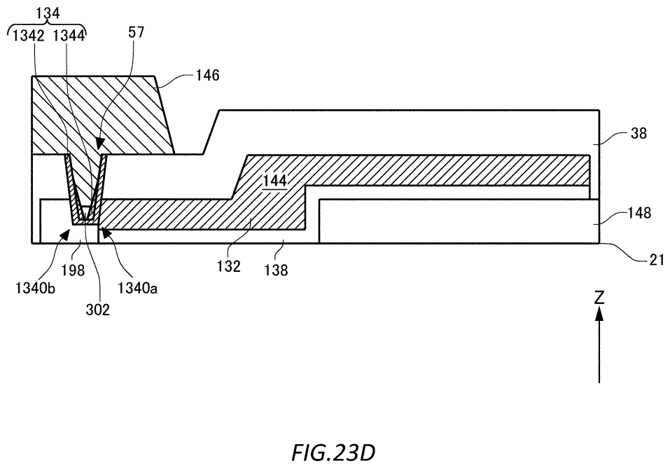

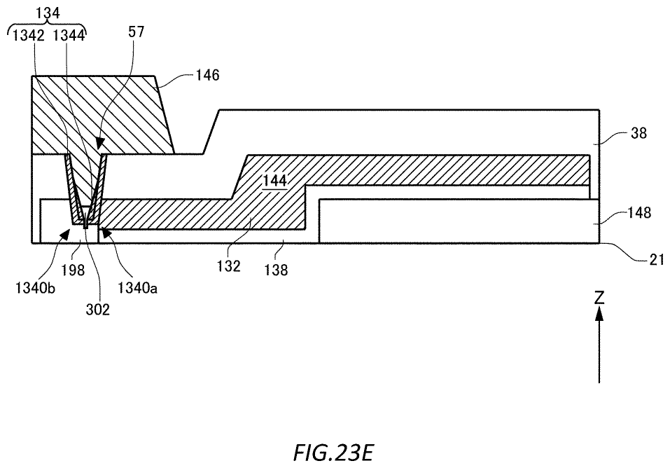

FIG. 23A illustrates an example of the enlarged view of the cross section f-f′ in FIG. 19B. The present drawing illustrates the region above the front surface 21 of the semiconductor substrate 10 in the inactive portion 130. The semiconductor device 100 in the present example is different from that in the example of FIG. 21A in that the first inactive contact portion 134 is different in structure. In the present example, the difference from the example of FIG. 21A will be particularly described, and other configurations may be the same as those in the example of FIG. 21A.

The side walls of the first inactive contact portion 134 may have a trench contact structure in contact with the side surface of the polycrystalline portion 132. The bottom surface corner portion 1340 of the first inactive contact portion 134 in the present example is in contact with the polycrystalline portion 132 on the side surface of the polycrystalline portion 132.

The side wall of the first inactive contact portion 134 may be in contact with the polycrystalline portion 132 and the interlayer dielectric film 38. The polycrystalline portion 132 may be in contact with the side wall of the first inactive contact portion 134, from the bottom surface corner portion 1340 to a region of 10% or more and 90% or less of the side wall of the first inactive contact portion 134. The polycrystalline portion 132 in the present example is in contact with the side wall of the first inactive contact portion 134, from the bottom surface corner portion 1340 to a region of 35% of the side wall of the first inactive contact portion 134. That is, the ratio of the length L4 to the length L3 in the present example is 35%.

FIG. 23B illustrates an example of the enlarged view of the cross section f-f′ in FIG. 19B. The present drawing illustrates the region above the front surface 21 of the semiconductor substrate 10 in the inactive portion 130. The semiconductor device 100 in the present example is different from that in the example of FIG. 23A in that the housing portion 198 is a region, which is provided below the first inactive contact portion 134, in the field dielectric film 148. Other configurations may be the same as those in the example of FIG. 23A.

FIG. 23C illustrates an example of the enlarged view of the cross section f-f′ in FIG. 19B. The present drawing illustrates the region above the front surface 21 of the semiconductor substrate 10 in the inactive portion 130. The semiconductor device 100 in the present example is different from those in the examples of FIGS. 23A and 23B in that the housing portion 198 is provided separately from the interlayer dielectric film 38 and the field dielectric film 148, and the housing portion 198 includes polysilicon having an impurity concentration lower than that of the contact region 300 of the polycrystalline portion 132. Other configurations may be the same as those in the examples of FIGS. 23A and/or 23B.

FIG. 23D illustrates an example of the enlarged view of the cross section f-f′ in FIG. 19B when the void 302 is generated in the first inactive contact portion 134. The present example illustrates a case where, in the etch-back step of the plug portion 1344, the plug portion 1344 near the center of the bottom surface of the first inactive contact portion 134 is removed due to over-etching. In this case, it is difficult to fill the first inactive contact portion 134 with the metal material of the edge metal layer 146, and the void 302 may be generated near the center of the bottom surface of the first inactive contact portion 134.

The first inactive contact portion 134 in the present example is provided such that the bottom surface corner portion 1340 is in contact with the polycrystalline portion 132 and the bottom surface is in contact with the housing portion 198. Therefore, even when the void 302 is generated inside the first inactive contact portion 134, near the center of its bottom surface, the influence on the electrical connection at the bottom surface corner portion 1340 between the first inactive contact portion 134 and the polycrystalline portion 132 is suppressed. Accordingly, it is possible to improve the yield of the semiconductor device 100 having desired characteristics. In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, even when the void 302 is formed in the region near the center of the first inactive contact portion 134 in contact with the housing portion 198, it is possible to obtain stable quality and improve the yield.

FIG. 23E illustrates another example of the enlarged view of the cross section f-f′ in FIG. 19B when the void 302 is generated in the first inactive contact portion 134. The present example illustrates a case where, in the etch-back step of the plug portion 1344, the plug portion 1344 and the barrier metal film 1342 near the center of the bottom surface of the first inactive contact portion 134 are removed due to over-etching, and further, the housing portion 198 is also over-etched. In this case, it is difficult to fill the first inactive contact portion 134 with the metal material of the edge metal layer 146, and the void 302 may be generated near the center of the bottom surface of the first inactive contact portion 134.

In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, similarly to the example of FIG. 23D, even when the void 302 is formed in the region near the center of the first inactive contact portion 134 in contact with the housing portion 198, it is possible to obtain stable quality and improve the yield.

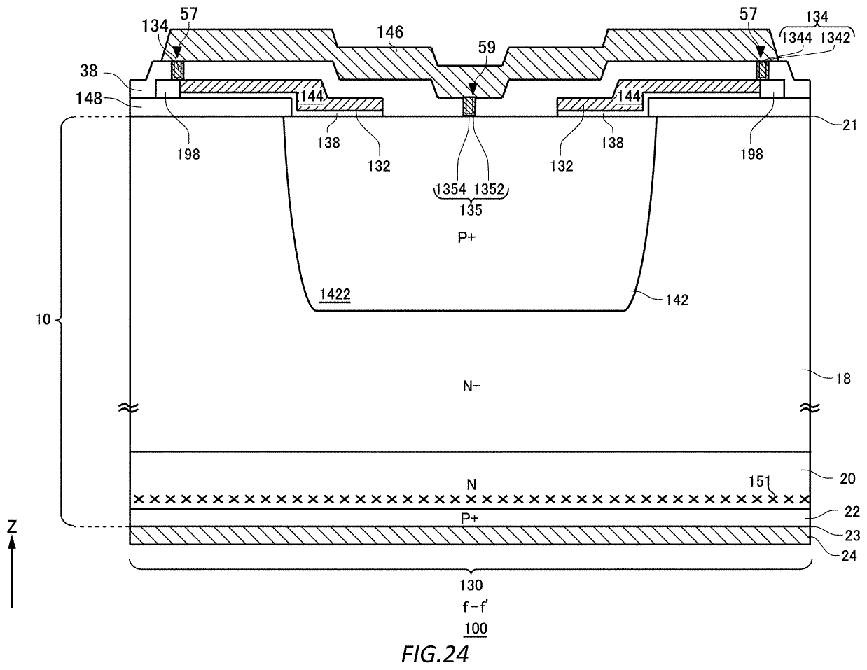

FIG. 24 illustrates an example of the cross section f-f′ in FIG. 19B. The semiconductor device 100 in the present example is different from that in the example of FIG. 20 in that the first inactive contact portion 134 is provided above the polycrystalline portion 132 positioned above the field dielectric film 148. Other configurations may be the same as those in the example of FIG. 20.

The first inactive contact portion 134 in FIG. 20 and the first inactive contact portion 134 in FIG. 24 may be provided separately, or may be provided in combination. For example, as the first inactive contact portion 134 connecting the edge metal layer 146 and the polycrystalline portion 132, the first inactive contact portion 134 may be provided only at an end portion of the field plate 144 on a guard ring 142 side as illustrated in FIG. 20, the first inactive contact portion 134 may be provided only at an end portion of the field plate 144 on a side spaced apart from the guard ring 142 as illustrated in FIG. 24, or the first inactive contact portion 134 may be provided at both the end portion of the field plate 144 on the guard ring 142 side and the end portion on the side spaced apart from the guard ring 142. The first inactive contact portion 134 may be provided only at an end portion of one field plate 144 on a side apart from the guard ring 142 when viewed from the contact hole 59. The edge metal layer 146 and the guard ring 142 are electrically connected via the contact hole 59 into which the second inactive contact portion 135 is embedded.

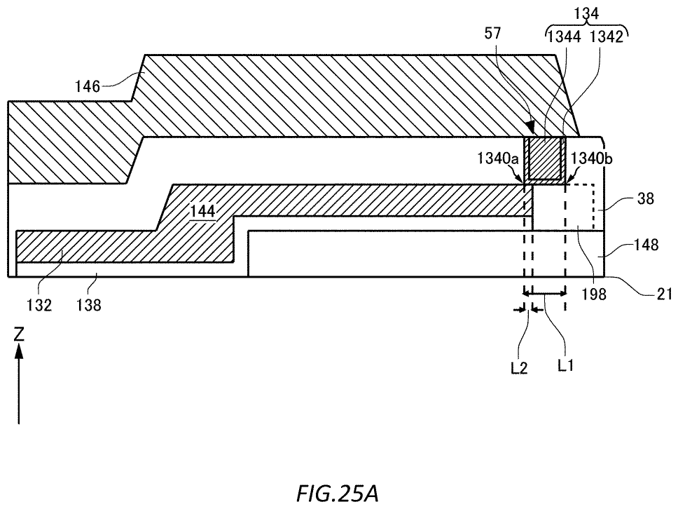

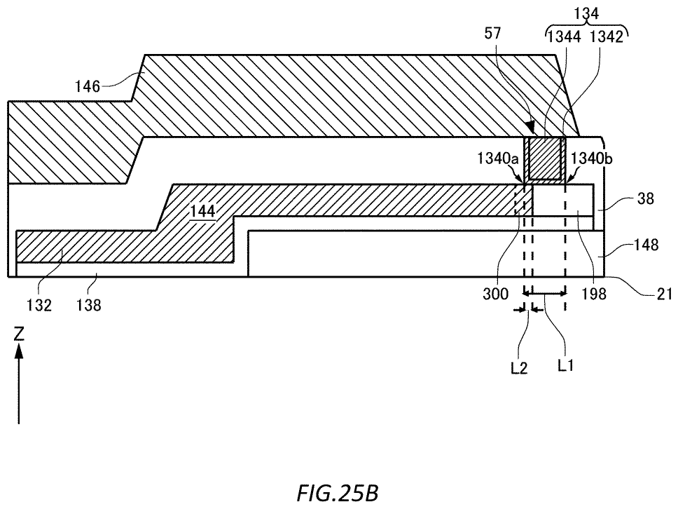

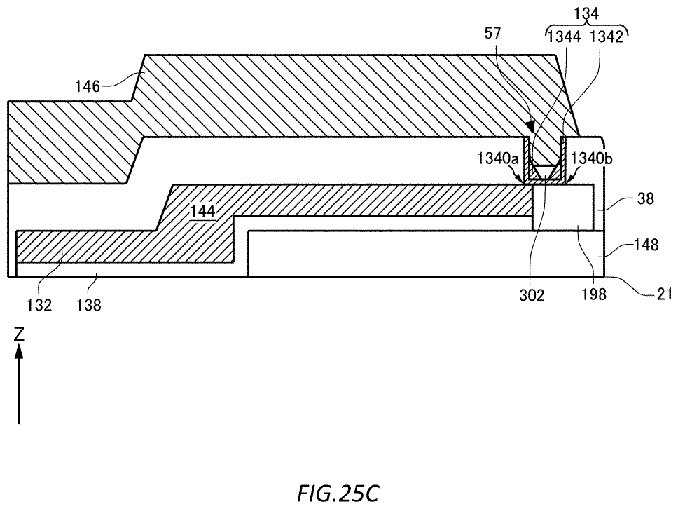

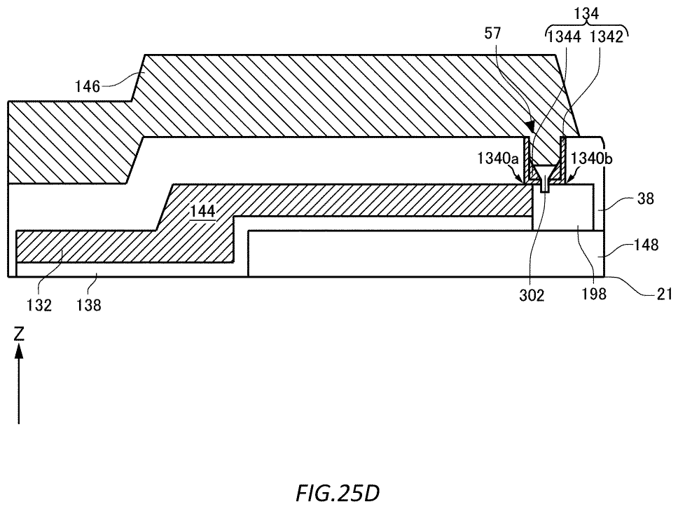

FIG. 25A illustrates an example of the enlarged view of the cross section f-f′ in FIG. 19B. The present drawing illustrates the region above the front surface 21 of the semiconductor substrate 10 in the inactive portion 130. The semiconductor device 100 in the present example is different from that in the example of FIG. 21A in that the first inactive contact portion 134 is provided above the polycrystalline portion 132 positioned above the field dielectric film 148. Other configurations may be the same as those in the example of FIG. 21A.

FIG. 25B illustrates an example of the enlarged view of the cross section f-f′ in FIG. 19B. The present drawing illustrates the region above the front surface 21 of the semiconductor substrate 10 in the inactive portion 130. The semiconductor device 100 in the present example is different from that in the example of FIG. 25A in that the housing portion 198 is provided separately from the interlayer dielectric film 38, and the housing portion 198 includes polysilicon having an impurity concentration lower than that of the contact region 300 of the polycrystalline portion 132. Other configurations may be the same as those in the example of FIG. 25A.

FIG. 25C illustrates an example of the enlarged view of the cross section f-f′ in FIG. 19B when the void 302 is generated in the first inactive contact portion 134. The present example illustrates a case where, in the etch-back step of the plug portion 1344, the plug portion 1344 near the center of the bottom surface of the first inactive contact portion 134 is removed due to over-etching. In this case, it is difficult to fill the first inactive contact portion 134 with the metal material of the edge metal layer 146, and the void 302 may be generated near the center of the bottom surface of the first inactive contact portion 134.

The first inactive contact portion 134 in the present example is provided such that the bottom surface corner portion 1340 is in contact with the polycrystalline portion 132 and the bottom surface is in contact with the housing portion 198. Therefore, even when the void 302 is generated inside the first inactive contact portion 134, near the center of its bottom surface, the influence on the electrical connection at the bottom surface corner portion 1340 between the first inactive contact portion 134 and the polycrystalline portion 132 is suppressed. Accordingly, it is possible to improve the yield of the semiconductor device 100 having desired characteristics. In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, even when the void 302 is formed in the region near the center of the first inactive contact portion 134 in contact with the housing portion 198, it is possible to obtain stable quality and improve the yield.

FIG. 25D illustrates another example of the enlarged view of the cross section f-f′ in FIG. 19B when the void 302 is generated in the first inactive contact portion 134. The present example illustrates a case where, in the etch-back step of the plug portion 1344, the plug portion 1344 and the barrier metal film 1342 near the center of the bottom surface of the first inactive contact portion 134 are removed due to over-etching, and further, the housing portion 198 is also over-etched. In this case, it is difficult to fill the first inactive contact portion 134 with the metal material of the edge metal layer 146, and the void 302 may be generated near the center of the bottom surface of the first inactive contact portion 134.

In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, similarly to the example of FIG. 25C, even when the void 302 is formed in the region near the center of the first inactive contact portion 134 in contact with the housing portion 198, it is possible to obtain stable quality and improve the yield.

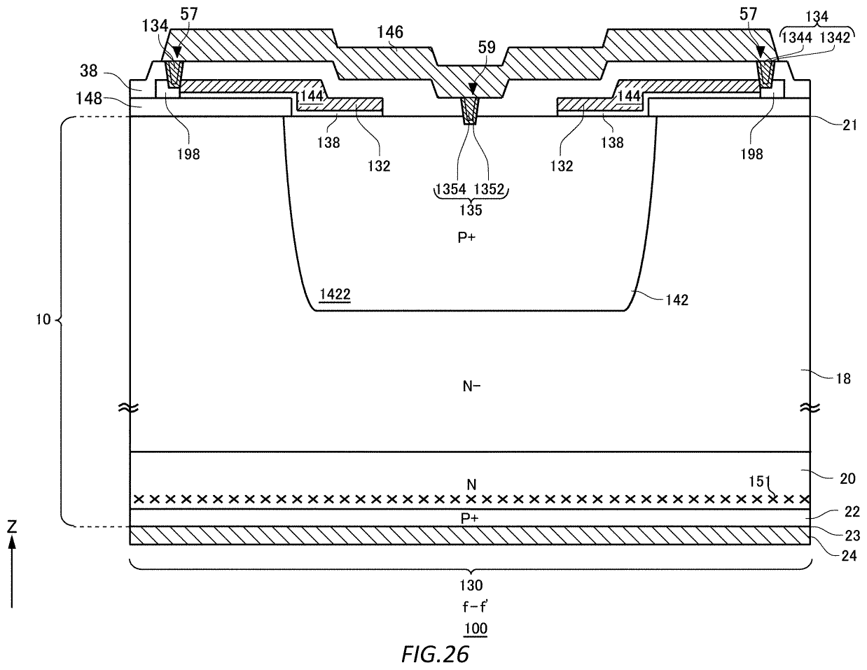

FIG. 26 illustrates an example of the cross section f-f′ in FIG. 19B. The semiconductor device 100 in the present example is different from that in the example of FIG. 22 in that the first inactive contact portion 134 is provided above the polycrystalline portion 132 positioned above the field dielectric film 148. Other configurations may be the same as those in the example of FIG. 22.

The first inactive contact portion 134 in FIG. 22 and the first inactive contact portion 134 in FIG. 26 may be provided separately, or may be provided in combination. For example, as the first inactive contact portion 134 connecting the edge metal layer 146 and the polycrystalline portion 132, the first inactive contact portion 134 may be provided only at the end portion of the field plate 144 on the guard ring 142 side as illustrated in FIG. 22, the first inactive contact portion 134 may be provided only at the end portion of the field plate 144 on the side spaced apart from the guard ring 142 as illustrated in FIG. 26, or the first inactive contact portion 134 may be provided at both the end portion of the field plate 144 on the guard ring 142 side and the end portion on the side spaced apart from the guard ring 142. The first inactive contact portion 134 may be provided only at the end portion of one field plate 144 on the side apart from the guard ring 142 when viewed from the contact hole 59. The edge metal layer 146 and the guard ring 142 are electrically connected via the contact hole 59 into which the second inactive contact portion 135 is embedded.

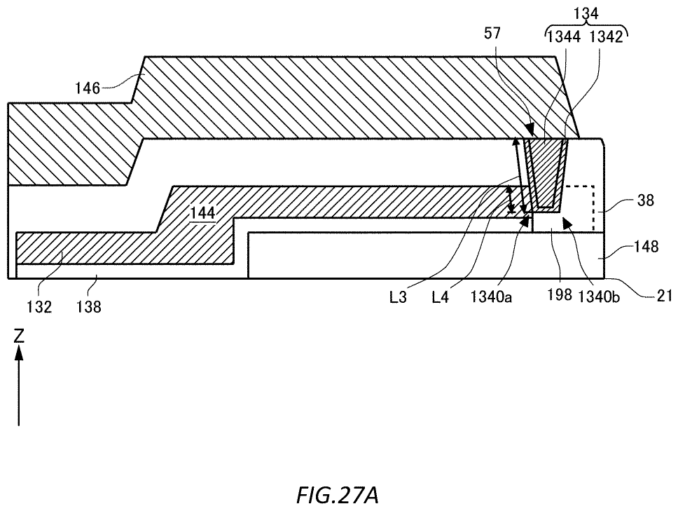

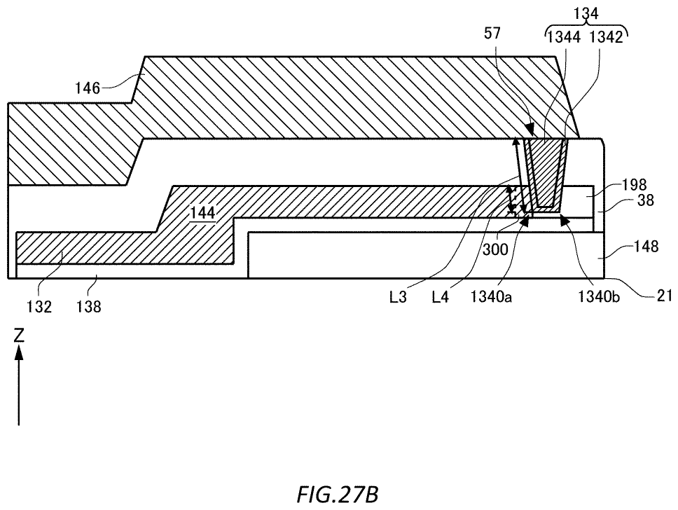

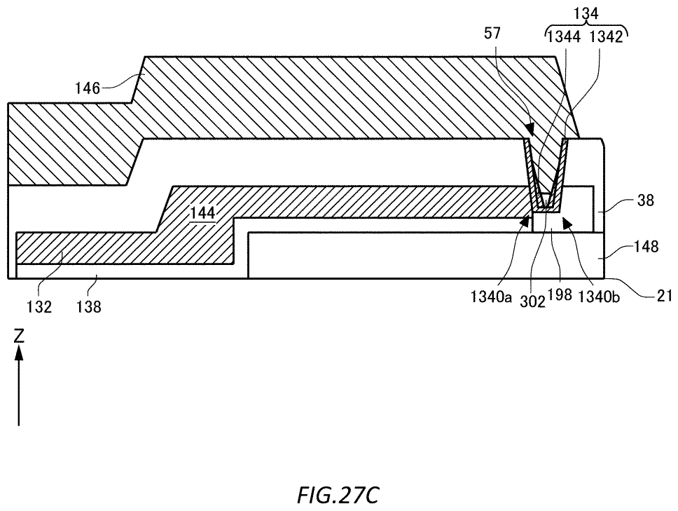

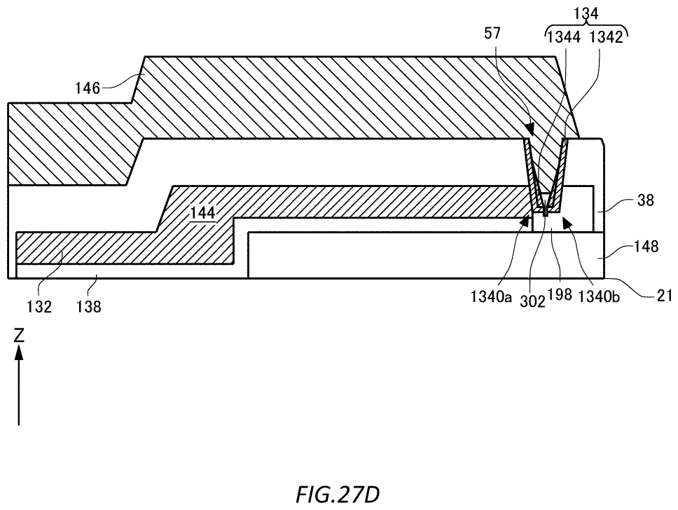

FIG. 27A illustrates an example of the enlarged view of the cross section f-f′ in FIG. 19B. The present drawing illustrates the region above the front surface 21 of the semiconductor substrate 10 in the inactive portion 130. The semiconductor device 100 in the present example is different from that in the example of FIG. 23A in that the first inactive contact portion 134 is provided above the polycrystalline portion 132 positioned above the field dielectric film 148. Other configurations may be the same as those in the example of FIG. 23A.

FIG. 27B illustrates an example of the enlarged view of the cross section f-f′ in FIG. 19B. The present drawing illustrates the region above the front surface 21 of the semiconductor substrate 10 in the inactive portion 130. The semiconductor device 100 in the present example is different from that in the example of FIG. 27A in that the housing portion 198 is provided separately from the interlayer dielectric film 38, and the housing portion 198 includes polysilicon having an impurity concentration lower than that of the contact region 300 of the polycrystalline portion 132. Other configurations may be the same as those in the example of FIG. 27A.

FIG. 27C illustrates an example of the enlarged view of the cross section f-f′ in FIG. 19B when the void 302 is generated in the first inactive contact portion 134. The present example illustrates a case where, in the etch-back step of the plug portion 1344, the plug portion 1344 near the center of the bottom surface of the first inactive contact portion 134 is removed due to over-etching. In this case, it is difficult to fill the first inactive contact portion 134 with the metal material of the edge metal layer 146, and the void 302 may be generated near the center of the bottom surface of the first inactive contact portion 134.

The first inactive contact portion 134 in the present example is provided such that the bottom surface corner portion 1340 is in contact with the polycrystalline portion 132 and the bottom surface is in contact with the housing portion 198. Therefore, even when the void 302 is generated inside the first inactive contact portion 134, near the center of its bottom surface, the influence on the electrical connection at the bottom surface corner portion 1340 between the first inactive contact portion 134 and the polycrystalline portion 132 is suppressed. Accordingly, it is possible to improve the yield of the semiconductor device 100 having desired characteristics. In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, even when the void 302 is formed in the region near the center of the first inactive contact portion 134 in contact with the housing portion 198, it is possible to obtain stable quality and improve the yield.

FIG. 27D illustrates another example of the enlarged view of the cross section f-f′ in FIG. 19B when the void 302 is generated in the first inactive contact portion 134. The present example illustrates a case where, in the etch-back step of the plug portion 1344, the plug portion 1344 and the barrier metal film 1342 near the center of the bottom surface of the first inactive contact portion 134 are removed due to over-etching, and further, the housing portion 198 is also over-etched. In this case, it is difficult to fill the first inactive contact portion 134 with the metal material of the edge metal layer 146, and the void 302 may be generated near the center of the bottom surface of the first inactive contact portion 134.

In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, similarly to the example of FIG. 27C, even when the void 302 is formed in the region near the center of the first inactive contact portion 134 in contact with the housing portion 198, it is possible to obtain stable quality and improve the yield.

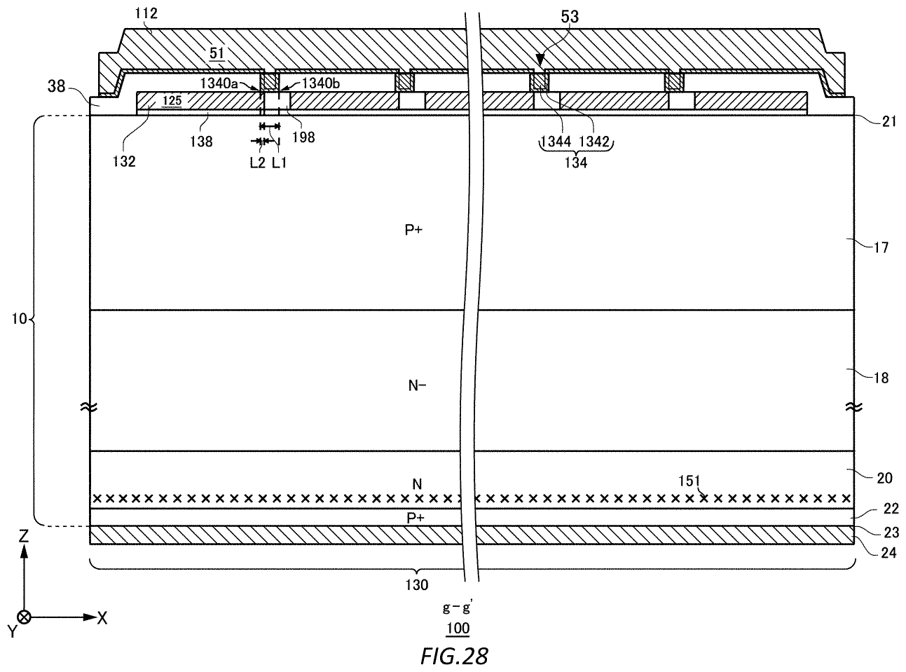

FIG. 28 illustrates an example of a cross section g-g′ in FIG. 19A. The cross section g-g′ is an XZ plane passing through the gate pad 112 in the inactive portion 130. The semiconductor device 100 in the present example includes, in the cross section g-g′, the semiconductor substrate 10, the interlayer dielectric film 38, a pad electrode 51, the collector electrode 24, and the first inactive contact portion 134. The gate pad 112 is an example of the pad electrode 51.

The pad electrode 51 is provided above the semiconductor substrate 10. The pad electrode 51 may be provided above the interlayer dielectric film 38. The gate pad 112 in the present example is provided above the interlayer dielectric film 38. A material of the pad electrode 51 may be the same metal as the material of the emitter electrode 52.

The inactive portion 130 includes the polycrystalline portion 132 provided above the semiconductor substrate 10. The polycrystalline portion 132 in the present example is a pad connection portion 125.

The inactive portion 130 may include the third interlayer dielectric film 138 on the upper surface of the semiconductor substrate 10. The third interlayer dielectric film 138 may be, for example, the same material as that of the gate dielectric film 42 and/or the dummy dielectric film 32. As an example, the third interlayer dielectric film 138 may be a thermal oxide film. The polycrystalline portion 132 may be provided above the third interlayer dielectric film 138. In another example, the third interlayer dielectric film 138 may be a material different from that of the gate dielectric film 42 and/or the dummy dielectric film 32. The pad connection portion 125 in the present example is provided above the third interlayer dielectric film 138.

The first inactive contact portion 134 is electrically connected to the polycrystalline portion 132. The first inactive contact portion 134 in the present example is electrically connected to the pad connection portion 125. The first inactive contact portion 134 may electrically connect the pad electrode 51 and the pad connection portion 125.

The first inactive contact portion 134 is provided to extend from the upper surface to the lower surface of the interlayer dielectric film 38. The contact hole 53 may be provided to penetrate the interlayer dielectric film 38. The first inactive contact portion 134 may include the contact hole 53 and a metal layer with which an inside of the contact hole 53 is filled. The housing portion 198 is provided below the first inactive contact portion 134.

The polycrystalline portion 132 may be connected to the pad electrode 51 via the first inactive contact portion 134. The pad connection portion 125 in the present example is connected to the pad electrode 51 via the first inactive contact portion 134.

The bottom surface corner portion 1340 of the first inactive contact portion 134 may be in contact with the polycrystalline portion 132. The bottom surface corner portion 1340 of the first inactive contact portion 134 may be the intersection of the bottom surface of the first inactive contact portion 134 and the side surface of the first inactive contact portion 134. The bottom surface corner portion 1340 being in contact with the polycrystalline portion 132 may mean being in contact with the polycrystalline portion 132 on the upper surface of the polycrystalline portion 132, may mean being in contact with the polycrystalline portion 132 on the side surface of the polycrystalline portion 132, or may mean being in contact with the polycrystalline portion 132 in a region inside the polycrystalline portion 132. The bottom surface corner portion 1340 in the present example is in contact with the polycrystalline portion 132 on the upper surface of the polycrystalline portion 132.

The first inactive contact portion 134 in the present example includes two bottom surface corner portions 1340. One of the two bottom surface corner portions 1340 may be in contact with the polycrystalline portion 132. Another of the two bottom surface corner portions 1340 may be in contact with the housing portion 198 or may not be in contact with the housing portion 198. In the first inactive contact portion 134 in the present example, one bottom surface corner portion 1340a is in contact with the polycrystalline portion 132, and another bottom surface corner portion 1340b is in contact with the housing portion 198.

The bottom surface of the first inactive contact portion 134 may be in contact with the housing portion 198. The bottom surface of the first inactive contact portion 134 may be a surface between the two bottom surface corner portions 1340 of the first inactive contact portion 134. The bottom surface of the first inactive contact portion 134 being in contact with the housing portion 198 may mean that the bottom surface is in contact with the housing portion 198 on the upper surface of the housing portion 198, and may mean that the bottom surface is in contact with the housing portion 198 in a region inside the housing portion 198. In the first inactive contact portion 134 in the present example, the bottom surface is in contact with the housing portion 198 on the upper surface of the housing portion 198.

The first inactive contact portion 134 in the present example is provided such that the bottom surface corner portion 1340 is in contact with the polycrystalline portion 132 and the bottom surface is in contact with the housing portion 198. Accordingly, it is possible to reliably secure electrical connection between the pad electrode 51 and the polycrystalline portion 132. In the etch-back step of the plug portion 1344, when the plug portion 1344 and the barrier metal film 1342 near the center of the bottom surface of the first inactive contact portion 134 are removed due to over-etching, a void may be generated inside the first inactive contact portion 134. Even in this case, the electrical connection can be secured by the barrier metal film 1342 and/or the plug portion 1344 remaining at the bottom surface corner portion 1340 of the first inactive contact portion 134.

The bottom surface of the first inactive contact portion 134 in the present example is provided in contact with the housing portion 198. Therefore, even when a void is generated inside the first inactive contact portion 134, near the center of its bottom surface, the influence on the electrical connection at the bottom surface corner portion 1340 between the first inactive contact portion 134 and the polycrystalline portion 132 is suppressed. Accordingly, it is possible to improve the yield of the semiconductor device 100 having desired characteristics. In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, even when a void is formed in a region near the center of the first inactive contact portion 134 in contact with the housing portion 198, it is possible to obtain stable quality and improve the yield.

The bottom surface of the first inactive contact portion 134 may be in contact with the polycrystalline portion 132 and the housing portion 198. In the first inactive contact portion 134 in the present example, one bottom surface corner portion 1340a is in contact with the polycrystalline portion 132, and another bottom surface corner portion 1340b is in contact with the housing portion 198, so that the bottom surface of the first inactive contact portion 134 is in contact with the polycrystalline portion 132 and the housing portion 198.

The polycrystalline portion 132 may be in contact with the bottom surface of the first inactive contact portion 134, from the bottom surface corner portion 1340 to a region of 10% or more and 40% or less of the bottom surface of the first inactive contact portion 134. That is, a ratio of an area of a surface, which is in contact with the polycrystalline portion 132, in the bottom surface of the first inactive contact portion 134 to an area of the bottom surface of the first inactive contact portion 134 may be 10% or more and 40% or less. With reference to FIG. 28, the length L1 is a length of the bottom surface of the first inactive contact portion 134 in the cross section perpendicular to the front surface 21 of the semiconductor substrate 10. The length L2 is a length of the bottom surface, which is in contact with the polycrystalline portion 132, in the bottom surface of the first inactive contact portion 134 in the cross section perpendicular to the front surface 21 of the semiconductor substrate 10. Therefore, the ratio of the length L2 to the length L1 may be 10% or more and 40% or less. The polycrystalline portion 132 in the present example is in contact with the bottom surface of the first inactive contact portion 134, from the bottom surface corner portion 1340a to a region of 20% of the bottom surface of the first inactive contact portion 134. That is, the ratio of the length L2 to the length L1 in the present example is 20%.

The side surface of the polycrystalline portion 132 may be in contact with the side surface of the housing portion 198. The housing portion 198 may be a region, which is provided below the first inactive contact portion 134, in the interlayer dielectric film 38. The housing portion 198 may be formed in a step of providing the interlayer dielectric film 38, and may be formed of the same material as that of the interlayer dielectric film 38. When the housing portion 198 is formed as the region, which is provided below the first inactive contact portion 134, in the interlayer dielectric film 38, the housing portion 198 may be a virtual region. That is, the housing portion 198 may be integrally formed as a part of the interlayer dielectric film 38. In another example, the housing portion 198 may be polysilicon having an impurity concentration lower than that of the polycrystalline portion 132 or non-doped polysilicon. In another example, the housing portion 198 may be the third interlayer dielectric film 138 provided above the semiconductor substrate 10. In this case, the housing portion 198 may be formed in a step of providing the third interlayer dielectric film 138, and may be formed of the same material as that of the third interlayer dielectric film 138. That is, the housing portion 198 may be integrally formed as a part of the third interlayer dielectric film 138.

The first inactive contact portion 134 may include the barrier metal film 1342 provided in the contact hole 53 and the plug portion 1344. The barrier metal film 1342 of the first inactive contact portion 134 may contain titanium, a titanium compound, or the like. The plug portion 1344 of the first inactive contact portion 134 may contain a plug metal such as tungsten. The barrier metal film 1342 in the present example is provided above the interlayer dielectric film 38 and is in contact with the pad electrode 51. Also in the active portion 120 or other inactive portions 130 such as the edge termination structure portion 140 or the temperature sensitive portion 180, the barrier metal film 1242, the barrier metal film 1342, and/or the barrier metal film 1882 may be provided above the interlayer dielectric film 38. The plug portion 1344 in the present example is provided inside the contact hole 53. When the plug portion 1344 is provided in a part of the first inactive contact portion 134, a remaining region of the first inactive contact portion 134 may be filled with the same material as that of the pad electrode 51. In another example, the plug portion 1344 may be provided outside the contact hole 53 and above the barrier metal film 1342 and be in contact with the pad electrode 51, and also in the active portion 120 or other inactive portions 130, the plug portion 1244, the plug portion 1344, and/or the plug portion 1884 may be provided outside the contact hole 54, the contact hole 55, the contact hole 56, the contact hole 57, the contact hole 58, and/or the contact hole 59 and above the barrier metal film 1242, the barrier metal film 1342, and/or the barrier metal film 1882. In still another example, the barrier metal film 1342 may not be provided above the interlayer dielectric film 38 but may be provided only inside the contact hole 53.

The polycrystalline portion 132 may be connected to the pad electrode 51 through the contact hole 53 provided in the interlayer dielectric film 38. The pad connection portion 125 in the present example is connected to the pad electrode 51 through the contact hole 53 provided in the interlayer dielectric film 38.

The polycrystalline portion 132 in the present example may be formed below the gate pad 112. Although the pad connection portions 125 are discretely provided in the cross section in FIG. 28, the pad connection portions 125 may be connected to each other in a different cross section as described below.

The pad connection portion 125 may be formed of the same polycrystalline as that of the gate conductive portion 44 and the dummy conductive portion 34. In another example, the pad connection portion 125 may be a polycrystalline film obtained by performing ion implantation or the like as necessary to impart conductivity to a polycrystalline film formed simultaneously with a polycrystalline material constituting the temperature sensitive diode 183, and the dielectric film below the polycrystalline portion 132 may have the same configuration as that of the second interlayer dielectric film 37 of the temperature sensitive portion 180 instead of the dielectric film of the same material as that of the gate dielectric film 42 or the like. The pad connection portion 125 may not be electrically connected to a portion other than the pad electrode 51. In this case, the pad electrode 51 may be directly connected to the gate metal layer 50. In addition, the pad connection portion 125 may not have conductivity. In another example, the pad connection portion 125 may be electrically connected to the portion other than the pad electrode 51. For example, the pad connection portion 125 may be connected to the connection portion 25. In addition, the pad electrode 51 may not be directly connected to the gate metal layer 50 but may be connected via the pad connection portion 125. In this case, the pad connection portion 125 has conductivity, and may be connected to the gate metal layer 50 outside the gate pad 112 in top view, and may be connected to the gate metal layer 50 by a method similar to that of the connection with the pad electrode 51.

The barrier metal film 1342 may be provided up to an end portion of the pad electrode 51. The pad electrode 51 may be provided wider than an end portion of the pad connection portion 125. In another example, the pad electrode 51 may not be provided up to the end portion of the pad connection portion 125.

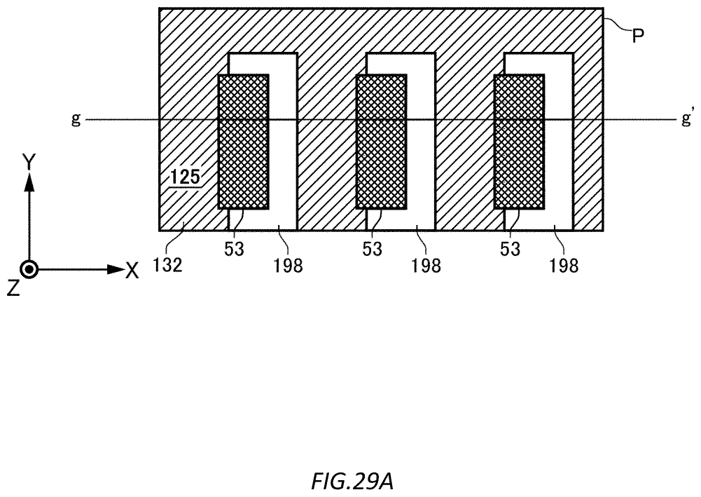

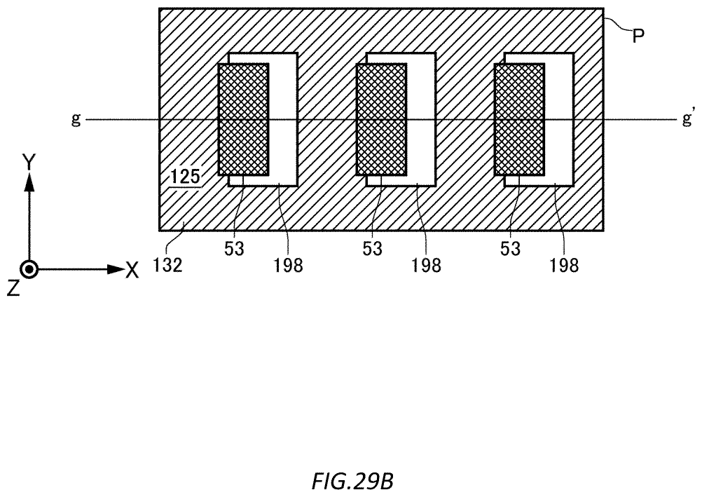

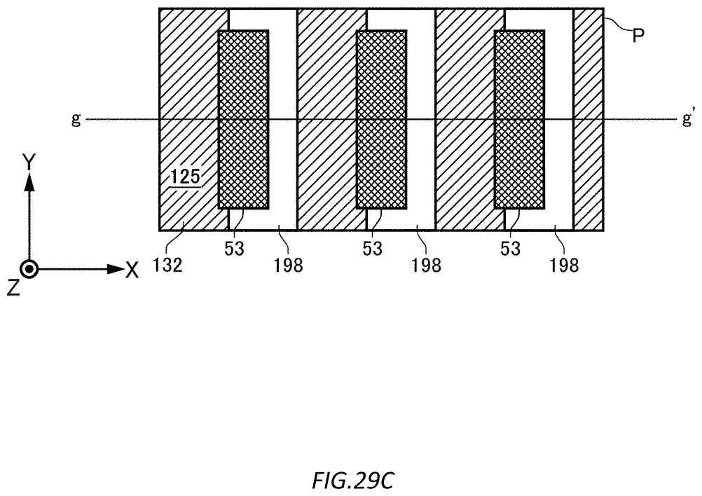

FIG. 29A illustrates an example of a region P including a part indicating a position of the cross section g-g′ in FIG. 19A and its periphery. In the present drawing, the polycrystalline portions 132 and the housing portions 198 are repeatedly arranged in the X axis direction on the cross section g-g′ and its periphery. The polycrystalline portions 132 are connected to each other at a position away from the cross section g-g′ in the Y axis direction. As described above, the polycrystalline portions 132 may be arranged in a comb shape. By providing a plurality of contact holes 53 across the housing portions 198 and the polycrystalline portions 132, the polycrystalline portions 132 repeatedly arrayed in the X axis direction and the pad electrode 51 can be connected. In addition, arrangement obtained by translating or inverting the arrangement illustrated in the present example in the X axis or the Y axis may be repeatedly arrayed.

FIG. 29B illustrates another example of the region P including the part indicating the position of the cross section g-g′ in FIG. 19A and its periphery. In the present drawing, the polycrystalline portions 132 and the housing portions 198 are repeatedly arranged in the X axis direction on the cross section g-g′ and its periphery. The polycrystalline portions 132 are connected to each other at a position away from the cross section g-g′ in the Y axis direction. As described above, the polycrystalline portion 132 may be arranged so as to discretely include a plurality of housing portions 198 therein. By providing a plurality of contact holes 53 across the housing portions 198 and the polycrystalline portions 132, the polycrystalline portions 132 repeatedly arrayed in the X axis direction and the pad electrode 51 can be connected. In addition, arrangement obtained by translating or inverting the arrangement illustrated in the present example in the X axis or the Y axis may be repeatedly arrayed. The arrangements of the polycrystalline portions 132 illustrated in FIGS. 29A and 29B may be applied not only to the arrangement of the pad connection portions 125 and the contact holes 53 but also to arrangement of the connection portions 25, the contact holes 55, and the contact holes 56 in other inactive portions 130, arrangement of the field plates 144 and the contact holes 57, and arrangement of the temperature sensitive anode regions 182, the temperature sensitive cathode regions 181, and the contact holes 58 in the temperature sensitive portion 180.

FIG. 29C illustrates another example of the region P including the part indicating the position of the cross section g-g′ in FIG. 19A and its periphery. In the present drawing, the polycrystalline portions 132 and the housing portions 198 are repeatedly arranged in the X axis direction on the cross section g-g′ and its periphery. The polycrystalline portions 132 are not connected to each other. As described above, the polycrystalline portions 132 may be discretely arranged. By providing a plurality of contact holes 53 across the housing portions 198 and the polycrystalline portions 132, the polycrystalline portions 132 repeatedly arrayed in the X axis direction and the pad electrode 51 can be connected. When the pad connection portion 125 is not connected to another member of the semiconductor device 100, the polycrystalline portions 132 may not be connected to each other. The polycrystalline portions 132 may also be discretely arranged in the Y axis direction.

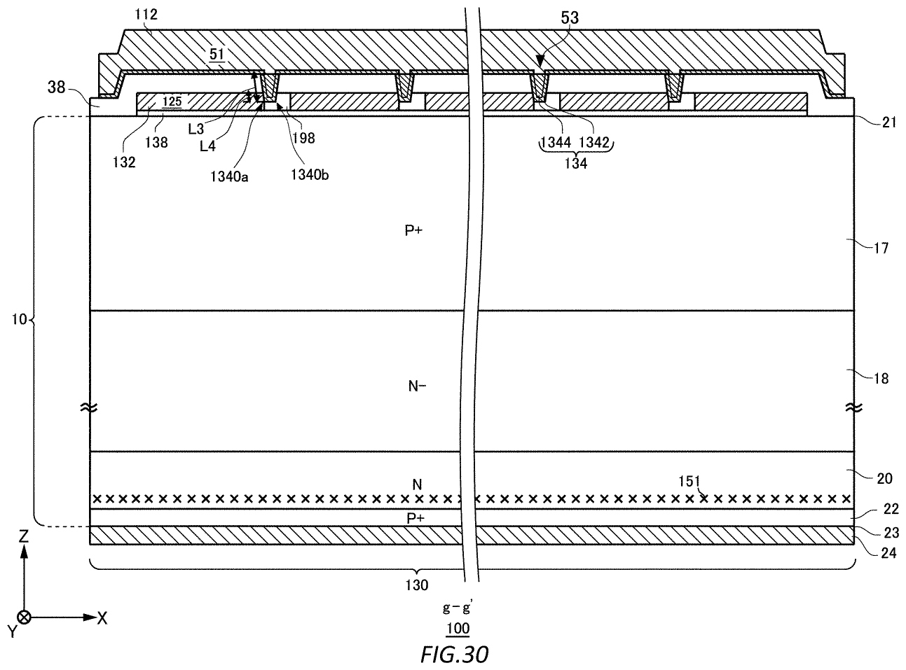

FIG. 30 illustrates another example of the cross section g-g′ in FIG. 19A. The semiconductor device 100 in the present example is different from that in the example of FIG. 28 in that the first inactive contact portion 134 has a trench contact structure. Other configurations may be the same as those in the example of FIG. 28. When the first inactive contact portion 134 has a trench contact structure, the first inactive contact portion 134 may extend from the upper surface of the polycrystalline portion 132 in the depth direction of the semiconductor substrate 10. The active contact portion 124 may have the planar contact structure of FIG. 1B or the trench contact structure of FIG. 10B.

The semiconductor device 100 in the present example is different from that in the example of FIG. 28 in that the first inactive contact portion 134 is different in structure. In the present example, the difference from the example of FIG. 28 will be particularly described, and other configurations may be the same as those in the example of FIG. 28.

The side walls of the first inactive contact portion 134 may have a trench contact structure in contact with the side surface of the polycrystalline portion 132. The bottom surface corner portion 1340 of the first inactive contact portion 134 in the present example is in contact with the polycrystalline portion 132 on the side surface of the polycrystalline portion 132.

The side wall of the first inactive contact portion 134 may be in contact with the polycrystalline portion 132 and the interlayer dielectric film 38. The polycrystalline portion 132 may be in contact with the side wall of the first inactive contact portion 134, from the bottom surface corner portion 1340 to a region of 10% or more and 90% or less of the side wall of the first inactive contact portion 134. That is, a ratio of an area of the side wall, which is in contact with the polycrystalline portion 132, in the side wall of the first inactive contact portion 134 to an area of the side wall, on a side in contact with the polycrystalline portion 132, among the side walls of the first inactive contact portion 134 may be 10% or more and 90% or less. With reference to FIG. 30, the length L3 is a length of the side wall of the first inactive contact portion 134 in the cross section perpendicular to the front surface 21 of the semiconductor substrate 10, and the length L4 is a length of the side wall, which is in contact with the polycrystalline portion 132, in the side wall of the first inactive contact portion 134 in the cross section perpendicular to the front surface 21 of the semiconductor substrate 10. Therefore, the ratio of the length L4 to the length L3 may be 10% or more and 90% or less. The polycrystalline portion 132 in the present example is in contact with the side wall of the first inactive contact portion 134, from the bottom surface corner portion 1340 to a region of 35% of the side wall of the first inactive contact portion 134. That is, the ratio of the length L4 to the length L3 in the present example is 35%.

In the etch-back step of the plug portion 1344, when the plug portion 1344 near the center of the bottom surface of the first inactive contact portion 134 is removed due to over-etching, it is difficult to fill the first inactive contact portion 134 with the metal material of the pad electrode 51, and a void may be generated near the center of the bottom surface of the first inactive contact portion 134. The first inactive contact portion 134 in the present example is provided such that the bottom surface corner portion 1340 is in contact with the polycrystalline portion 132 and the bottom surface is in contact with the housing portion 198. Therefore, even when a void is generated inside the first inactive contact portion 134, near the center of its bottom surface, the influence on the electrical connection at the bottom surface corner portion 1340 between the first inactive contact portion 134 and the polycrystalline portion 132 is suppressed. Accordingly, it is possible to improve the yield of the semiconductor device 100 having desired characteristics. In the electrical connection between the first inactive contact portion 134 and the polycrystalline portion 132, the inactive portion 130 in the present example secures the electrical connection through the bottom surface corner portion 1340, rather than the central portion of the bottom surface of the first inactive contact portion 134. As a result, even when a void is formed in a region near the center of the first inactive contact portion 134 in contact with the housing portion 198, it is possible to obtain stable quality and improve the yield.

Although description has been given using the gate pad 112 in FIGS. 28 to 30, the configuration described with respect to the gate pad 112 may also be applied to another pad. For example, the configuration may be used for the anode pad 116, the cathode pad 118, and/or the sensing electrode 114 illustrated in FIG. 19A, and/or any pad (not shown). The pad electrode 51 may be in direct contact with the anode wiring portion 117, the cathode wiring portion 119, or the like, or may be indirectly connected via the polycrystalline portion 132. Note that although the example of the XZ cross section has been described with reference to FIG. 28, a longitudinal direction of the contact hole 53 may not be the Y axis direction. For example, the longitudinal direction of the contact hole 53 may be the X axis direction or any direction, and the contact holes 53 having different directions may be used in combination.

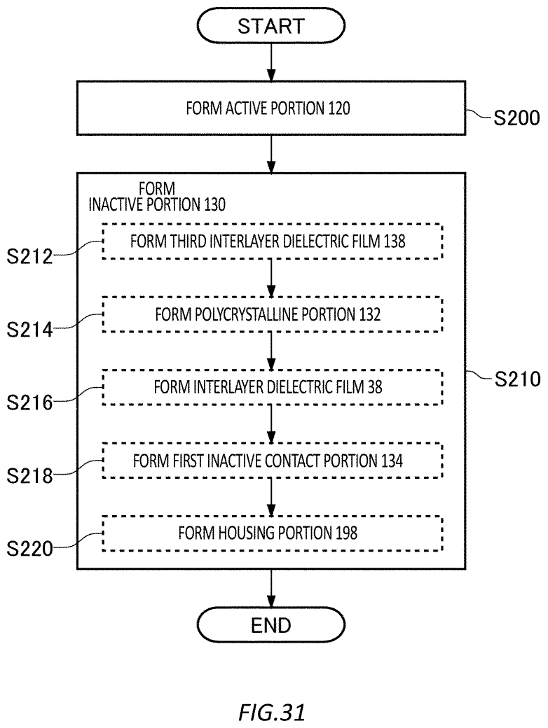

FIG. 31 is a flowchart illustrating an example of a manufacturing step of the semiconductor device 100. The manufacturing step in the present example includes step S200 of forming the active portion 120 and step S210 of forming the inactive portion 130. An order of step S200 of forming the active portion 120 and step S210 of forming the inactive portion 130 is not limited thereto. The active portion 120 may be formed after the inactive portion 130 is formed, and a part or all of the step of forming the active portion 120 and a part of the step of forming the inactive portion 130 may be the same step.

Step S210 of forming the inactive portion 130 includes step S212 of forming the third interlayer dielectric film 138, step S214 of forming the polycrystalline portion 132, step S216 of forming the interlayer dielectric film 38, step S218 of forming the first inactive contact portion 134, and step S220 of forming the housing portion 198.

In step S212, the third interlayer dielectric film 138 is formed above the semiconductor substrate 10. The third interlayer dielectric film 138 may be a dielectric film which insulates the semiconductor substrate 10 from the connection portion 25, a dielectric film which insulates the semiconductor substrate 10 from the field plate 144, or a dielectric film which insulates the semiconductor substrate 10 from the pad connection portion 125. The third interlayer dielectric film 138 may be formed by a method that is conventional to persons skilled in the art. As an example, step S212 may be a step of forming the gate dielectric film 42 in the active portion 120, and the third interlayer dielectric film 138 may be a thermal oxide film formed by heating the semiconductor substrate 10. As another example, step S212 may be step S112 of forming the second interlayer dielectric film 37 in the temperature sensitive portion 180.

In step S214, the polycrystalline portion 132 is formed above the semiconductor substrate 10. The polycrystalline portion 132 may be formed above the third interlayer dielectric film 138. The polycrystalline portion 132 may be the connection portion 25 which electrically connects the emitter electrode 52 and the dummy conductive portion 34, may be the connection portion 25 which electrically connects the gate metal layer 50 and the gate conductive portion 44, may be the field plate 144, or may be the pad connection portion 125 which is provided below the pad electrode 51. The polycrystalline portion 132 may be formed by a method that is conventional to persons skilled in the art. As an example, step S214 may be a step of forming the gate conductive portion 44 in the active portion 120, and the polycrystalline portion 132 may be formed by depositing polysilicon doped with impurities above the semiconductor substrate 10. As another example, step S212 may be step S114 of depositing non-doped polysilicon above the semiconductor substrate 10 in the temperature sensitive portion 180, then implanting impurity ions, and performing annealing processing.

In step S216, the interlayer dielectric film 38 is formed above the polycrystalline portion 132. The interlayer dielectric film 38 may be formed by stacking a plurality of dielectric films. Step S216 of forming the interlayer dielectric film 38 may be a step of forming the interlayer dielectric film 38 in the active portion 120.

In step S218, the first inactive contact portion 134 extending from the upper surface to the lower surface of the interlayer dielectric film 38 is formed. Step S218 of forming the first inactive contact portion 134 may be a step of forming, in the active portion 120, the active contact portion 124 extending from the upper surface to the lower surface of the interlayer dielectric film 38. However, the first inactive contact portion 134 and the active contact portion 124 may be formed in different steps.

Step S218 of forming the first inactive contact portion 134 may include a step of by etching the interlayer dielectric film 38 to form the contact hole 53, the contact hole 55, the contact hole 56, and/or the contact hole 57. In this step, the contact hole 59 may also be formed. In addition, the contact hole 54 may also be formed in the interlayer dielectric film 38 of the active portion 120. In addition, the contact hole 58 may also be formed in the interlayer dielectric film 38 of the temperature sensitive portion 180. However, these contact holes may be formed in different steps.

Step S218 of forming the first inactive contact portion 134 may include a step of forming the barrier metal film 1342. The barrier metal film 1342 may be formed by forming a metal film inside the contact hole 53, the contact hole 55, the contact hole 56, and/or the contact hole 57 and then performing annealing in the nitrogen atmosphere. As an example, the barrier metal film 1342 may be formed by forming a Ti film inside the contact hole 53, the contact hole 55, the contact hole 56, and/or the contact hole 57 and then performing annealing in the nitrogen atmosphere. In this case, a TiN film may be formed by annealing the Ti film. In this step, a barrier metal film may be formed on the active contact portion 124 and/or the second inactive contact portion 135.

Step S218 of forming the first inactive contact portion 134 may include a step of forming the plug portion 1344. As an example, the plug portion 1344 may be formed by forming tungsten so as to be embedded into the contact hole 53, the contact hole 55, the contact hole 56, and/or the contact hole 57 by a chemical vapor deposition (CVD) method. In this step, a plug portion may be formed in the active contact portion 124 and/or the second inactive contact portion 135.

Step S218 of forming the first inactive contact portion 134 may include a step of performing etch-back on the plug portion 1344. Accordingly, an unnecessary tungsten film outside the contact hole 53, the contact hole 55, the contact hole 56, and/or the contact hole 57 may be removed. However, the plug portion 1344 may be provided in a part of the first inactive contact portion 134, and may be provided to protrude from the contact hole 53, the contact hole 55, the contact hole 56, and/or the contact hole 57 and reach above the interlayer dielectric film 38. The etch-back may be performed by dry etching or chemical mechanical polishing (CMP). When the tungsten film outside the contact hole is removed, the barrier metal film 1342 outside the contact hole may also be removed. The barrier metal film 1342 may be removed in a step different from the etch-back of the plug portion 1344. The barrier metal film 1342 may not be removed. In this step, the plug portion of the active contact portion 124 and/or the second inactive contact portion 135 may be etched back.

When the barrier metal film 1342 and/or the plug portion 1344 are not provided in the first inactive contact portion 134, the above-described step may be omitted. In this case, at the same time as the step of providing the pad electrode 51, the emitter electrode 52, the gate metal layer 50, and/or the edge metal layer 146, the inside of the contact hole 53, the contact hole 55, the contact hole 56, and/or the contact hole 57 may be filled to form the first inactive contact portion 134.

In step S218 of forming the first inactive contact portion 134, the first inactive contact portion 134 may be formed such that the bottom surface corner portion 1340 of the first inactive contact portion 134 is in contact with the polycrystalline portion 132. In step S218 of forming the first inactive contact portion 134, the first inactive contact portion 134 may be formed such that the bottom surface of the first inactive contact portion 134 is in contact with the housing portion 198.

The bottom surface corner portion 1340 of the first inactive contact portion 134 in the present example is provided in contact with the polycrystalline portion 132, and the bottom surface thereof is provided in contact with the housing portion 198, so that it is possible to reliably secure electrical connection between the pad electrode 51, the emitter electrode 52, the gate metal layer 50 and/or the edge metal layer 146 and the polycrystalline portion 132. Since the bottom surface of the first inactive contact portion 134 in the present example is provided in contact with the housing portion 198, even when the plug portion 1344 and the barrier metal film 1342 near the center of the bottom surface of the first inactive contact portion 134 are removed due to over-etching in the etch-back step of the plug portion 1344 and a void is generated inside the first inactive contact portion 134, it is possible to suppress the influence on the electrical connection at the bottom surface corner portion 1340 between the first inactive contact portion 134 and the polycrystalline portion 132 and to improve the yield of the semiconductor device 100 having desired characteristics. That is, in the electrical connection between the first inactive contact portion 134 and the polycrystalline portion 132, the electrical connection through the bottom surface corner portion 1340 is secured rather than the electrical connection through the central portion of the bottom surface of the first inactive contact portion 134, so that even when a void is formed in the region near the center of the first inactive contact portion 134 in contact with the housing portion 198, it is possible to obtain stable quality and improve the yield.

In step S220, the housing portion 198 is formed below the first inactive contact portion 134. An order of step S220 of forming the housing portion 198 is not limited thereto. Step S220 of forming the housing portion 198 may be included in step S214 of forming the polycrystalline portion 132, or may be included in step S216 of forming the interlayer dielectric film 38.

As an example, in the examples illustrated in FIG. 12A, 14A, 16A, 18A, 21A, 23A, 25A, 27A, or 28 to 30, the housing portion 198 is the region, which is provided below the first inactive contact portion 134, in the interlayer dielectric film 38. In this case, step S220 of forming the housing portion 198 may be included in step S216 of forming the interlayer dielectric film 38.

As another example, in the examples illustrated in FIG. 21C, 23C, 25B, 27B, or 28 to 30, the housing portion 198 has polysilicon. In this case, step S220 of forming the housing portion 198 may be included in step S214 of forming the polycrystalline portion 132. The polycrystalline portion 132 and the housing portion 198 may be formed by stacking non-doped polysilicon in regions to be the housing portion 198 and the polycrystalline portion 132, implanting impurity ions into each region, and performing annealing processing.

While the present invention has been described by way of the embodiments, the technical scope of the present invention is not limited to the above-described embodiments. It is apparent to persons skilled in the art that various alterations or improvements can be made to the above described embodiments. It is also apparent from description of the claims that the embodiments to which such changes or improvements are made may be included in the technical scope of the present invention.

It should be noted that each process of the operations, procedures, steps, stages, and the like performed by the device, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### (Item 1)

A semiconductor device including:
an active portion which is provided in a semiconductor substrate; and
a temperature sensitive portion which is provided above the semiconductor substrate, wherein
the temperature sensitive portion includes
a temperature sensitive diode which is provided above the semiconductor substrate,
a first interlayer dielectric film which is provided above the temperature sensitive diode,
a temperature sensitive contact portion which is provided to extend from an upper surface to a lower surface of the first interlayer dielectric film, and
a housing portion which is provided below the temperature sensitive contact portion,
a bottom surface corner portion of the temperature sensitive contact portion is in contact with the temperature sensitive diode, and
a bottom surface of the temperature sensitive contact portion is in contact with the housing portion.

### (Item 2)

The semiconductor device according to item 1, wherein
a side surface of the temperature sensitive diode is in contact with a side surface of the housing portion.

### (Item 3)

The semiconductor device according to item 1, including
a second interlayer dielectric film which is provided between the temperature sensitive diode and the semiconductor substrate in a depth direction of the semiconductor substrate.

### (Item 4)

The semiconductor device according to item 3, wherein
an upper surface of the second interlayer dielectric film is in contact with a lower surface of the temperature sensitive diode and a lower surface of the housing portion.

### (Item 5)

The semiconductor device according to item 1, wherein
the housing portion is a region, which is provided below the temperature sensitive contact portion, in the first interlayer dielectric film.

### (Item 6)

The semiconductor device according to item 3, wherein
the housing portion is the second interlayer dielectric film which is provided above the semiconductor substrate.

### (Item 7)

The semiconductor device according to item 3, wherein
the second interlayer dielectric film includes a recess on its upper surface side, and
the temperature sensitive diode is provided in the recess of the second interlayer dielectric film.

### (Item 8)

The semiconductor device according to item 1, wherein
the temperature sensitive diode includes a contact region in contact with the housing portion, and
the housing portion includes a polycrystalline semiconductor of a conductivity type different from that of the contact region of the temperature sensitive diode.

### (Item 9)

The semiconductor device according to item 1, wherein
the temperature sensitive diode includes a contact region in contact with the housing portion, and
the housing portion includes a polycrystalline semiconductor which has a same conductivity type as that of the contact region of the temperature sensitive diode and has a doping concentration lower than that of the contact region.

### (Item 10)

The semiconductor device according to item 1, wherein
the temperature sensitive diode includes
a temperature sensitive anode region which is provided above the semiconductor substrate, and
a temperature sensitive cathode region which is provided above the semiconductor substrate and is provided in contact with the temperature sensitive anode region.

### (Item 11)

The semiconductor device according to item 1, wherein
the temperature sensitive contact portion includes
a barrier metal film which is provided on the bottom surface corner portion of the temperature sensitive contact portion, and
a plug portion which is provided in contact with an inside of the barrier metal film.

### (Item 12)

The semiconductor device according to item 1, wherein
the active portion includes a plurality of active contact portions which are provided at a front surface of the semiconductor substrate.

### (Item 13)

The semiconductor device according to any one of items 1 to 12, wherein
a bottom surface of the temperature sensitive contact portion is in contact with the temperature sensitive diode and the housing portion.

### (Item 14)

The semiconductor device according to item 13, wherein
the temperature sensitive diode is in contact with the bottom surface of the temperature sensitive contact portion, from the bottom surface corner portion to a region of 10% or more and 40% or less of the bottom surface of the temperature sensitive contact portion.

### (Item 15)

The semiconductor device according to any one of items 1 to 12, wherein
side walls of the temperature sensitive contact portion have a trench contact structure in contact with a side surface of the temperature sensitive diode.

### (Item 16)

The semiconductor device according to item 15, wherein
a side wall of the temperature sensitive contact portion is in contact with the temperature sensitive diode and the first interlayer dielectric film, and
the temperature sensitive diode is in contact with the side wall of the temperature sensitive contact portion, from the bottom surface corner portion to a region of 10% or more and 90% or less of the side wall of the temperature sensitive contact portion.

### (Item 17)

A method for manufacturing a semiconductor device, including:
forming an active portion in a semiconductor substrate; and
forming a temperature sensitive portion above the semiconductor substrate, wherein
the forming the temperature sensitive portion includes
forming a temperature sensitive diode above the semiconductor substrate,
forming a first interlayer dielectric film above the temperature sensitive diode,
forming a temperature sensitive contact portion extending from an upper surface to a lower surface of the first interlayer dielectric film, and
forming a housing portion below the temperature sensitive contact portion,
a bottom surface corner portion of the temperature sensitive contact portion is in contact with the temperature sensitive diode, and
a bottom surface of the temperature sensitive contact portion is in contact with the housing portion.

### (Item 18)

A semiconductor device including an active portion and an inactive portion, wherein
the inactive portion includes
a polycrystalline portion which is provided above a semiconductor substrate,
an interlayer dielectric film which is provided above the polycrystalline portion,
a first inactive contact portion which is provided to extend from an upper surface to a lower surface of the interlayer dielectric film, and
a housing portion which is provided below the first inactive contact portion,
a bottom surface corner portion of the first inactive contact portion is in contact with the polycrystalline portion, and
a bottom surface of the first inactive contact portion is in contact with the housing portion.

### (Item 19)

The semiconductor device according to item 18, wherein
a side surface of the polycrystalline portion is in contact with a side surface of the housing portion.

### (Item 20)

The semiconductor device according to item 18, wherein
the housing portion is a region, which is provided below the first inactive contact portion, in the interlayer dielectric film.

### (Item 21)

The semiconductor device according to item 18, wherein
the first inactive contact portion includes
a barrier metal film which is provided on the bottom surface corner portion of the first inactive contact portion, and
a plug portion which is provided in contact with an inside of the barrier metal film.

### (Item 22)

The semiconductor device according to item 18, wherein
the active portion includes a plurality of active contact portions which are provided at a front surface of the semiconductor substrate.

### (Item 23)

The semiconductor device according to item 18, wherein
a bottom surface of the first inactive contact portion is in contact with the polycrystalline portion and the housing portion.

### (Item 24)

The semiconductor device according to item 23, wherein
the polycrystalline portion is in contact with the bottom surface of the first inactive contact portion, from the bottom surface corner portion to a region of 10% or more and 40% or less of the bottom surface of the first inactive contact portion.

### (Item 25)

The semiconductor device according to item 18, wherein
side walls of the first inactive contact portion have a trench contact structure in contact with a side surface of the polycrystalline portion.

### (Item 26)

The semiconductor device according to item 25, wherein
a side wall of the first inactive contact portion is in contact with the polycrystalline portion and the interlayer dielectric film, and
the polycrystalline portion is in contact with the side wall of the first inactive contact portion, from the bottom surface corner portion to a region of 10% or more and 90% or less of the side wall of the first inactive contact portion.

### (Item 27)

The semiconductor device according to any one of items 18 to 26, including:
a gate trench portion which is provided at a front surface of the semiconductor substrate and includes a gate conductive portion; and
a gate metal layer which is provided above the semiconductor substrate and is electrically connected to the gate conductive portion, wherein
the polycrystalline portion
is connected to the gate metal layer via the first inactive contact portion, and
is connected to the gate conductive portion.

### (Item 28)

The semiconductor device according to any one of items 18 to 26, including:
a dummy trench portion which is provided at a front surface of the semiconductor substrate and includes a dummy conductive portion; and
an emitter electrode which is provided above the semiconductor substrate and is electrically connected to the semiconductor substrate, wherein
the polycrystalline portion
is connected to the emitter electrode via the first inactive contact portion, and
is connected to the dummy conductive portion.

### (Item 29)

The semiconductor device according to any one of items 18 to 26, including:
a guard ring of a second conductivity type which is provided between the active portion and an end side of the semiconductor substrate at a front surface of the semiconductor substrate;
and an edge metal layer which is provided above the semiconductor substrate and is electrically connected to the guard ring, wherein
the polycrystalline portion is connected to the edge metal layer via the first inactive contact portion.

### (Item 30)

The semiconductor device according to item 29, including
a field dielectric film which is provided below the interlayer dielectric film, wherein
the first inactive contact portion is provided above the polycrystalline portion positioned above the field dielectric film.

### (Item 31)

The semiconductor device according to any one of items 18, 19, or 21 to 26, including:
a guard ring of a second conductivity type which is provided between the active portion and an end side of the semiconductor substrate at a front surface of the semiconductor substrate;
an edge metal layer which is provided above the semiconductor substrate and is electrically connected to the guard ring; and
a field dielectric film which is provided below the interlayer dielectric film, wherein
the polycrystalline portion is connected to the edge metal layer via the first inactive contact portion, and
the housing portion is a region, which is provided below the first inactive contact portion, in the field dielectric film.

### (Item 32)

The semiconductor device according to any one of items 18, 19, or 21 to 26, including:
a guard ring of a second conductivity type which is provided between the active portion and an end side of the semiconductor substrate at a front surface of the semiconductor substrate; and
an edge metal layer which is provided above the semiconductor substrate and is electrically connected to the guard ring, wherein
the polycrystalline portion is connected to the edge metal layer via the first inactive contact portion,
the polycrystalline portion includes a contact region in contact with the housing portion, and
the housing portion includes a polycrystalline semiconductor which has an impurity concentration lower than that of the contact region of the polycrystalline portion.

### (Item 33)

The semiconductor device according to any one of items 18 to 26, including
a pad electrode which is provided above the semiconductor substrate, wherein
the polycrystalline portion
is connected to the pad electrode via the first inactive contact portion.

### (Item 34)

A method for manufacturing a semiconductor device, including:
forming an active portion; and
forming an inactive portion, wherein
the forming the inactive portion includes
forming a polycrystalline portion above a semiconductor substrate,
forming an interlayer dielectric film above the polycrystalline portion,
forming a first inactive contact portion extending from an upper surface to a lower surface of the interlayer dielectric film, and
forming a housing portion below the first inactive contact portion,
a bottom surface corner portion of the first inactive contact portion is in contact with the polycrystalline portion, and
a bottom surface of the first inactive contact portion is in contact with the housing portion.

### EXPLANATION OF REFERENCES

10: semiconductor substrate; 12: emitter region; 14: base region; 15: contact region; 16: accumulation region; 17: well region; 18: drift region; 20: buffer region; 21: front surface; 22: collector region; 23: back surface; 24: collector electrode; 25: connection portion; 30: dummy trench portion; 31: extending part; 32: dummy dielectric film; 33: connecting part; 34: dummy conductive portion; 36: first interlayer dielectric film; 37: second interlayer dielectric film; 38: interlayer dielectric film; 40: gate trench portion; 41: extending part; 42: gate dielectric film; 43: connecting part; 44: gate conductive portion; 50: gate metal layer; 51: pad electrode; 52: emitter electrode; 53: contact hole; 54: contact hole; 55: contact hole; 56: contact hole; 57: contact hole; 58: contact hole; 59: contact hole; 70: transistor portion; 71: mesa portion; 80: diode portion; 81: mesa portion; 82: cathode region; 90: boundary portion; 91: mesa portion; 100: semiconductor device; 102: end side; 112: gate pad; 114: sensing electrode; 115: current sensing portion; 116: anode pad; 117: anode wiring portion; 118: cathode pad; 119: cathode wiring portion; 120: active portion; 122: active trench portion; 124: active contact portion; 125: pad connection portion; 130: inactive portion; 132: polycrystalline portion; 134: first inactive contact portion; 135: second inactive contact portion; 138: third interlayer dielectric film; 140: edge termination structure portion; 142: guard ring; 144: field plate; 146: edge metal layer; 148: field dielectric film; 151: back surface side lifetime control region; 152: front surface side lifetime control region; 170: Zener diode portion; 180: temperature sensitive portion; 181: temperature sensitive cathode region; 182: temperature sensitive anode region; 183: temperature sensitive diode; 188: temperature sensitive contact portion; 198: housing portion; 200: recess; 300: contact region; 302: void; 1340: bottom surface corner portion; 1242: barrier metal film; 1244: plug portion; 1342: barrier metal film; 1344: plug portion; 1352: barrier metal film; 1354: plug portion; 1420: non-corner region; 1422: corner region; 1880: bottom surface corner portion; 1882: barrier metal film; and 1884: plug portion.

What is claimed is:

1. A semiconductor device comprising: an active portion; and an inactive portion, wherein
the inactive portion includes
a polycrystalline portion which is provided above a semiconductor substrate,
an interlayer dielectric film which is provided above the polycrystalline portion,
a first inactive contact portion which is provided to extend from an upper surface to a lower surface of the interlayer dielectric film, and
a housing portion which is provided below the first inactive contact portion,
a bottom surface corner portion of the first inactive contact portion is in contact with the polycrystalline portion, and
a bottom surface of the first inactive contact portion is in contact with the housing portion.

2. The semiconductor device according to claim 1, wherein
a side surface of the polycrystalline portion is in contact with a side surface of the housing portion.

3. The semiconductor device according to claim 1, wherein
the housing portion is a region, which is provided below the first inactive contact portion, in the interlayer dielectric film.

4. The semiconductor device according to claim 1, wherein
the first inactive contact portion includes
a barrier metal film which is provided on the bottom surface corner portion of the first inactive contact portion, and
a plug portion which is provided in contact with an inside of the barrier metal film.

5. The semiconductor device according to claim 1, wherein
the active portion includes a plurality of active contact portions which are provided at a front surface of the semiconductor substrate.

6. The semiconductor device according to claim 1, wherein
a bottom surface of the first inactive contact portion is in contact with the polycrystalline portion and the housing portion.

7. The semiconductor device according to claim 6, wherein
the polycrystalline portion is in contact with the bottom surface of the first inactive contact portion, from the bottom surface corner portion to a region of 10% or more and 40% or less of the bottom surface of the first inactive contact portion.

8. The semiconductor device according to claim 1, wherein
side walls of the first inactive contact portion have a trench contact structure in contact with a side surface of the polycrystalline portion.

9. The semiconductor device according to claim 1, wherein
a side wall of the first inactive contact portion is in contact with the polycrystalline portion and the interlayer dielectric film, and
the polycrystalline portion is in contact with the side wall of the first inactive contact portion, from the bottom surface corner portion to a region of 10% or more and 90% or less of the side wall of the first inactive contact portion.

10. The semiconductor device according to claim 1, comprising:
a gate trench portion which is provided at a front surface of the semiconductor substrate and includes a gate conductive portion; and
a gate metal layer which is provided above the semiconductor substrate and is electrically connected to the gate conductive portion, wherein
the polycrystalline portion
is connected to the gate metal layer via the first inactive contact portion, and
is connected to the gate conductive portion.

11. The semiconductor device according to claim 1, comprising:
a dummy trench portion which is provided at a front surface of the semiconductor substrate and includes a dummy conductive portion; and
an emitter electrode which is provided above the semiconductor substrate and is electrically connected to the semiconductor substrate, wherein
the polycrystalline portion
is connected to the emitter electrode via the first inactive contact portion, and
is connected to the dummy conductive portion.

12. The semiconductor device according to claim 1, comprising:
a guard ring of a second conductivity type which is provided between the active portion and an end side of the semiconductor substrate at a front surface of the semiconductor substrate; and
an edge metal layer which is provided above the semiconductor substrate and is electrically connected to the guard ring, wherein
the polycrystalline portion is connected to the edge metal layer via the first inactive contact portion.

13. The semiconductor device according to claim 12, comprising
a field dielectric film which is provided below the interlayer dielectric film, wherein
the first inactive contact portion is provided above the polycrystalline portion positioned above the field dielectric film.

14. The semiconductor device according to claim 1, comprising:
a guard ring of a second conductivity type which is provided between the active portion and an end side of the semiconductor substrate at a front surface of the semiconductor substrate;
an edge metal layer which is provided above the semiconductor substrate and is electrically connected to the guard ring; and
a field dielectric film which is provided below the interlayer dielectric film, wherein
the polycrystalline portion is connected to the edge metal layer via the first inactive contact portion, and
the housing portion is a region, which is provided below the first inactive contact portion, in the field dielectric film.

15. The semiconductor device according to claim 1, comprising:
a guard ring of a second conductivity type which is provided between the active portion and an end side of the semiconductor substrate at a front surface of the semiconductor substrate; and
an edge metal layer which is provided above the semiconductor substrate and is electrically connected to the guard ring, wherein
the polycrystalline portion is connected to the edge metal layer via the first inactive contact portion,
the polycrystalline portion includes a contact region in contact with the housing portion, and
the housing portion includes a polycrystalline semiconductor which has an impurity concentration lower than that of the contact region of the polycrystalline portion.

16. The semiconductor device according to claim 1, comprising
a pad electrode which is provided above the semiconductor substrate, wherein
the polycrystalline portion
is connected to the pad electrode via the first inactive contact portion.

17. The semiconductor device according to claim 1, comprising
a temperature sensitive portion which is provided above the semiconductor substrate, wherein
the temperature sensitive portion includes a temperature sensitive diode which is provided above the semiconductor substrate, and
the polycrystalline portion is the temperature sensitive diode.

18. The semiconductor device according to claim 17, wherein
the temperature sensitive diode includes a contact region in contact with the housing portion, and
the housing portion includes a polycrystalline semiconductor of a conductivity type different from that of the contact region of the temperature sensitive diode.

19. The semiconductor device according to claim 17, wherein
the temperature sensitive diode includes a contact region in contact with the housing portion, and
the housing portion includes a polycrystalline semiconductor which has a same conductivity type as that of the contact region of the temperature sensitive diode and has a doping concentration lower than that of the contact region.

20. A method for manufacturing a semiconductor device, comprising:
forming an active portion; and
forming an inactive portion, wherein
the forming the inactive portion includes
forming a polycrystalline portion above a semiconductor substrate,
forming an interlayer dielectric film above the polycrystalline portion,
forming a first inactive contact portion extending from an upper surface to a lower surface of the interlayer dielectric film, and
forming a housing portion below the first inactive contact portion,
a bottom surface corner portion of the first inactive contact portion is in contact with the polycrystalline portion, and
a bottom surface of the first inactive contact portion is in contact with the housing portion.
